(19) United States
(12) Patent Application Publication
(10) Pub. No.: US 2024/0130153 A1
(43) Pub. Date: Apr. 18, 2024

(54) EXTENDING OLED OPERATIONAL LIFETIME VIA GRADED CO-HOST/CO-DOPED EMISSION LAYER METHOD

(71) Applicant: The Regents of the University of Michigan, Ann Arbor, MI (US)

(72) Inventors: Stephen R. Forrest, Ann Arbor, MI (US); Haonan ZHAO, Ann Arbor, MI (US); Jongchan KIM, Ann Arbor, MI (US)

(21) Appl. No.: 18/470,908

(22) Filed: Sep. 20, 2023

Related U.S. Application Data
(60) Provisional application No. 63/384,172, filed on Nov. 17, 2022.
(60) Provisional application No. 63/376,500, filed on Sep. 21, 2022.

(51) Int. Cl. H10K 50/15; H10K 50/125; H10K 50/18; H10K 59/80

(52) U.S. Cl. CPC H10K 50/15; H10K 50/125; H10K 50/181; H10K 59/80516; H10K 2102/302

(57) ABSTRACT

Disclosed are methods, designs and materials for extending the device operational lifetime of the phosphorescent organic light emitting devices (OLEDs) such as thermally activated delayed fluorescence (TADF) OLEDs. Applying a graded cohost or co-doped emission layer (EML) in the organic layers, both charge transport and charge balance can be precisely engineered to generate a uniform exciton/exciplex profile, preventing the early deaths due to the dense hot-excited states in the device. This invention is aimed at the short lifetime problem of the high efficient phosphorescent OLEDs and TADF OLEDs, especially in the white, blue and deep blue applications.

### CROSS-REFERENCE TO RELATED APPLICATIONS

This application claims priority under 35 U.S.C. § 119(e) to U.S.Provisional Application No. 63/384,172, filed on Nov. 17, 2022, and U.S.Provisional Application No, 63/376,500, filed on Sep. 21, 2022, the entire contents of which are incorporated herein by reference.

### STATEMENT REGARDING FEDERALLY SPONSORED RESEARCH OR DEVELOPMENT

This invention was made with government support under DE-EE0009688 awarded by the U.S. Department of Energy. The government has certain rights in the invention.

### BACKGROUND OF THE INVENTION

Compared to fluorescent OLEDs, phosphorescent OLEDs and TADF OLEDs can achieve close to 100% utilization of excitons via effective singlet-triplet mixing. They either use heavy metal atoms for strong spin-orbit coupling (SOC) or fast endothermic intersystem crossing (ISC, or reverse ISC in some literature) to enable effective luminescence from the originally dark and long-lived triplet excitons. However, the naturally forbidden optical transition from the triplets to the ground state determines the long lifetime of the triplet excitons, leading to a much higher chance for the excess triplet energy to damage the organic molecules. For example, the triplet-polaron annihilation (TPA) and the triplet-triplet annihilation (TTA) are two common causes of the short-lived blue OLEDs. In the previous work, people have developed methods to enhance the exciton radiative decay rate from the scopes of chemistry, physics, and electronic engineering.

Opto-electronic devices that make use of organic materials are becoming increasingly desirable for various reasons. Many of the materials used to make such devices are relatively inexpensive, so organic opto-electronic devices have the potential for cost advantages over inorganic devices. In addition, the inherent properties of organic materials, such as their flexibility, may make them well suited for particular applications such as fabrication on a flexible substrate. Examples of organic opto-electronic devices include organic light emitting diodes/devices (OLEDs), organic phototransistors, organic photovoltaic cells, and organic photodetectors. For OLEDs, the organic materials may have performance advantages over conventional materials.

OLEDs make use of thin organic films that emit light when voltage is applied across the device. OLEDs are becoming an increasingly interesting technology for use in applications such as flat panel displays, illumination, and backlighting.

One application for phosphorescent emissive molecules is a full color display. Industry standards for such a display call for pixels adapted to emit particular colors, referred to as “saturated” colors. In particular, these standards call for saturated red, green, and blue pixels. Alternatively, the OLED can be designed to emit white light. In conventional liquid crystal displays emission from a white backlight is filtered using absorption filters to produce red, green and blue emission. The same technique can also be used with OLEDs. The white OLED can be either a single emissive layer (EML) device or a stack structure. Color may be measured using CIE coordinates, which are well known to the art.

### SUMMARY OF THE INVENTION

Some embodiments of the invention disclosed herein are set forth below, and any combination of these embodiments (or portions thereof) may be made to define another embodiment.

In one aspect an organic light emitting device (OLED) comprises a substrate, a first electrode positioned over the substrate, a hole injection layer (HIL) positioned over the first electrode, an emission layer (EML) positioned over the HIL, comprising a graded host material graded in a first direction and a graded emitter material graded in a second direction, an electron transport layer (ETL) positioned over the EML, and a second electrode positioned over the ETL.

In one embodiment, the graded emitter material comprises a TADF emitter.

In one embodiment, the TADF emitter comprises a blue TADF emitter.

In one embodiment, the graded host material comprises an electron transport (ET) host.

In one embodiment, the EML further comprises a hole transport (HT) host.

In one embodiment, the graded host material is linearly graded from 18% to 8% from the HBL interface to the EBL interface.

In one embodiment, the graded emitter material is linearly graded from 18% to 8% from the EBL interface to the HBL interface.

In one embodiment, the device further comprises an electron blocking layer (EBL) positioned between the HIL and the EML.

In one embodiment, the device further comprises a hole blocking layer (HBL) positioned between the EML and the ETL.

In one embodiment, the first electrode has a thickness of 50 nm to 100 nm.

In one embodiment, the first electrode comprises ITO.

In one embodiment, the HIL has thickness of 0.5 nm to 10 nm.

In one embodiment, the ETL has a thickness of 10 nm to 50 nm.

In one embodiment, the HT host is a first host compound comprising at least one chemical moiety selected from the group consisting of triphenylene, carbazole, indolocarbazole, dibenzothiphene, dibenzofuran, dibenzoselenophene, 5λ2-benzo[d]benzo[4,5]imidazo[3,2-a]imidazole, 5,9-dioxa-13b-boranaphtho[3,2,1-de]anthracene, triazine, boryl, silyl, aza-triphenylene, aza-carbazole, aza-indolocarbazole, aza-dibenzothiophene, aza-dibenzofuran, aza-dibenzoselenophene, aza-5 λ 2-benzo[d]benzo[4,5]imidazo[3,2-a]imidazole, and aza-(5,9-dioxa-13b-boranaphtho[3,2,1-de]anthracene).

In one embodiment, the blue TADF comprises:

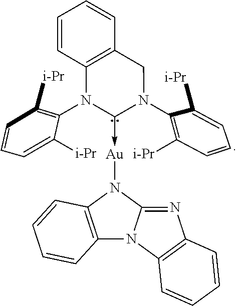

In one embodiment, the ET host is a second host compound having the structure of Formula I:

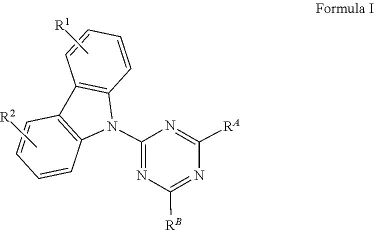

wherein, in Formula I, R^{A} and R^{B} are each independently selected from the group consisting of:

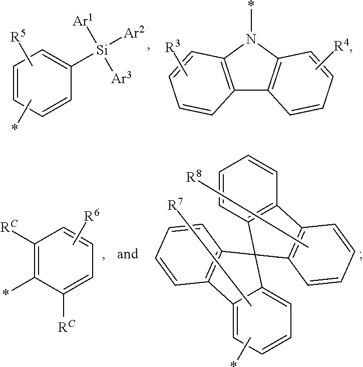

wherein * indicates the bond to Formula I; wherein each of R⁵ to R⁸ represent mono to the maximum number of substitution, or no substitution; Ar¹, Ar², and Ar³ are each an aryl or heteroaryl group, wherein the Ar¹, Ar², and Ar³ are each optionally further substituted with one or more substituents R^{D}; each R^{C}, R^{D}, and R¹ to R⁸ is independently a hydrogen or is selected from the group consisting of deuterium, halogen, alkyl, cycloalkyl, heteroalkyl, heterocycloalkyl, arylalkyl, alkoxy, aryloxy, amino, silyl, germyl, boryl, alkenyl, cycloalkenyl, heteroalkenyl, alkynyl, aryl, heteroaryl, acyl, carboxylic acid, ether, ester, nitrile, isonitrile, sulfanyl, selenyl, sulfinyl, sulfonyl, phosphino, and combinations thereof; and R¹ to R⁸ represent mono to the maximum number of substitution, or no substitution; each R¹ to R⁸ is independently a hydrogen or is selected from the group consisting of deuterium, halogen, alkyl, cycloalkyl, heteroalkyl, heterocycloalkyl, arylalkyl, alkoxy, aryloxy, amino, silyl, germyl, boryl, alkenyl, cycloalkenyl, heteroalkenyl, alkynyl, aryl, heteroaryl, acyl, carboxylic acid, ether, ester, nitrile, isonitrile, sulfanyl, selenyl, sulfinyl, sulfonyl, phosphino, and combinations thereof; and wherein any two adjacent substituents may join to form a ring.

In one embodiment, the LUMO of the EML is in the range of 0.1 to 2 eV, and the HOMO of the EML is in the range of 5 to 7 eV.

In one embodiment, a product comprising the device as described above, where the product sis elected from the group consisting of a flat panel display, a curved display, a computer monitor, a computer, a medical monitor, a television, a billboard, a light for interior or exterior illumination and/or signaling, a heads-up display, a fully or partially transparent display, a flexible display, a rollable display, a foldable display, a stretchable display, a laser printer, a telephone, a mobile phone, a tablet, a phablet, a personal digital assistant (PDA), a wearable device, a laptop computer, a digital camera, a camcorder, a viewfinder, a micro-display, a 3-D display, a virtual reality or augmented reality display or device, a vehicle, a video wall comprising multiple displays tiled together, a theater or stadium screen, a light therapy device, a camera, an imaging device, and a sign.

In another aspect, a method of manufacturing an organic light emitting device (OLED) comprises depositing a first electrode over a substrate, depositing a hole injection layer (HIL) positioned over the first electrode, depositing an emission layer (EML) positioned over the HIL, wherein the EML comprises a graded cohost or co-doped emission layer, depositing an electron transport layer (ETL) positioned over the EML, and depositing a second electrode positioned over the ETL.

In one embodiment, the method further comprises depositing an electron blocking layer (EBL) positioned between the HIL and the EML.

In one embodiment, the method further comprises depositing a hole blocking layer (HBL) positioned between the EML and the ETL.

In another aspect, an organic light emitting device (OLED) comprises a substrate, a first electrode positioned over the substrate, a hole injection layer (HIL) positioned over the first electrode, an electron blocking layer (EBL) positioned over the HIL, an emission layer (EML) positioned over the EBL, a hole blocking layer (HBL) positioned over the EML, an electron transport layer (ETL) positioned over the HBL, and a second electrode positioned over the ETL.

In one embodiment, the EML comprises a graded cohost or co-doped emission layer.

In one embodiment, the EML includes a second host configured to reduce the electron/hole barrier and increase the less balanced carrier mobility.

In one embodiment, the EML comprises an electron transport (ET) host, and hole transport (HT) host, and a blue TADF.

In one embodiment, the ET host is linearly graded from 18% to 8% from the HBL interface to the EBL interface, and the Blue TADF 1 is linearly graded from 18% to 8% from the EBL interface to the HBL interface.

### BRIEF DESCRIPTION OF THE DRAWINGS

The foregoing purposes and features, as well as other purposes and features, will become apparent with reference to the description and accompanying figures below, which are included to provide an understanding of the invention and constitute a part of the specification, in which like numerals represent like elements, and in which:

FIG. 1 is a block diagram depicting an exemplary organic light emitting device (OLED) in accordance with some embodiments.

FIG. 2 is a block diagram depicting an exemplary inverted organic light emitting device that does not have a separate electron transport layer in accordance with some embodiments.

FIG. 3A depicts exemplary molecules used in the device in accordance with some embodiments.

FIG. 3B depicts an exemplary device and energy level structure for the single host and graded cohost device in accordance with some embodiments.

FIG. 4A is a plot showing exemplary J-V characteristics of the graded mixed host and single host devices in accordance with some embodiments.

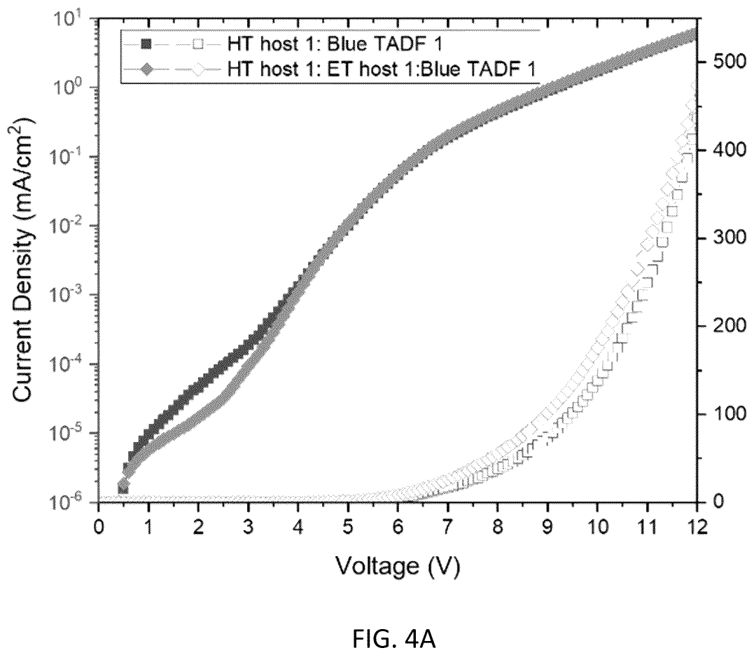

FIG. 4B is a plot showing exemplary EQE vs current of the two devices in accordance with some embodiments.

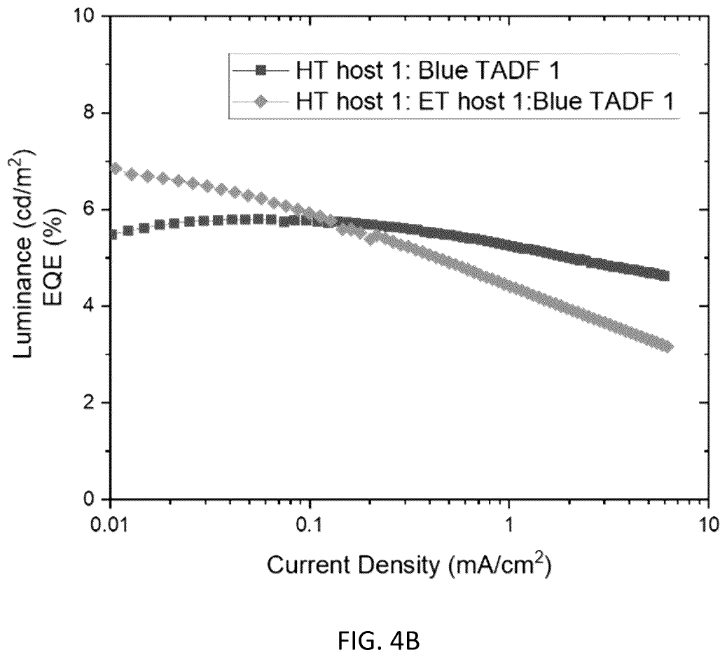

FIG. 4C shows an exemplary semi-log plot of lifetime curves for two devices in accordance with some embodiments.

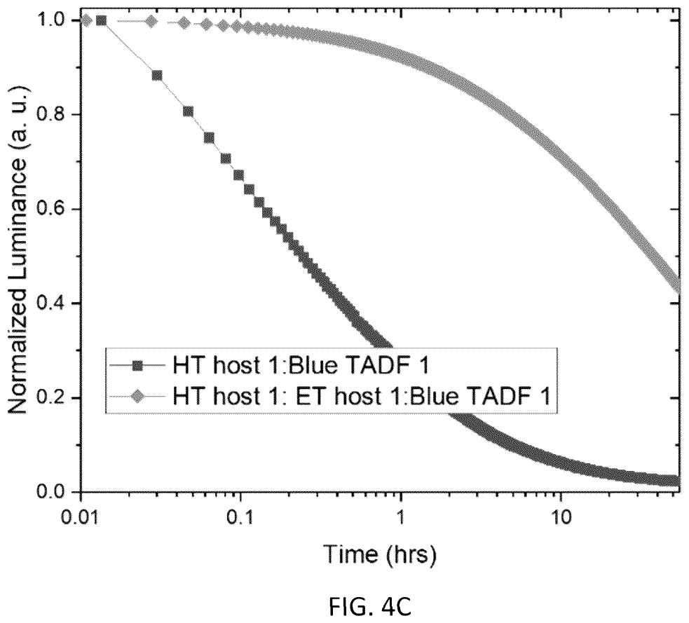

FIG. 4D is a plot showing exemplary spectra of two devices in accordance with some embodiments.

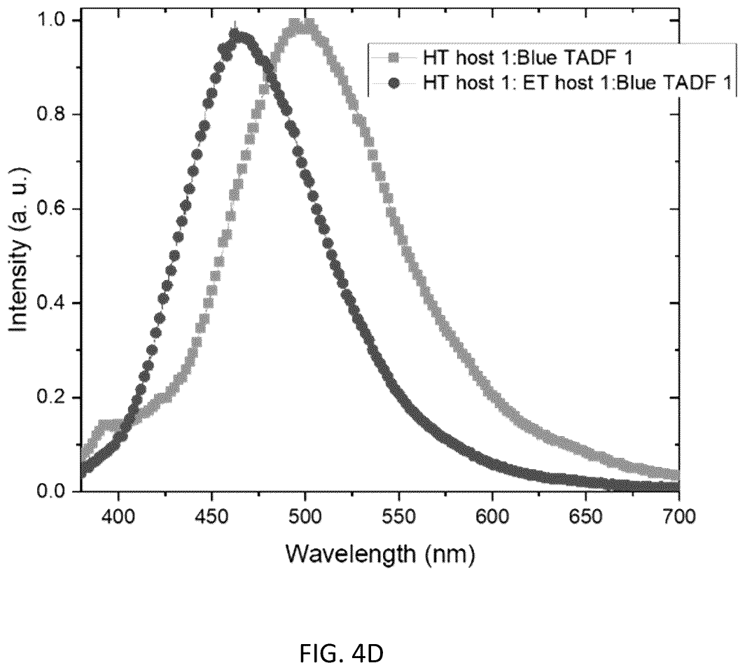

FIG. 5 is an energy level diagram of a PHOLED with the frontier orbital energies of the materials in eV. The anode and cathode are located on the left and right sides of the diagram, respectively.

FIG. 6 shows the molecular structural formulae of SiTrzCz2 and the calculated optimized structure, and HOMO and LUMO states of SiTrzCz2 via density functional theory.

FIG. 7 depicts the fluorescence and phosphorescence spectra of a neat SiTrzCz2 film at room temperature and 77K.

FIG. 8 is a phase diagram determined by differential scanning calorimetry (DSC) of mixed films comprising mCBP and SiTrzCz2 at varied weight ratio. The trend for each phase transition during the thermal loop is indicated by the solid line. The vanished Tc and Tm near the SiTrzCz2 75 wt % show that the mixture stays amorphous (indicated by white color) during the scan. The dashed line shows the expected melting point Tm.

FIG. 9 depicts the grazing incidence wide-angle X-ray scattering patterns (GIWAXS) of neat mCBP and 1:1 mixed film comprising mCBP and SiTrzCz2.

FIG. 10 shows a plot of the line cut patterns of the GIWAXS patterns of neat mCBP and a 1:1 mixed film.

FIG. 11 shows the crystal structure of mCBP focusing on its π-stacking geometry at left. The 4.2 Å distance between each π-system is shown. Also shown is the molecular structural formulae of mCBP. At right is the crystal structure of mCBP showing its lamellar stacking habit. The distance between each lamellar block (10.5 Å) is shown.

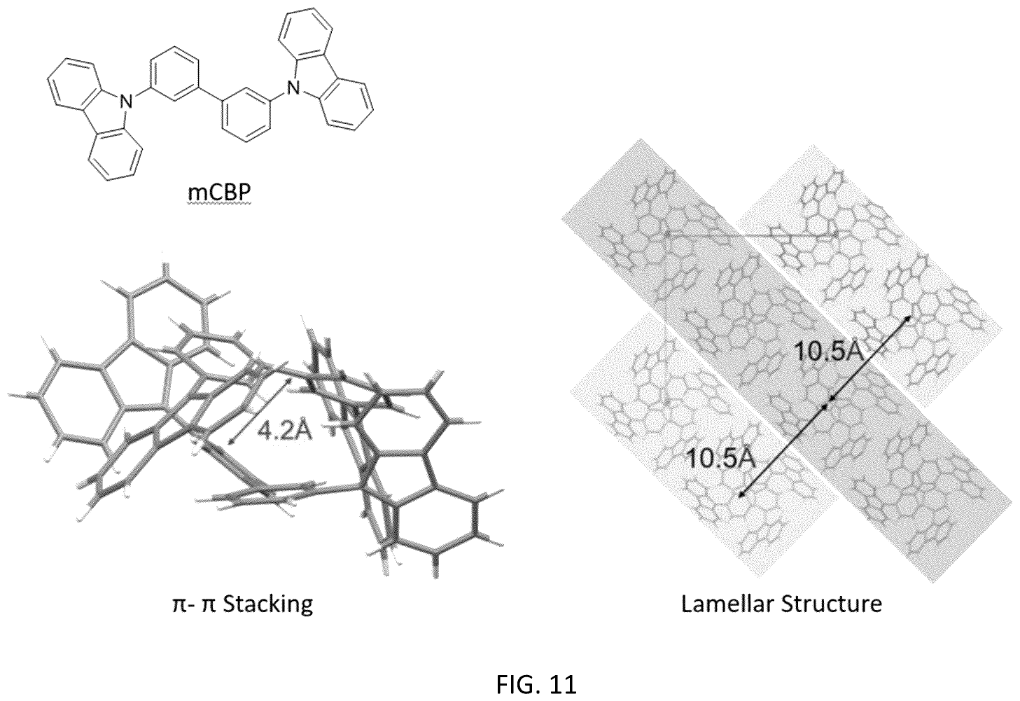

FIG. 12 is a plot of the current density—external quantum efficiency (J-EQE) characteristics of exemplary OLEDs with neat and mixed host matrices with at varied phosphor doping concentrations.

FIG. 13 is a plot of the clectroluminescence spectra of an exemplary mixed host device with 12 vol. % doped Ir(cb)3 at several current densities. The blue diamonds show the spectrum of a neat mCBP host OLED with a 12 vol. % doping concentration of Ir(cb)3 in the emissive layer.

FIG. 14 is a plot of the measured photoluminescent quantum yield (PLQY) (red) and peak external quantum efficiency (EQE, black) vs. concentration (volume %) of SiTrzCz2 within the emissive layer.

FIG. 15 is a plot of the measured thin film PLQY (red) and exciton radiative lifetime (black) of the neat mCBP and 1:1 mixed host vs. doping concentration of Ir(cb)3.

FIG. 16 is a series of plots of the J-V characteristics of the electron- and hole-only devices comprising a 1:1 volume ratio mCBP:SiTrzCz2 mixed host at various Ir(cb)3 concentrations, as well as J-V characteristics of PHOLEDs with the neat mCBP and 1:1 mixed host at several Ir(cb)3 concentrations.

FIG. 17 is a plot of luminance vs. time of PHOLEDs comprising a neat mCBP and a 1:1 mixed host. The initial luminance is L0=500 cd/m².

### DETAILED DESCRIPTION OF THE INVENTION

It is to be understood that the figures and descriptions of the present invention have been simplified to illustrate elements that are relevant for a clearer comprehension of the present invention, while eliminating, for the purpose of clarity, many other elements found in systems and methods of extending OLED operational lifetime via graded co-host/co-doped emission layers. Those of ordinary skill in the art may recognize that other elements and/or steps are desirable and/or required in implementing the present invention. However, because such elements and steps are well known in the art, and because they do not facilitate a better understanding of the present invention, a discussion of such elements and steps is not provided herein. The disclosure herein is directed to all such variations and modifications to such elements and methods known to those skilled in the art.

Unless defined otherwise, all technical and scientific terms used herein have the same meaning as commonly understood by one of ordinary skill in the art to which this invention belongs. Although any methods and materials similar or equivalent to those described herein can be used in the practice or testing of the present invention, exemplary methods and materials are described.

As used herein, each of the following terms has the meaning associated with it in this section.

The articles “a” and “an” are used herein to refer to one or to more than one (i.e., to at least one) of the grammatical object of the article. By way of example, “an element” means one element or more than one element.

“About” as used herein when referring to a measurable value such as an amount, a temporal duration, and the like, is meant to encompass variations of ±20%, ±10%, ±5%, ±1%, and ±0.1% from the specified value, as such variations are appropriate.

Ranges: throughout this disclosure, various aspects of the invention can be presented in a range format. It should be understood that the description in range format is merely for convenience and brevity and should not be construed as an inflexible limitation on the scope of the invention. Where appropriate, the description of a range should be considered to have specifically disclosed all the possible subranges as well as individual numerical values within that range. For example, description of a range such as from 1 to 6 should be considered to have specifically disclosed subranges such as from 1 to 3, from 1 to 4, from 1 to 5, from 2 to 4, from 2 to 6, from 3 to 6 etc., as well as individual numbers within that range, for example, 1, 2, 2.7, 3, 4, 5, 5.3, and 6. This applies regardless of the breadth of the range.

As used herein, the term “organic” includes polymeric materials as well as small molecule organic materials that may be used to fabricate organic opto-electronic devices. “Small molecule” refers to any organic material that is not a polymer, and “small molecules” may actually be quite large. Small molecules may include repeat units in some circumstances. For example, using a long chain alkyl group as a substituent does not remove a molecule from the “small molecule” class. Small molecules may also be incorporated into polymers, for example as a pendent group on a polymer backbone or as a part of the backbone. Small molecules may also serve as the core moiety of a dendrimer, which consists of a series of chemical shells built on the core moiety. The core moiety of a dendrimer may be a fluorescent or phosphorescent small molecule emitter. A dendrimer may be a “small molecule,” and it is believed that all dendrimers currently used in the field of OLEDs are small molecules.

As used herein, “top” means furthest away from the substrate, while “bottom” means closest to the substrate. Where a first layer is described as “disposed over” a second layer, the first layer is disposed further away from substrate. There may be other layers between the first and second layer, unless it is specified that the first layer is “in contact with” the second layer. For example, a cathode may be described as “disposed over” an anode, even though there are various organic layers in between.

As used herein, “solution processable” means capable of being dissolved, dispersed, or transported in and/or deposited from a liquid medium, either in solution or suspension form.

A ligand may be referred to as “photoactive” when it is believed that the ligand directly contributes to the photoactive properties of an emissive material. A ligand may be referred to as “ancillary” when it is believed that the ligand does not contribute to the photoactive properties of an emissive material, although an ancillary ligand may alter the properties of a photoactive ligand.

As used herein, and as would be generally understood by one skilled in the art, a first “Highest Occupied Molecular Orbital” (HOMO) or “Lowest Unoccupied Molecular Orbital” (LUMO) energy level is “greater than” or “higher than” a second HOMO or LUMO energy level if the first energy level is closer to the vacuum energy level. Since ionization potentials (IP) are measured as a negative energy relative to a vacuum level, a higher HOMO energy level corresponds to an IP having a smaller absolute value (an IP that is less negative). Similarly, a higher LUMO energy level corresponds to an electron affinity (EA) having a smaller absolute value (an EA that is less negative). On a conventional energy level diagram, with the vacuum level at the top, the LUMO energy level of a material is higher than the HOMO energy level of the same material. A “higher” HOMO or LUMO energy level appears closer to the top of such a diagram than a “lower” HOMO or LUMO energy level.

As used herein, and as would be generally understood by one skilled in the art, a first work function is “greater than” or “higher than” a second work function if the first work function has a higher absolute value. Because work functions are generally measured as negative numbers relative to vacuum level, this means that a “higher” work function is more negative. On a conventional energy level diagram, with the vacuum level at the top, a “higher” work function is illustrated as further away from the vacuum level in the downward direction. Thus, the definitions of HOMO and LUMO energy levels follow a different convention than work functions.

The terms “halo,” “halogen,” and “halide” are used interchangeably and refer to fluorine, chlorine, bromine, and iodine.

The term “acyl” refers to a substituted carbonyl radical (C(O)—Rs).

The term “ester” refers to a substituted oxycarbonyl (—O—C(O)—Rs or —C(O)—O—Rs) radical.

The term “ether” refers to an —ORs radical.

The terms “sulfanyl” or “thio-ether” are used interchangeably and refer to a —SRs radical.

The terms “selenyl” refers to a —SeRs radical.

The term “sulfinyl” refers to a —S(O)—Rs radical.

The term “sulfonyl” refers to a —SO2-Rs radical.

The term “phosphino” refers to a —P(Rs)3 radical, wherein each Rs can be same or different.

The term “silyl” refers to a —Si(Rs)3 radical, wherein each Rs can be same or different.

The term “germyl” refers to a —Ge(Rs)3 radical, wherein each Rs can be same or different.

The term “boryl” refers to a —B(Rs)2 radical or its Lewis adduct —B(Rs)3 radical, wherein Rs can be same or different.

In each of the above, Rs can be hydrogen or a substituent selected from the group consisting of deuterium, halogen, alkyl, cycloalkyl, heteroalkyl, heterocycloalkyl, arylalkyl, alkoxy, aryloxy, amino, silyl, alkenyl, cycloalkenyl, heteroalkenyl, alkynyl, aryl, heteroaryl, and combination thereof. Preferred Rs is selected from the group consisting of alkyl, cycloalkyl, aryl, heteroaryl, and combination thereof.

The term “alkyl” refers to and includes both straight and branched chain alkyl radicals. Preferred alkyl groups are those containing from one to fifteen carbon atoms and includes methyl, ethyl, propyl, 1-methylethyl, butyl, 1-methylpropyl, 2-methylpropyl, pentyl, 1-methylbutyl, 2-methylbutyl, 3-methylbutyl, 1,1-dimethylpropyl, 1,2-dimethylpropyl, 2,2-dimethylpropyl, and the like. Additionally, the alkyl group may be optionally substituted.

The term “cycloalkyl” refers to and includes monocyclic, polycyclic, and spiro alkyl radicals. Preferred cycloalkyl groups are those containing 3 to 12 ring carbon atoms and includes cyclopropyl, cyclopentyl, cyclohexyl, bicyclo[3.1.1]heptyl, spiro[4.5]decyl, spiro[5.5]undecyl, adamantyl, and the like. Additionally, the cycloalkyl group may be optionally substituted.

The terms “heteroalkyl” or “heterocycloalkyl” refer to an alkyl or a cycloalkyl radical, respectively, having at least one carbon atom replaced by a heteroatom. Optionally the at least one heteroatom is selected from O, S, N, P, B, Si and Se, preferably, O, S or N. Additionally, the heteroalkyl or heterocycloalkyl group may be optionally substituted.

The term “alkenyl” refers to and includes both straight and branched chain alkene radicals. Alkenyl groups are essentially alkyl groups that include at least one carbon-carbon double bond in the alkyl chain. Cycloalkenyl groups are essentially cycloalkyl groups that include at least one carbon-carbon double bond in the cycloalkyl ring. The term “heteroalkenyl” as used herein refers to an alkenyl radical having at least one carbon atom replaced by a heteroatom. Optionally the at least one heteroatom is selected from O, S, N, P, B, Si, and Se, preferably, O, S, or N. Preferred alkenyl, cycloalkenyl, or heteroalkenyl groups are those containing two to fifteen carbon atoms. Additionally, the alkenyl, cycloalkenyl, or heteroalkenyl group may be optionally substituted.

The term “alkynyl” refers to and includes both straight and branched chain alkyne radicals. Alkynyl groups are essentially alkyl groups that include at least one carbon-carbon triple bond in the alkyl chain. Preferred alkynyl groups are those containing two to fifteen carbon atoms. Additionally, the alkynyl group may be optionally substituted.

The terms “aralkyl” or “arylalkyl” are used interchangeably and refer to an alkyl group that is substituted with an aryl group. Additionally, the aralkyl group may be optionally substituted.

The term “heterocyclic group” refers to and includes aromatic and non-aromatic cyclic radicals containing at least one heteroatom. Optionally the at least one heteroatom is selected from O, S, N, P, B, Si, and Se, preferably, O, S, or N. Hetero-aromatic cyclic radicals may be used interchangeably with heteroaryl. Preferred hetero-non-aromatic cyclic groups are those containing 3 to 7 ring atoms which includes at least one hetero atom, and includes cyclic amines such as morpholino, piperidino, pyrrolidino, and the like, and cyclic ethers/thio-ethers, such as tetrahydrofuran, tetrahydropyran, tetrahydrothiophene, and the like. Additionally, the heterocyclic group may be optionally substituted.

The term “aryl” refers to and includes both single-ring aromatic hydrocarbyl groups and polycyclic aromatic ring systems. The polycyclic rings may have two or more rings in which two carbons are common to two adjoining rings (the rings are “fused”) wherein at least one of the rings is an aromatic hydrocarbyl group, e.g., the other rings can be cycloalkyls, cycloalkenyls, aryl, heterocycles, and/or heteroaryls. Preferred aryl groups are those containing six to thirty carbon atoms, preferably six to twenty carbon atoms, more preferably six to twelve carbon atoms. Especially preferred is an aryl group having six carbons, ten carbons or twelve carbons. Suitable aryl groups include phenyl, biphenyl, triphenyl, triphenylene, tetraphenylene, naphthalene, anthracene, phenalene, phenanthrene, fluorene, pyrene, chrysene, perylene, and azulene, preferably phenyl, biphenyl, triphenyl, triphenylene, fluorene, and naphthalene. Additionally, the aryl group may be optionally substituted.

The term “heteroaryl” refers to and includes both single-ring aromatic groups and polycyclic aromatic ring systems that include at least one heteroatom. The heteroatoms include, but are not limited to O, S, N, P, B, Si, and Se. In many instances, O, S, or N are the preferred heteroatoms. Hetero-single ring aromatic systems are preferably single rings with 5 or 6 ring atoms, and the ring can have from one to six heteroatoms. The hetero-polycyclic ring systems can have two or more rings in which two atoms are common to two adjoining rings (the rings are “fused”) wherein at least one of the rings is a heteroaryl, e.g., the other rings can be cycloalkyls, cycloalkenyls, aryl, heterocycles, and/or heteroaryls. The hetero-polycyclic aromatic ring systems can have from one to six heteroatoms per ring of the polycyclic aromatic ring system. Preferred heteroaryl groups are those containing three to thirty carbon atoms, preferably three to twenty carbon atoms, more preferably three to twelve carbon atoms. Suitable heteroaryl groups include dibenzothiophene, dibenzofuran, dibenzoselenophene, furan, thiophene, benzofuran, benzothiophene, benzoselenophene, carbazole, indolocarbazole, pyridylindole, pyrrolodipyridine, pyrazole, imidazole, triazole, oxazole, thiazole, oxadiazole, oxatriazole, dioxazole, thiadiazole, pyridine, pyridazine, pyrimidine, pyrazine, triazine, oxazine, oxathiazine, oxadiazine, indole, benzimidazole, indazole, indoxazine, benzoxazole, benzisoxazole, benzothiazole, quinoline, isoquinoline, cinnoline, quinazoline, quinoxaline, naphthyridine, phthalazine, pteridine, xanthene, acridine, phenazine, phenothiazine, phenoxazine, benzofuropyridine, furodipyridine, benzothienopyridine, thienodipyridine, benzoselenophenopyridine, and selenophenodipyridine, preferably dibenzothiophene, dibenzofuran, dibenzoselenophene, carbazole, indolocarbazole, imidazole, pyridine, triazine, benzimidazole, 1,2-azaborine, 1,3-azaborine, 1,4-azaborine, borazine, and aza-analogs thereof. Additionally, the heteroaryl group may be optionally substituted.

Of the aryl and heteroaryl groups listed above, the groups of triphenylene, naphthalene, anthracene, dibenzothiophene, dibenzofuran, dibenzoselenophene, carbazole, indolocarbazole, imidazole, pyridine, pyrazine, pyrimidine, triazine, and benzimidazole, and the respective aza-analogs of each thereof are of particular interest.

The terms alkyl, cycloalkyl, heteroalkyl, heterocycloalkyl, alkenyl, cycloalkenyl, heteroalkenyl, alkynyl, aralkyl, heterocyclic group, aryl, and heteroaryl, as used herein, are independently unsubstituted, or independently substituted, with one or more general substituents.

In many instances, the general substituents are selected from the group consisting of deuterium, halogen, alkyl, cycloalkyl, heteroalkyl, heterocycloalkyl, arylalkyl, alkoxy, aryloxy, amino, silyl, germyl, alkenyl, cycloalkenyl, heteroalkenyl, alkynyl, aryl, heteroaryl, acyl, carboxylic acid, ether, ester, nitrile, isonitrile, sulfanyl, selenyl, sulfinyl, sulfonyl, phosphino, boryl, and combinations thereof.

In some instances, the preferred general substituents are selected from the group consisting of deuterium, fluorine, alkyl, cycloalkyl, heteroalkyl, alkoxy, aryloxy, amino, silyl, germyl, boryl, alkenyl, cycloalkenyl, heteroalkenyl, aryl, heteroaryl, nitrile, isonitrile, sulfanyl, and combinations thereof.

In some instances, the more preferred general substituents are selected from the group consisting of deuterium, fluorine, alkyl, cycloalkyl, alkoxy, aryloxy, amino, silyl, boryl, aryl, heteroaryl, sulfanyl, and combinations thereof.

In yet other instances, the most preferred general substituents are selected from the group consisting of deuterium, fluorine, alkyl, cycloalkyl, aryl, heteroaryl, and combinations thereof.

The terms “substituted” and “substitution” refer to a substituent other than H that is bonded to the relevant position, e.g., a carbon or nitrogen. For example, when R1 represents mono-substitution, then one R1 must be other than H (i.e., a substitution). Similarly, when R1 represents di-substitution, then two of R1 must be other than H. Similarly, when R1 represents zero or no substitution, R1, for example, can be a hydrogen for available valencies of ring atoms, as in carbon atoms for benzene and the nitrogen atom in pyrrole, or simply represents nothing for ring atoms with fully filled valencies, e.g., the nitrogen atom in pyridine. The maximum number of substitutions possible in a ring structure will depend on the total number of available valencies in the ring atoms.

As used herein, “combinations thereof” indicates that one or more members of the applicable list are combined to form a known or chemically stable arrangement that one of ordinary skill in the art can envision from the applicable list. For example, an alkyl and deuterium can be combined to form a partial or fully deuterated alkyl group, a halogen and alkyl can be combined to form a halogenated alkyl substituent, and a halogen, alkyl, and aryl can be combined to form a halogenated arylalkyl. In one instance, the term substitution includes a combination of two to four of the listed groups. In another instance, the term substitution includes a combination of two to three groups. In yet another instance, the term substitution includes a combination of two groups. Preferred combinations of substituent groups are those that contain up to fifty atoms that are not hydrogen or deuterium, or those which include up to forty atoms that are not hydrogen or deuterium, or those that include up to thirty atoms that are not hydrogen or deuterium. In many instances, a preferred combination of substituent groups will include up to twenty atoms that are not hydrogen or deuterium.

The “aza” designation in the fragments described herein, i.e. aza-dibenzofuran, aza-dibenzothiophene, etc. means that one or more of the C—H groups in the respective aromatic ring can be replaced by a nitrogen atom, for example, and without any limitation, azatriphenylene encompasses both dibenzo[f,h]quinoxaline and dibenzo[f,h]quinoline. One of ordinary skill in the art can readily envision other nitrogen analogs of the aza-derivatives described above, and all such analogs are intended to be encompassed by the terms as set forth herein.

As used herein, “deuterium” refers to an isotope of hydrogen. Deuterated compounds can be readily prepared using methods known in the art. For example, U.S. Pat. No. 8,557,400, Patent Pub. No. WO 2006/095951, and U.S. Pat. Application Pub. No. US 2011/0037057, which are hereby incorporated by reference in their entireties, describe the making of deuterium-substituted organometallic complexes. Further reference is made to Ming Yan, et al., Tetrahedron 2015, 71, 1425-30 and Atzrodt et al., Angew. Chem. Int. Ed. (Reviews) 2007, 46, 7744-65, which are incorporated by reference in their entireties, describe the deuteration of the methylene hydrogens in benzyl amines and efficient pathways to replace aromatic ring hydrogens with deuterium, respectively.

It is to be understood that when a molecular fragment is described as being a substituent or otherwise attached to another moiety, its name may be written as if it were a fragment (e.g. phenyl, phenylene, naphthyl, dibenzofuryl) or as if it were the whole molecule (e.g. benzene, naphthalene, dibenzofuran). As used herein, these different ways of designating a substituent or attached fragment are considered to be equivalent.

In some instances, a pair of adjacent substituents can be optionally joined or fused into a ring. The preferred ring is a five, six, or seven-membered carbocyclic or heterocyclic ring, includes both instances where the portion of the ring formed by the pair of substituents is saturated and where the portion of the ring formed by the pair of substituents is unsaturated. As used herein, “adjacent” means that the two substituents involved can be on the same ring next to each other, or on two neighboring rings having the two closest available substitutable positions, such as 2, 2′ positions in a biphenyl, or 1, 8 position in a naphthalene, as long as they can form a stable fused ring system.

Referring now in detail to the drawings, in which like reference numerals indicate like parts or elements throughout the several views, in various embodiments, presented herein are systems devices and method for extending OLED operational lifetime via graded co-host/co-doped emission layers.

Generally, an OLED comprises at least one organic layer disposed between and electrically connected to an anode and a cathode. When a current is applied, the anode injects holes and the cathode injects electrons into the organic layer(s). The injected holes and electrons each migrate toward the oppositely charged electrode. When an electron and hole localize on the same molecule, an “exciton,” which is a localized electron-hole pair having an excited energy state, is formed. Light is emitted when the exciton relaxes via a photoemissive mechanism. In some cases, the exciton may be localized on an excimer or an exciplex. Non-radiative mechanisms, such as thermal relaxation, may also occur, but are generally considered undesirable.

The initial OLEDs used emissive molecules that emitted light from their singlet states (“fluorescence”) as disclosed, for example, in U.S. Pat. No. 4,769,292, which is incorporated by reference in its entirety. Fluorescent emission generally occurs in a time frame of less than 10 nanoseconds.

OLEDs having emissive materials that emit light from triplet states (“phosphorescence”) have been demonstrated. Baldo et al., “Highly Efficient Phosphorescent Emission from Organic Electroluminescent Devices,” Nature, vol. 395, 151-154, 1998; (“Baldo-I”) and Baldo et al., “Very high-efficiency green organic light-emitting devices based on electrophosphorescence,” Appl. Phys. Lett., vol. 75, No. 3, 4-6 (1999) (“Baldo-II”), are incorporated by reference in their entireties. Phosphorescence is described in more detail in US Pat. No. 7,279,704 at cols. 5-6, which are incorporated by reference.

As used herein, and as would be understood by one skilled in the art, “HATCN” (referred to interchangeably as HAT-CN) refers to 1,4,5,8,9,11-Hexaazatriphenylenehexacarbonitrile.

“TAPC” refers to 4,4′-Cyclohexylidenebis[N,N-bis(4-methylphenyl)aniline]. “B3PYMPM” refers to 4,6-Bis(3,5-di(pyridin-3-yl)phenyl)-2-methylpyrimidine. “BPyTP2” refers to 2,7-Bis(2,2′-bipyridin-5-yl) triphenylene. “LiQ” refers to Lithium Quinolate. “ITO” refers to Indium Tin Oxide. “CBP” refers to 4,4′-Bis(N-carbazolyl)-1,1′-biphenyl. “Ir(ppy)2acac” refers to bis[2-(2-pyridinyl-N)phenyl-C](acetylacetonato)iridium(III).

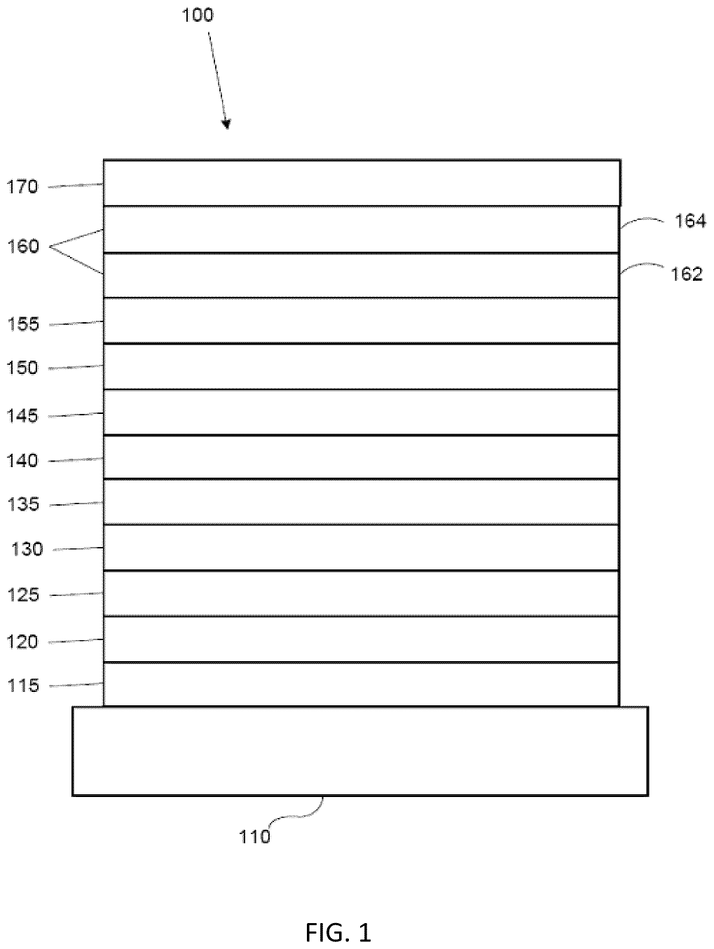

FIG. 1 shows an organic light emitting device 100. The figures are not necessarily drawn to scale. Device 100 may include a substrate 110, an anode 115, a hole injection layer 120, a hole transport layer 125, an electron blocking layer 130, an emissive layer 135, a hole blocking layer 140, an electron transport layer 145, an electron injection layer 150, a protective layer 155, a cathode 160, and a barrier layer 170. Cathode 160 is a compound cathode having a first conductive layer 162 and a second conductive layer 164. Device 100 may be fabricated by depositing the layers described, in order. The properties and functions of these various layers, as well as example materials, are described in more detail in U.S. Pat. No. 7,279,704 at cols. 6-10, which are incorporated by reference.

More examples for each of these layers are available. For example, a flexible and transparent substrate-anode combination is disclosed in U.S. Pat. No. 5,844,363, which is incorporated by reference in its entirety. An example of a p-doped hole transport layer is m-MTDATA doped with F4-TCNQ at a molar ratio of 50:1, as disclosed in U.S. Patent Application Publication No. 2003/0230980, which is incorporated by reference in its entirety. Examples of emissive and host materials are disclosed in U.S. Pat. No. 6,303,238 to Thompson et al., which is incorporated by reference in its entirety. An example of an n-doped electron transport layer is BPhen doped with Li at a molar ratio of 1:1, as disclosed in U.S. Patent Application Publication No. 2003/0230980, which is incorporated by reference in its entirety. U.S. Pat. Nos. 5,703,436 and 5,707,745, which are incorporated by reference in their entireties, disclose examples of cathodes including compound cathodes having a thin layer of metal such as Mg:Ag with an overlying transparent, electrically-conductive, sputter-deposited ITO layer. The theory and use of blocking layers is described in more detail in U.S. Pat. No. 6,097,147 and U.S. Patent Application Publication No. 2003/0230980, which are incorporated by reference in their entireties. Examples of injection layers are provided in U.S. Patent Application Publication No. 2004/0174116, which is incorporated by reference in its entirety. A description of protective layers may be found in U.S. Patent Application Publication No. 2004/0174116, which is incorporated by reference in its entirety.

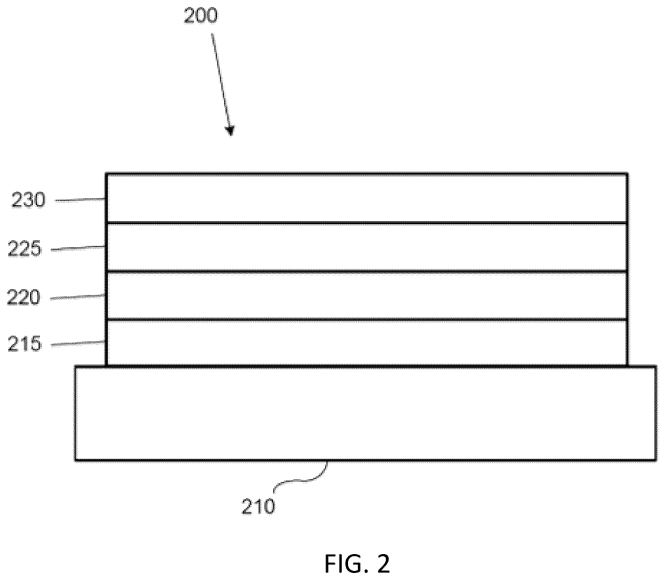

FIG. 2 shows an inverted OLED 200. The device includes a substrate 210, a cathode 215, an emissive layer 220, a hole transport layer 225, and an anode 230. Device 200 may be fabricated by depositing the layers described, in order. Because the most common OLED configuration has a cathode disposed over the anode, and device 200 has cathode 215 disposed under anode 230, device 200 may be referred to as an “inverted” OLED. Materials similar to those described with respect to device 100 may be used in the corresponding layers of device 200. FIG. 2 provides one example of how some layers may be omitted from the structure of device 100.

The simple layered structure illustrated in FIG. 1 and FIG. 2 is provided by way of non-limiting example, and it is understood that embodiments of the disclosure may be used in connection with a wide variety of other structures. The specific materials and structures described are exemplary in nature, and other materials and structures may be used. Functional OLEDs may be achieved by combining the various layers described in different ways, or layers may be omitted entirely, based on design, performance, and cost factors. Other layers not specifically described may also be included. Materials other than those specifically described may be used. Although many of the examples provided herein describe various layers as comprising a single material, it is understood that combinations of materials, such as a mixture of host and dopant, or more generally a mixture, may be used. Also, the layers may have various sublayers. The names given to the various layers herein are not intended to be strictly limiting. For example, in device 200, hole transport layer 225 transports holes and injects holes into emissive layer 220, and may be described as a hole transport layer or a hole injection layer. In one embodiment, an OLED may be described as having an “organic layer” disposed between a cathode and an anode. This organic layer may comprise a single layer, or may further comprise multiple layers of different organic materials as described, for example, with respect to FIGS. 1 and 2.

Although certain embodiments of the disclosure are discussed in relation to one particular device or type of device (for example OLEDs) it is understood that the disclosed improvements to light outcoupling properties of a substrate may be equally applied to other devices, including but not limited to PLEDs, OPVs, charge-coupled devices (CCDs), photosensors, or the like.

Certain embodiments of the disclosure relate to a light emitting device comprising an emissive layer (EML) spaced far from a cathode as described herein. Conventional organic light emitting devices typically place the EML near a metal cathode which incurs plasmon losses due to near field coupling. To avoid exciting these lossy modes it is necessary to space the EML far from the cathode. However, utilizing a thick electron transport layer (ETL) can be problematic due to changes in charge balance and increased resistivity. These problems can be overcome by utilizing a charge generation layer, for example a charge generation layer comprising at least one electron transport layer and at least one hole transport layer, to convert electron into hole current. This allows the use of higher mobility hole transporting materials and maintains the charge balance of the device. In some embodiments, the charge generation layer may be replaced or combined with any other layer capable of conducting electrons.

Structures and materials not specifically described may also be used, such as OLEDs comprised of polymeric materials (PLEDs) such as disclosed in U.S. Pat. No. 5,247,190 to Friend et al., which is incorporated by reference in its entirety. By way of further example, OLEDs having a single organic layer may be used. OLEDs may be stacked, for example as described in U.S. Pat. No. 5,707,745 to Forrest et al, which is incorporated by reference in its entirety. The OLED structure may deviate from the simple layered structure illustrated in FIGS. 1 and 2. For example, the substrate may include an angled reflective surface to improve out-coupling, such as a mesa structure as described in U.S. Pat. No. 6,091,195 to Forrest et al., and/or a pit structure as described in U.S. Pat. No. 5,834,893 to Bulovic et al., which are incorporated by reference in their entireties.

Unless otherwise specified, any of the layers of the various embodiments may be deposited by any suitable method. For the organic layers, preferred methods include thermal evaporation, ink-jet, such as described in U.S. Pat. Nos. 6,013,982 and 6,087,196, which are incorporated by reference in their entireties, organic vapor phase deposition (OVPD), such as described in U.S. Pat. No. 6,337,102 to Forrest et al., which is incorporated by reference in its entirety, and deposition by organic vapor jet printing (OVJP), such as described in U.S. Pat. No. 7,431,968, which is incorporated by reference in its entirety. Other suitable deposition methods include spin coating and other solution based processes. Solution based processes are preferably carried out in nitrogen or an inert atmosphere. For the other layers, preferred methods include thermal evaporation. Preferred patterning methods include deposition through a mask, cold welding such as described in U.S. Pat. Nos. 6,294,398 and 6,468,819, which are incorporated by reference in their entireties, and patterning associated with some of the deposition methods such as ink-jet and OVJD. Other methods may also be used. The materials to be deposited may be modified to make them compatible with a particular deposition method. For example, substituents such as alkyl and aryl groups, branched or unbranched, and preferably containing at least 3 carbons, may be used in small molecules to enhance their ability to undergo solution processing. Substituents having 20 carbons or more may be used, and 3-20 carbons is a preferred range. Materials with asymmetric structures may have better solution processibility than those having symmetric structures, because asymmetric materials may have a lower tendency to recrystallize. Dendrimer substituents may be used to enhance the ability of small molecules to undergo solution processing.

Devices fabricated in accordance with embodiments of the present invention may further optionally comprise a barrier layer. One purpose of the barrier layer is to protect the electrodes and organic layers from damaging exposure to harmful species in the environment including moisture, vapor and/or gases, etc. The barrier layer may be deposited over, under or next to a substrate, an electrode, or over any other parts of a device including an edge. The barrier layer may comprise a single layer, or multiple layers. The barrier layer may be formed by various known chemical vapor deposition techniques and may include compositions having a single phase as well as compositions having multiple phases. Any suitable material or combination of materials may be used for the barrier layer. The barrier layer may incorporate an inorganic or an organic compound or both. The preferred barrier layer comprises a mixture of a polymeric material and a non-polymeric material as described in U.S. Pat. No. 7,968,146, PCT Pat. Application Nos. PCT/US2007/023098 and PCT/US2009/042829, which are herein incorporated by reference in their entireties. To be considered a “mixture”, the aforesaid polymeric and non-polymeric materials comprising the barrier layer should be deposited under the same reaction conditions and/or at the same time. The weight ratio of polymeric to non-polymeric material may be in the range of 95:5 to 5:95. The polymeric material and the non-polymeric material may be created from the same precursor material. In one example, the mixture of a polymeric material and a non-polymeric material consists essentially of polymeric silicon and inorganic silicon.

Devices fabricated in accordance with embodiments of the invention can be incorporated into a wide variety of electronic component modules (or units) that can be incorporated into a variety of electronic products or intermediate components. Examples of such electronic products or intermediate components include display screens, lighting devices such as discrete light source devices or lighting panels, etc. that can be utilized by the end-user product manufacturers. Such electronic component modules can optionally include the driving electronics and/or power source(s). Devices fabricated in accordance with embodiments of the invention can be incorporated into a wide variety of consumer products that have one or more of the electronic component modules (or units) incorporated therein. A consumer product comprising an OLED that includes the compound of the present disclosure in the organic layer in the OLED is disclosed. Such consumer products would include any kind of products that include one or more light source(s) and/or one or more of some type of visual displays. Some examples of such consumer products include flat panel displays, computer monitors, medical monitors, televisions, billboards, lights for interior or exterior illumination and/or signaling, heads-up displays, fully or partially transparent displays, flexible displays, laser printers, telephones, mobile phones, tablets, phablets, personal digital assistants (PDAs), wearable devices, laptop computers, digital cameras, camcorders, viewfinders, micro-displays (displays that are less than 2 inches diagonal), 3-D displays, virtual reality or augmented reality displays, vehicles, video walls comprising multiple displays tiled together, theater or stadium screen, and a sign. Various control mechanisms may be used to control devices fabricated in accordance with the present invention, including passive matrix and active matrix. Many of the devices are intended for use in a temperature range comfortable to humans, such as 18 C to 30 C, and more preferably at room temperature (20-25 C), but could be used outside this temperature range, for example, from −40 C to 80 C.

More details on OLEDs, and the definitions described above, can be found in U.S. Pat. No. 7,279,704, which is incorporated herein by reference in its entirety.

The materials and structures described herein may have applications in devices other than OLEDs. For example, other optoelectronic devices such as organic solar cells and organic photodetectors may employ the materials and structures. More generally, organic devices, such as organic transistors, may employ the materials and structures.

In some embodiments, the OLED has one or more characteristics selected from the group consisting of being flexible, being rollable, being foldable, being stretchable, and being curved. In some embodiments, the OLED is transparent or semi-transparent. In some embodiments, the OLED further comprises a layer comprising carbon nanotubes.

In some embodiments, the OLED further comprises a layer comprising a delayed fluorescent emitter. In some embodiments, the OLED comprises a RGB pixel arrangement or white plus color filter pixel arrangement. In some embodiments, the OLED is a mobile device, a hand held device, or a wearable device. In some embodiments, the OLED is a display panel having less than 10 inch diagonal or 50 square inch area. In some embodiments, the OLED is a display panel having at least 10 inch diagonal or 50 square inch area. In some embodiments, the OLED is a lighting panel.

In some embodiments, the compound can be an emissive dopant. In some embodiments, the compound can produce emissions via phosphorescence, fluorescence, thermally activated delayed fluorescence, i.e., TADF (also referred to as E-type delayed fluorescence; see, e.g., U.S. application Ser. No. 15/700,352, which is hereby incorporated by reference in its entirety), triplet-triplet annihilation, or combinations of these processes. In some embodiments, the emissive dopant can be a racemic mixture, or can be enriched in one enantiomer. In some embodiments, the compound can be homoleptic (each ligand is the same). In some embodiments, the compound can be heteroleptic (at least one ligand is different from others). When there are more than one ligand coordinated to a metal, the ligands can all be the same in some embodiments. In some other embodiments, at least one ligand is different from the other ligands. In some embodiments, every ligand can be different from each other. This is also true in embodiments where a ligand being coordinated to a metal can be linked with other ligands being coordinated to that metal to form a tridentate, tetradentate, pentadentate, or hexadentate ligands. Thus, where the coordinating ligands are being linked together, all of the ligands can be the same in some embodiments, and at least one of the ligands being linked can be different from the other ligand(s) in some other embodiments.

In some embodiments, the compound can be used as one component of an exciplex to be used as a sensitizer.

In some embodiments, the sensitizer is a single component, or one of the components to form an exciplex.

According to another aspect, a formulation comprising the compound described herein is also disclosed.

The OLED disclosed herein can be incorporated into one or more of a consumer product, an electronic component module, and a lighting panel. The organic layer can be an emissive layer and the compound can be an emissive dopant in some embodiments, while the compound can be a non-emissive dopant in other embodiments.

In some embodiments, the emissive layer comprises one or more quantum dots.

In yet another aspect of the present disclosure, a formulation that comprises the novel compound disclosed herein is described. The formulation can include one or more components selected from the group consisting of a solvent, a host, a hole injection material, hole transport material, electron blocking material, hole blocking material, and an electron transport material, disclosed herein.

The present disclosure encompasses any chemical structure comprising the novel compound of the present disclosure, or a monovalent or polyvalent variant thereof. In other words, the inventive compound, or a monovalent or polyvalent variant thereof, can be a part of a larger chemical structure. Such chemical structure can be selected from the group consisting of a monomer, a polymer, a macromolecule, and a supramolecule (also known as supermolecule). As used herein, a “monovalent variant of a compound” refers to a moiety that is identical to the compound except that one hydrogen has been removed and replaced with a bond to the rest of the chemical structure. As used herein, a “polyvalent variant of a compound” refers to a moiety that is identical to the compound except that more than one hydrogen has been removed and replaced with a bond or bonds to the rest of the chemical structure. In the instance of a supramolecule, the inventive compound can also be incorporated into the supramolecule complex without covalent bonds.

Conventional OLEDs typically have an optical outcoupling efficiency of around 20% or less. Most of the light is trapped in surface plasmon polariton modes (SPPs) at the metal electrode surface and in waveguide modes due to the high refractive index of organic materials and transparent electrodes. Conventional techniques to eliminate SPPs use a thick organic layer between the emissive layer(s) and a metal electrode. However, the thicker organic layers introduce more waveguided light, which results in little or no net change to the light extraction efficiency.

The exemplary device disclosed herein introduces a second host to balance the difference between hole transport and electron transport in the EML and on its boundaries. For devices using dopants with shallow lowest unoccupied molecular orbitals (LUMOs), the electron injection and electron transport are usually the bottleneck of detailed charge balance, leading to a high concentration of excitons and polarons near the interface of electron transporting layers (ETLs). The same can also happen when there are deep highest occupied molecular orbitals (HOMOs), and insufficient hole injection or transport. The aid of the second host can reduce the electron/hole barrier and increase the less balanced carrier mobility in the device.

Second, in this ternary layer a graded doping and/or graded host concentration is applied in the EML. The mobility of each carrier is controlled by the concentration of the electron transporting (ET) medium and the hole transporting (HT) medium. They are fitted to μ=αexp (Bc) cm²V⁻¹s⁻¹ from the hole/electron only devices (α, βare fitting parameters and c is the molecule concentration). The detailed charge balance and the exciton profile are simulated from the drift-diffusion model, and iterated by the sensing layer method, and the standard OLED characterization.

### Device Design

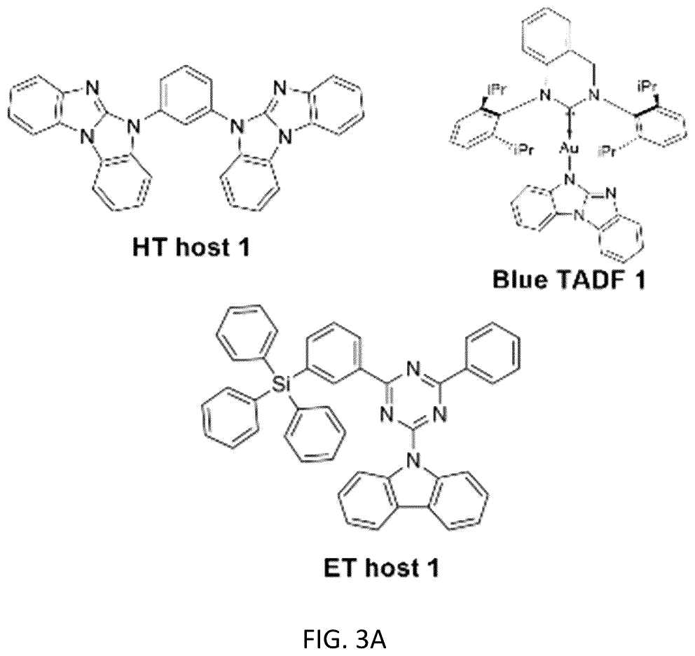

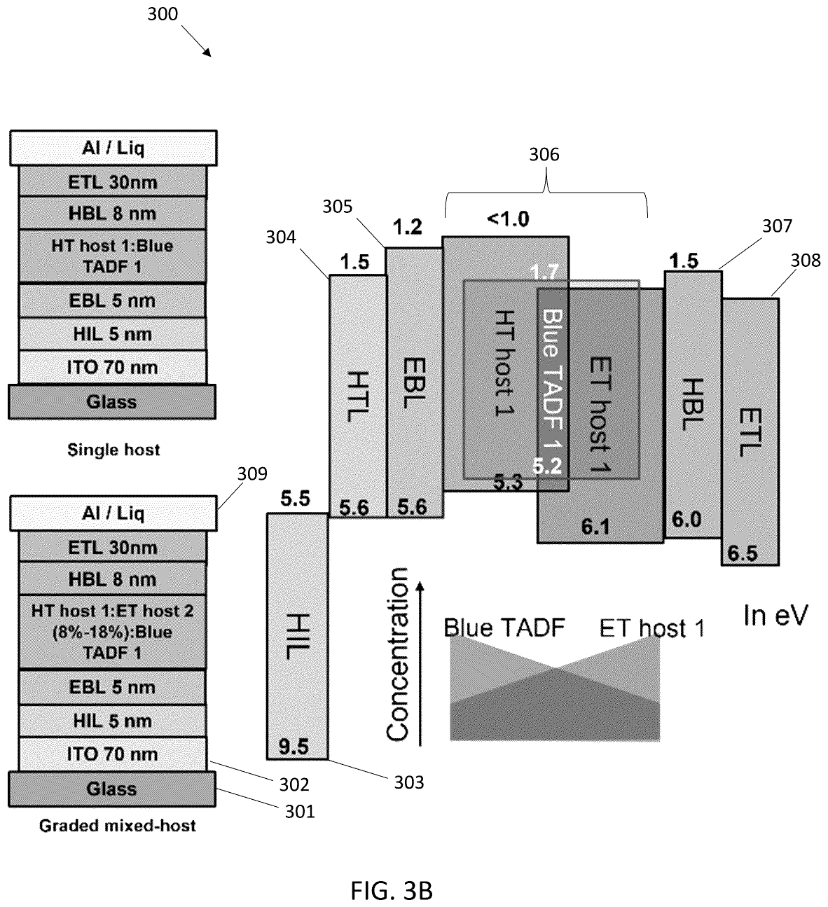

Referring now to FIGS. 3A-3B, in some embodiments, an organic light emitting device (OLED) 300 comprises a substrate 301, a first electrode 302 positioned over the substrate 301, a hole injection layer (HIL) 303 positioned over the first electrode 320, an emission layer (EML) 306 positioned over the HIL 303, comprising a graded host material graded in a first direction and a graded emitter material graded in a second direction which may be the same or different from the first direction, an electron transport layer (ETL) 308 positioned over the EML 306, and a second electrode 309 positioned over the ETL 308.

In some embodiments, the graded emitter material comprises a TADF emitter. In some embodiments, the TADF emitter comprises a blue TADF emitter. In some embodiments, the blue TADF emitter comprises a compound of Formula A:

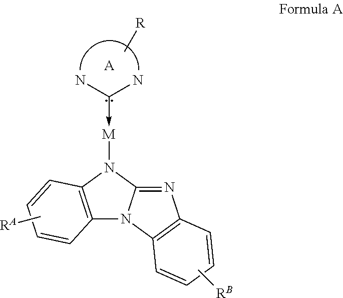

wherein, in Formula A,

M is a metal selected from the group consisting of Ag(I), Au(I), and Cu(I);

ring A is a carbene ligand;

R, R^{A}, and R^{B} represent mono to the maximum allowable substitution; and

each R, R^{A}, and R^{B} is independently hydrogen or a substituent selected from the group consisting of deuterium, halogen, alkyl, cycloalkyl, heteroalkyl, heterocycloalkyl, arylalkyl, alkoxy, aryloxy, amino, silyl, alkenyl, cycloalkenyl, heteroalkenyl, alkynyl, aryl, heteroaryl, nitrile, isonitrile, sulfanyl, boryl, acyl, carboxylic acid, ether, ester, sulfinyl, sulfonyl, cyano, phosphino, and combinations thereof; wherein any two adjacent R, R^{A}, and R^{B} are optionally joined or fused together to form a ring which is optionally substituted.

In some embodiments, ring A is represented by one of the following structures:

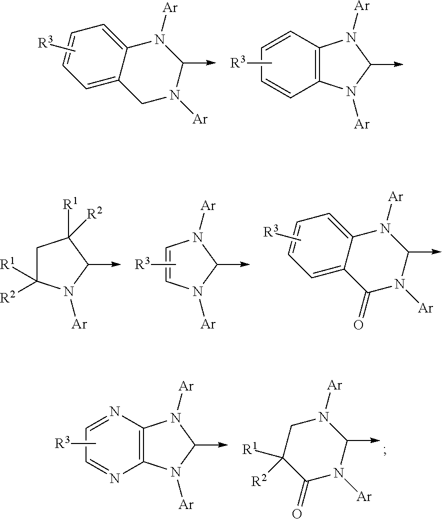

wherein each R¹, R², and R³ is independently selected from the group consisting of hydrogen, deuterium, halogen, pseudohalogen, alkyl, cycloalkyl, heteroalkyl, heterocycloalkyl, arylalkyl, alkoxy, aryloxy, amino, amide, hydroxyl, silyl, alkenyl, cycloalkenyl, heteroalkenyl, alkynyl, heteroalkynyl, aryl, heteroaryl, nitro, nitrile, isonitrile, sulfanyl, boryl, acyl, carboxylic acid, benzoyl, ether, ester, vinyl, ketone, sulfinyl, sulfonyl, cyano, phosphino, and combinations thereof; wherein any two adjacent substituents may together join to form a heteroaryl ring, an aryl ring, a cycloalkyl ring, or a bicyclic ring; and

wherein each Ar independently represents aryl or heteroaryl which is optionally further substituted with one or more substituents independently selected from the group consisting of hydrogen, deuterium, halogen, pseudohalogen, alkyl, cycloalkyl, heteroalkyl, heterocycloalkyl, arylalkyl, alkoxy, aryloxy, amino, amide, hydroxyl, silyl, alkenyl, cycloalkenyl, heteroalkenyl, alkynyl, heteroalkynyl, aryl, heteroaryl, nitro, nitrile, isonitrile, sulfanyl, boryl, acyl, carboxylic acid, benzoyl, ether, ester, vinyl, ketone, sulfinyl, sulfonyl, cyano, phosphino, and combinations thereof; wherein any two adjacent substituents may together join to form a ring.

In some embodiments, ring A is represented by one of the following structures:

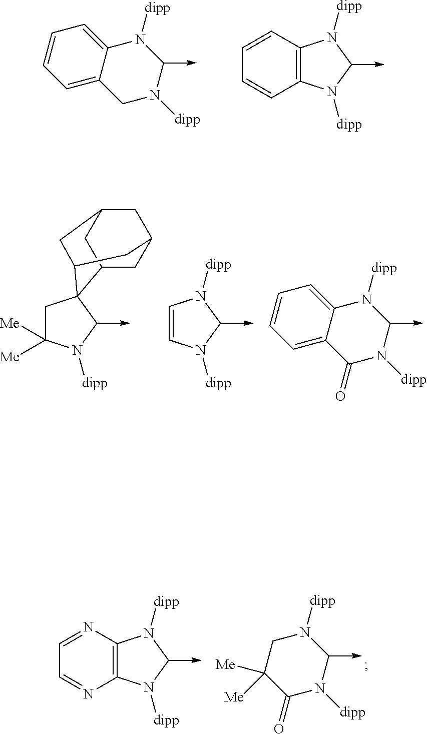

wherein dipp=2,6-disopropylphenyl.

In some embodiments, the blue TADF emitter comprises a compound having one of the following structures:

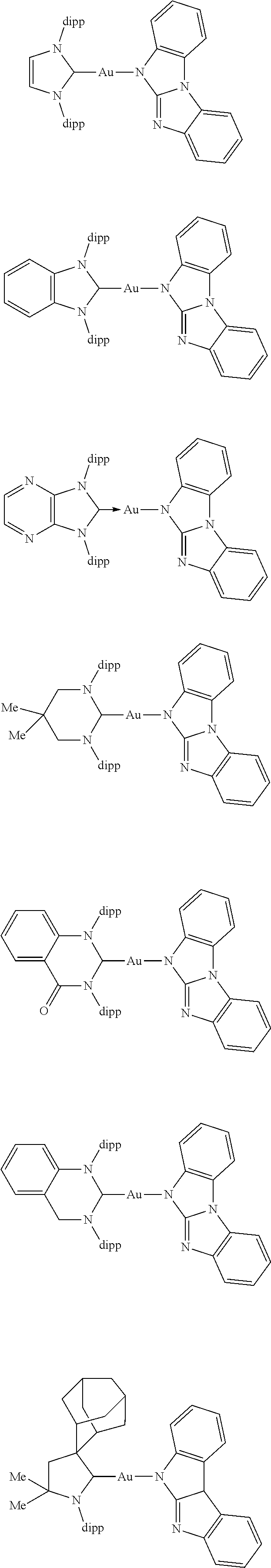

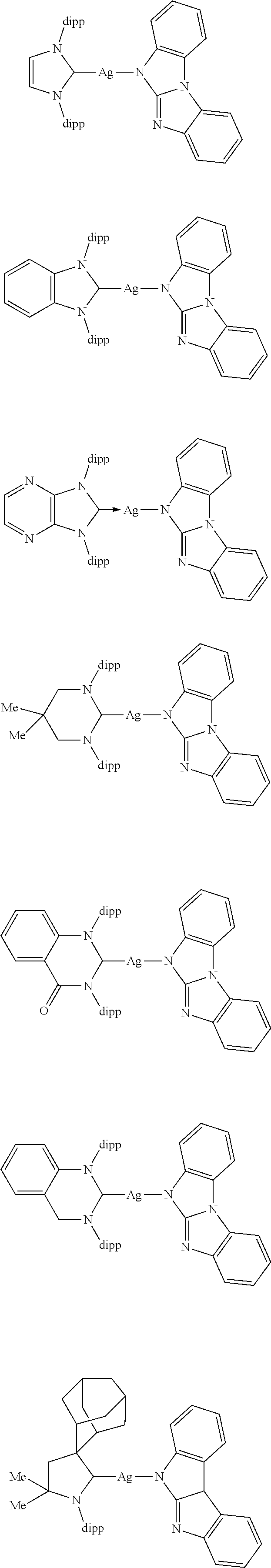

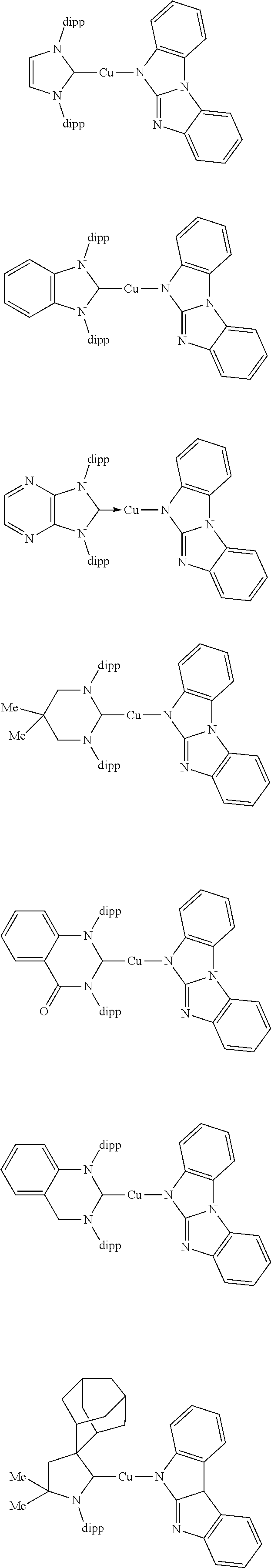

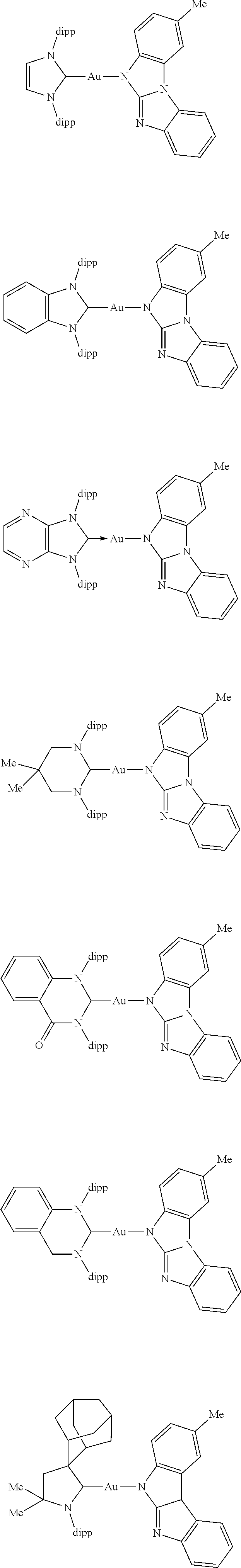

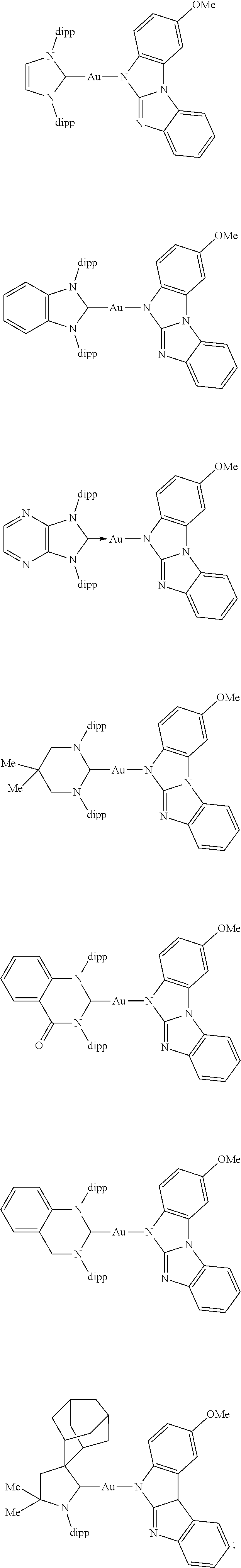

wherein dipp=2,6-disopropylphenyl.

In some embodiments, the blue TADF emitter comprises:

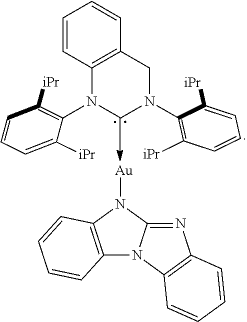

In some embodiments, the graded host material comprises an electron transport (ET) host. In some embodiments, the EML 306 further comprises a hole transport (HT) host.

In some embodiments, the graded host material is linearly graded from 18% to 8% from the HBL interface to the EBL interface. In some embodiments, the graded emitter material is linearly graded from 18% to 8% from the EBL interface to the HBL interface.

In some embodiments, the graded host material is linearly graded from 18% to 8% from the EBL interface to the HBL interface. In some embodiments, the graded emitter material is linearly graded from 18% to 8% from the HBL interface to the EBL interface.

In some embodiments, the EML 306 comprises oppositely graded cohost materials which may be doped with a TADF emitter. In some embodiments, the cohost materials are uniformly doped with the TADF emitter. In some embodiments, the TADF emitter is also graded. In some embodiments, the concentrations of the components of the EML 306 (i.e. host materials, emitter materials, TADF) equal 100% throughout the thickness of the EML 306.

In some embodiments, the grading of the host and/or emitter materials can be linear, parabolic, quadratic, stepwise, and/or follow a polynomial function of any order. In some embodiments, the grading of the host and/or emitter materials may be graded in a range from 0% to 100%, from 100% to 0%, from 0% to 50%, from 50% to 0%, from 20% to 80%, from 80% to 20%, or any other suitable grading percentages and/or rates.

In some embodiments, the device 300 further comprises an electron blocking layer (EBL) 305 positioned between the HIL 303 and the EML 306. In some embodiments, the device 300 further comprises a hole blocking layer (HBL) 307 positioned between the EML 306 and the ETL 308. In some embodiments, the device further comprises a hole transport layer (HTL) 304 positioned between the HIL 303 and the EBL 305.

In some embodiments, the first electrode 302 has a thickness of 50 nm to 100 nm. In some embodiments, the first electrode 302 comprises ITO. In some embodiments, the HIL 303 has thickness of 0.5 nm to 10 nm. In some embodiments, the ETL 308 has a thickness of 10 nm to 50 nm.

In some embodiments, the HT host is a first host compound comprising at least one chemical moiety selected from the group consisting of triphenylene, carbazole, indolocarbazole, dibenzothiphene, dibenzofuran, dibenzoselenophene, 5λ2-benzo[d]benzo[4,5]imidazo[3,2-a]imidazole, 5,9-dioxa-13b-boranaphtho[3,2,1-de]anthracene, triazine, boryl, silyl, aza-triphenylene, aza-carbazole, aza-indolocarbazole, aza-dibenzothiophene, aza-dibenzofuran, aza-dibenzoselenophene, aza-5 λ 2-benzo[d]benzo[4,5]imidazo[3,2-a]imidazole, and aza-(5,9-dioxa-13b-boranaphtho[3,2,1-de]anthracene).

In some embodiments, the ET host is a second host compound having the structure of Formula I:

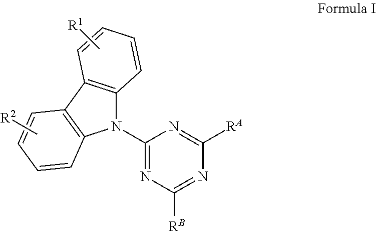

wherein, in Formula I, R^{A} and R^{B} are each independently selected from the group consisting of:

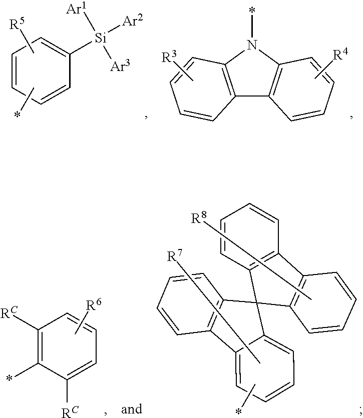

wherein * indicates the bond to Formula I; wherein each of R⁵ to R⁸ represent mono to the maximum number of substitution, or no substitution; Ar¹, Ar², and Ar³ are each an aryl or heteroaryl group, wherein the Ar¹, Ar², and Ar³ are each optionally further substituted with one or more substituents R^{D}; each R^{C}, R^{D}, and R¹ to R⁸ is independently a hydrogen or is selected from the group consisting of deuterium, halogen, alkyl, cycloalkyl, heteroalkyl, heterocycloalkyl, arylalkyl, alkoxy, aryloxy, amino, silyl, germyl, boryl, alkenyl, cycloalkenyl, heteroalkenyl, alkynyl, aryl, heteroaryl, acyl, carboxylic acid, ether, ester, nitrile, isonitrile, sulfanyl, selenyl, sulfinyl, sulfonyl, phosphino, and combinations thereof; and R¹ to R⁸ represent mono to the maximum number of substitution, or no substitution; each R¹ to R⁸ is independently a hydrogen or is selected from the group consisting of deuterium, halogen, alkyl, cycloalkyl, heteroalkyl, heterocycloalkyl, arylalkyl, alkoxy, aryloxy, amino, silyl, germyl, boryl, alkenyl, cycloalkenyl, heteroalkenyl, alkynyl, aryl, heteroaryl, acyl, carboxylic acid, ether, ester, nitrile, isonitrile, sulfanyl, selenyl, sulfinyl, sulfonyl, phosphino, and combinations thereof; and wherein any two adjacent substituents may join to form a ring.

In some embodiments, the LUMO of the EML is in the range of 0.1 to 2 eV, and/or the HOMO of the EML is in the range of 5 to 7 eV. In some embodiments, the hole/electron blocking layers (HBL, EBL) are used for exciton confinement.

In some embodiments, a method of manufacturing an organic light emitting device (OLED) comprises depositing a first electrode 302 over a substrate 301, depositing a hole injection layer (HIL) 303 positioned over the first electrode 302, depositing an emission layer (EML) 306 positioned over the HIL 303, wherein the EML 306 comprises a graded cohost or co-doped emission layer, depositing an electron transport layer (ETL) 308 positioned over the EML 306, and depositing a second electrode 309 positioned over the ETL 308.

In some embodiments, the method further comprises depositing an electron blocking layer (EBL) 305 positioned between the HIL 303 and the EML 306. In some embodiments, the method further comprises depositing a hole blocking layer (HBL) 307 positioned between the EML 306 and the ETL 308. In some embodiments, the method further comprises depositing a hole transport layer (HTL) 304 positioned between the HIL 303 and the EBL 305.

Devices of the present disclosure may comprise one or more electrodes, some of which may be fully or partially transparent or translucent. In some embodiments, one or more electrodes comprise indium tin oxide (ITO) or other transparent conductive materials. In some embodiments, one or more electrodes may comprise flexible transparent and/or conductive polymers.

Layers may include one or more electrodes, organic emissive layers, electron- or hole-blocking layers, electron- or hole-transport layers, buffer layers, or any other suitable layers known in the art. In some embodiments, one or more of the electrode layers may comprise a transparent flexible material. In some embodiments, both electrodes may comprise a flexible material and one electrode may comprise a transparent flexible material.

An OLED fabricated using devices and techniques disclosed herein may have one or more characteristics selected from the group consisting of being flexible, being rollable, being foldable, being stretchable, and being curved, and may be transparent or semi-transparent. In some embodiments, the OLED further comprises a layer comprising carbon nanotubes.

In some embodiments, an OLED fabricated using devices and techniques disclosed herein further comprises a layer comprising a delayed fluorescent emitter. In some embodiments, the OLED comprises a RGB pixel arrangement or white plus color filter pixel arrangement. In some embodiments, the OLED is a mobile device, a handheld device, or a wearable device. In some embodiments, the OLED is a display panel having less than 10 inch diagonal or 50 square inch area. In some embodiments, the OLED is a display panel having at least 10 inch diagonal or 50 square inch area. In some embodiments, the OLED is a lighting panel.

In some embodiments, the compound can be an emissive dopant. In some embodiments, the compound can produce emissions via phosphorescence, fluorescence, thermally activated delayed fluorescence, i.e., TADF (also referred to as E-type delayed fluorescence), triplet-triplet annihilation, or combinations of these processes.

An OLED fabricated according to techniques and devices disclosed herein can be incorporated into one or more of a consumer product, an electronic component module, and a lighting panel. The organic layer can be an emissive layer and the compound can be an emissive dopant in some embodiments, while the compound can be a non-emissive dopant in other embodiments.

The organic layer can also include a host. In some embodiments, two or more hosts are preferred. In some embodiments, the hosts used maybe a) bipolar, b) electron transporting, c) hole transporting or d) wide band gap materials that play little role in charge transport. In some embodiments, the host can include a metal complex. The host can be an inorganic compound. Further examples of materials which may be utilized for each layer of the device is described below.

In another aspect, the present disclosure also provides an OLED device comprising an anode, a cathode, and a first organic layer disposed between the anode and the cathode, wherein the first organic layer comprises a first host compound and a second host compound, wherein the first host compound comprises at least one chemical moiety selected from the group consisting of triphenylene, carbazole, indolocarbazole, dibenzothiphene, dibenzofuran, dibenzoselenophene, 5λ2-benzo[d]benzo[4,5]imidazo[3,2-a]imidazole, 5,9-dioxa-13b-boranaphtho[3,2,1-de]anthracene, triazine, boryl, silyl, aza-triphenylene, aza-carbazole, aza-indolocarbazole, aza-dibenzothiophene, aza-dibenzofuran, aza-dibenzoselenophene, aza-5 λ 2-benzo[d]benzo[4,5]imidazo[3,2-a]imidazole, and aza-(5,9-dioxa-13b-boranaphtho[3,2,1-de]anthracene), wherein the second host compound is a compound of Formula I:

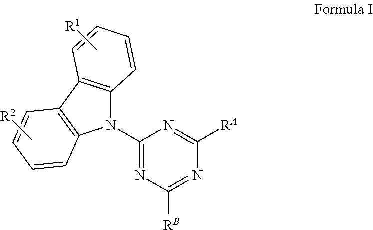

wherein, in Formula I, R^{A} and R^{B} independently represent alkyl, aryl, or heteroaryl which is optionally further substituted with a substituent selected from the group consisting of deuterium, halogen, alkyl, cycloalkyl, heteroalkyl, heterocycloalkyl, arylalkyl, alkoxy, aryloxy, amino, silyl, germyl, boryl, alkenyl, cycloalkenyl, heteroalkenyl, alkynyl, aryl, heteroaryl, acyl, carboxylic acid, ether, ester, nitrile, isonitrile, sulfanyl, selenyl, sulfinyl, sulfonyl, phosphino, and combinations thereof, R¹ to R⁴ represent mono to the maximum number of substitution, or no substitution, each R¹ to R⁴ is independently a hydrogen or is selected from the group consisting of deuterium, halogen, alkyl, cycloalkyl, heteroalkyl, heterocycloalkyl, arylalkyl, alkoxy, aryloxy, amino, silyl, germyl, boryl, alkenyl, cycloalkenyl, heteroalkenyl, alkynyl, aryl, heteroaryl, acyl, carboxylic acid, ether, ester, nitrile, isonitrile, sulfanyl, selenyl, sulfinyl, sulfonyl, phosphino, and combinations thereof, and wherein any two adjacent substituents may join to form a ring.

In some embodiments, R^{A} and R^{B} are each independently selected from the group consisting of:

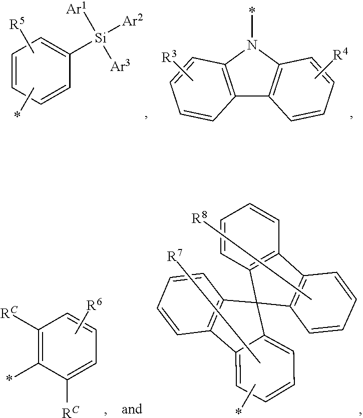

wherein * indicates the bond to Formula I, wherein each of R⁵ to R⁸ represent mono to the maximum number of substitution, or no substitution, Ar¹, Ar², and Ar³ are each an aryl or heteroaryl group, wherein the Ar¹, Ar², and Ar³ are each optionally further substituted with one or more substituents R^{D}, each R^{C}, R^{D}, and R⁵ to R⁸ is independently a hydrogen or is selected from the group consisting of deuterium, halogen, alkyl, cycloalkyl, heteroalkyl, heterocycloalkyl, arylalkyl, alkoxy, aryloxy, amino, silyl, germyl, boryl, alkenyl, cycloalkenyl, heteroalkenyl, alkynyl, aryl, heteroaryl, acyl, carboxylic acid, ether, ester, nitrile, isonitrile, sulfanyl, selenyl, sulfinyl, sulfonyl, phosphino, and combinations thereof, and wherein any two adjacent substituents may join to form a ring.

In some embodiments, the first organic layer may be an emissive layer that comprises a phosphorescent emitter.

In some embodiments, the phosphorescent emitter may be a transition metal complex having a formula of M(L_{A})ₚ(L_{B})_{q}(L_{C})ᵣ wherein L_{A}, L_{B}, and L_{C} are each a bidentate ligand, and wherein p is 1, 2, or 3, q is 0, 1, or 2, r is 0, 1, or 2, and p+q+r is the oxidation state of the metal M.

In some embodiments, the phosphorescent emitter has a formula selected from the group consisting of Ir(L_{A})₃, Ir(L_{A})(L_{B})₂, Ir(L_{A})₂(L_{B}), Ir(L_{A})₂(L_{C}), and Ir(L_{A})(L_{B})(L_{C}), wherein L_{A}, L_{B}, and L_{C} are different from each other.

In some embodiments, the phosphorescent emitter has a formula of Pt(LA)(LB), wherein L_{A} and L_{B} can be same or different.

In some embodiments, L_{A} and L_{B} are connected to form a tetradentate ligand.

In some embodiments, L_{A}, L_{B}, and L_{C} are independently selected from the group consisting of:

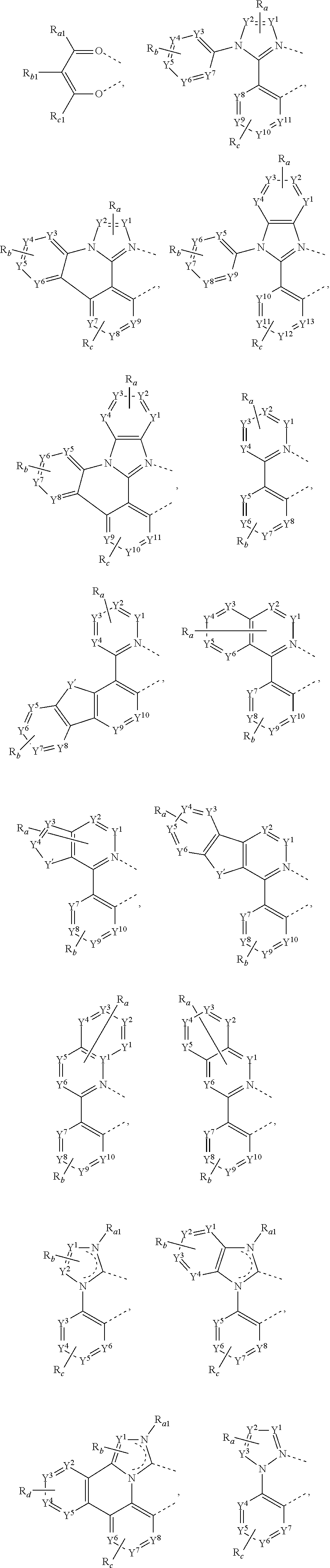

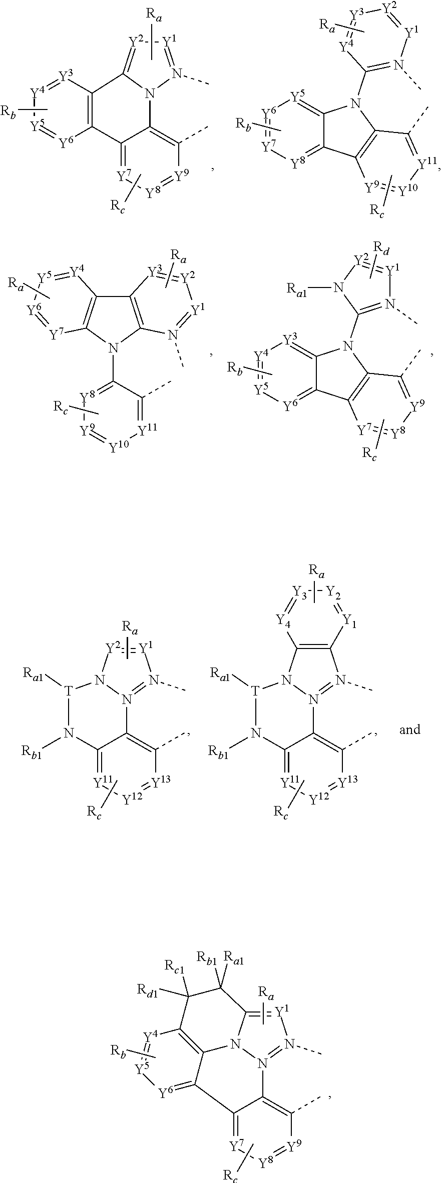

Wherein T is selected from the group consisting of B, Al, Ga, and In, each of Y¹ to Y¹³ is independently selected from the group consisting of carbon and nitrogen, Y′ is selected from the group consisting of BRₑ, BRₑR_{f}, NRₑ, PRₑ, P(O)Rₑ, O, S, Se, C═O, C═S, C═Se, C═NRₑ, C═CRₑR_{f}, S═O, SO₂, CRₑR_{f}, SiRₑR_{f}, and GeRₑR_{f}, Rₑ and R_{f} can be fused or joined to form a ring, each Rₐ, R_{b}, R_{c}, and R_{d} independently represent zero, mono, or up to a maximum allowed number of substitutions to its associated ring, each of Rₐ₁, R_{b1}, R_{c1}, R_{d1}, Rₐ, R_{b}, R_{c}, R_{d}, Rₑ and R_{f} is independently a hydrogen or a subsituent selected from the group consisting of deuterium, halide, alkyl, cycloalkyl, heteroalkyl, arylalkyl, alkoxy, aryloxy, amino, silyl, boryl, alkenyl, cycloalkenyl, heteroalkenyl, alkynyl, aryl, heteroaryl, acyl, carbonyl, carboxylic acid, ester, nitrile, isonitrile, sulfanyl, sulfinyl, sulfonyl, phosphino, and combinations thereof, the general substituents defined herein, and any two adjacent substituents of Rₐ, R_{b}, R_{c}, R_{d}, Rₑ and R_{f} can be fused or joined to form a ring or form a multidentate ligand.

In some embodiments, L_{A}, L_{B}, and L_{C} are each independently selected from the group consisting of:

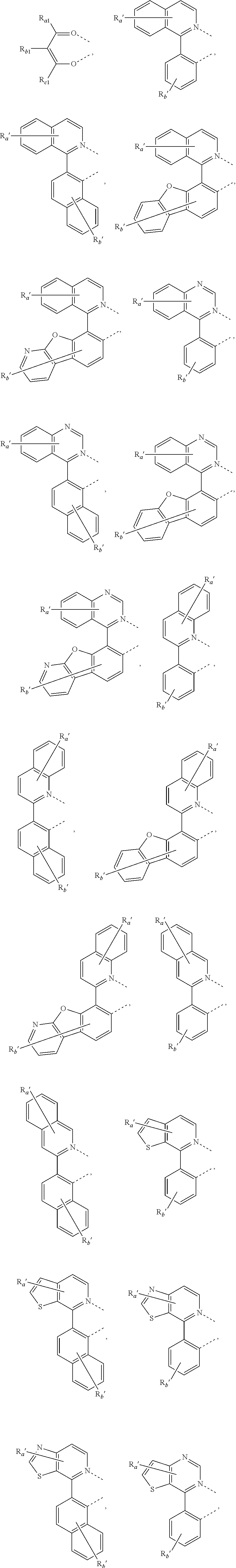

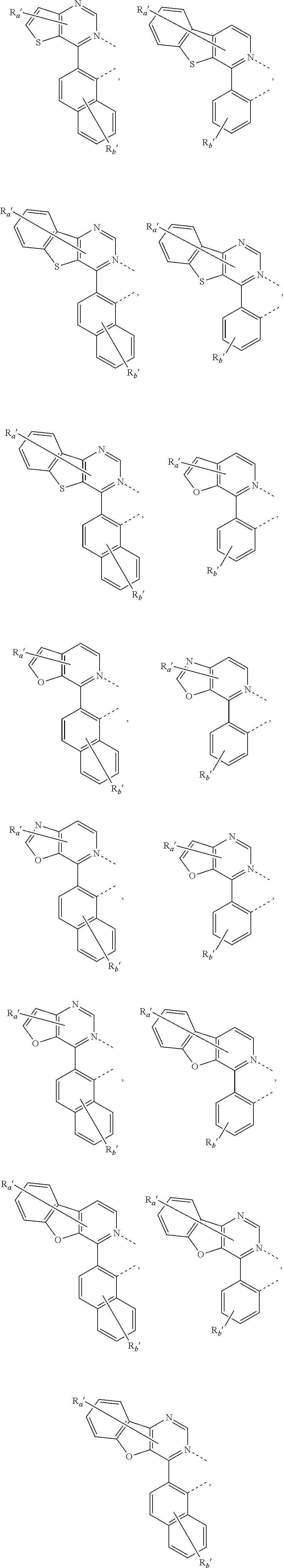

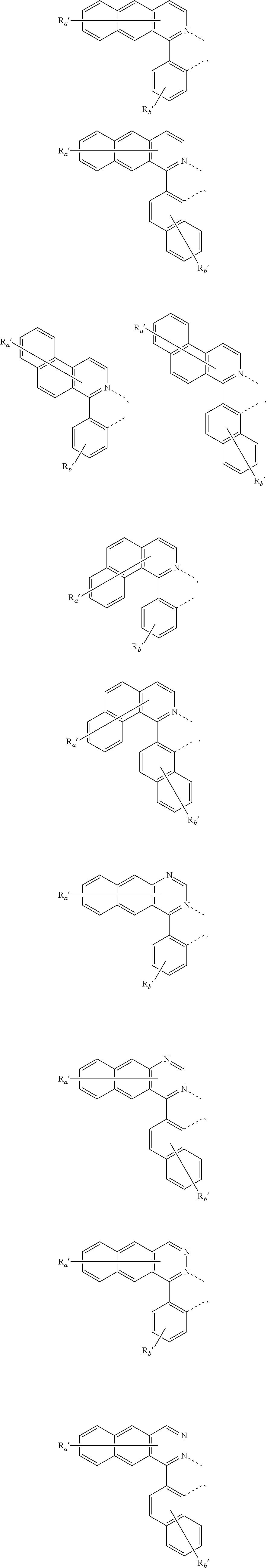

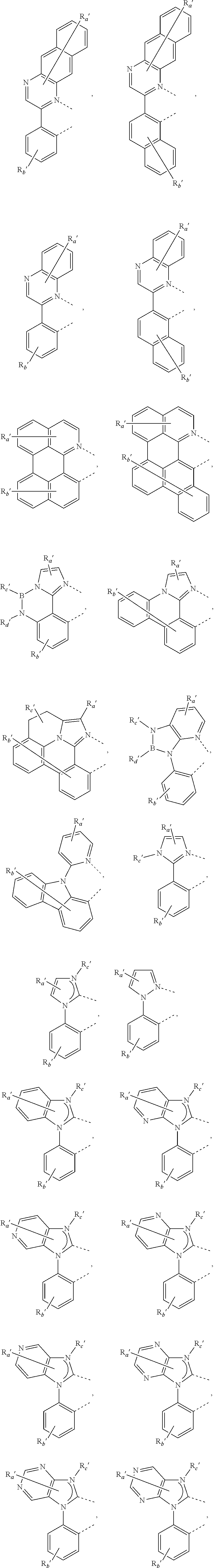

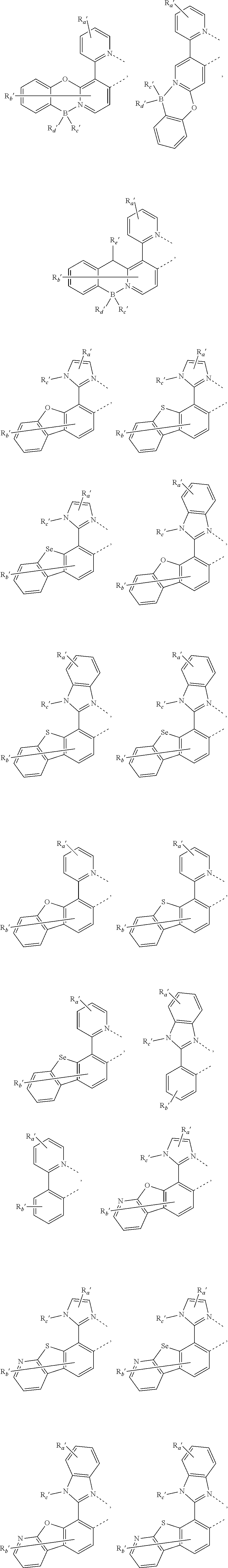

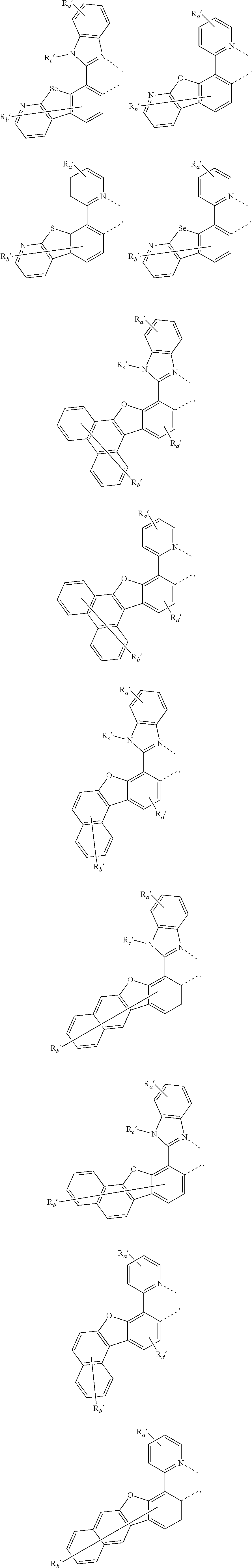

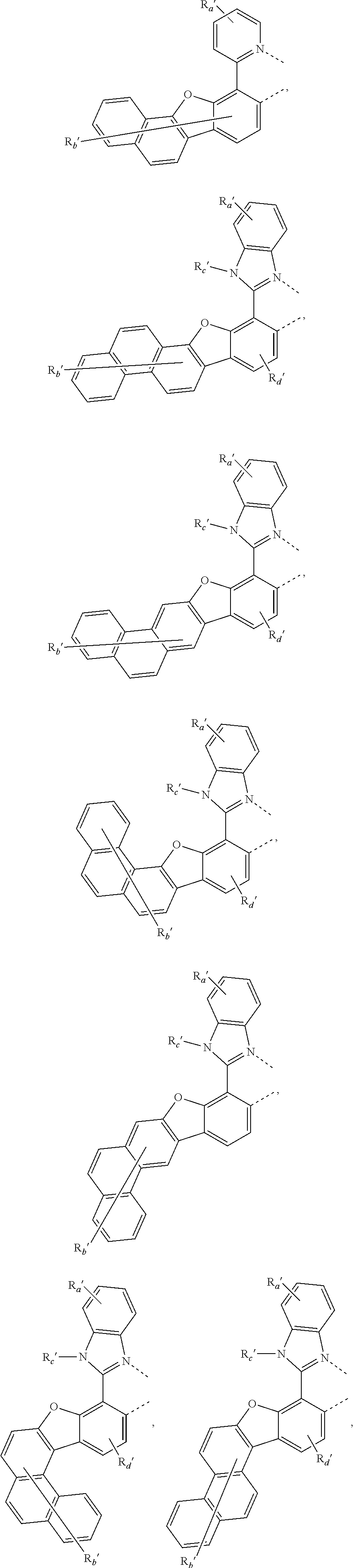

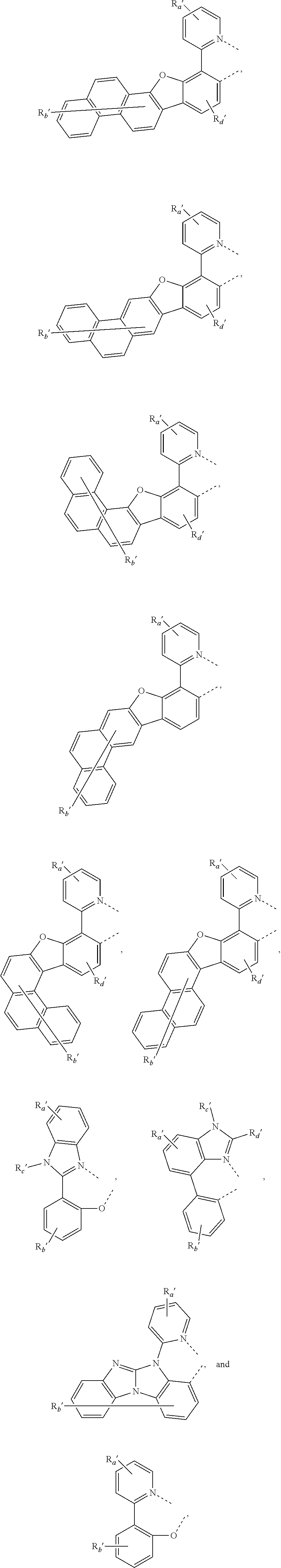

wherein Rₐ′, R_{b}′, R_{c}′, R_{d}′, and Rₑ′ each independently represents zero, mono, or up to a maximum allowed number of substitution to its associated ring, Rₐ′, R_{b}′, R_{c}′, R_{d}′, and Rₑ′ each independently hydrogen or a substituent selected from the group consisting of deuterium, halide, alkyl, cycloalkyl, heteroalkyl, arylalkyl, alkoxy, aryloxy, amino, silyl, boryl, alkenyl, cycloalkenyl, heteroalkenyl, alkynyl, aryl, heteroaryl, acyl, carbonyl, carboxylic acid, ester, nitrile, isonitrile, sulfanyl, sulfinyl, sulfonyl, phosphino, boryl, and combinations thereof, and two substituents of Rₐ′, R_{b}′, R_{c}′, R_{d}′, and Rₑ′ can be fused or joined to form a ring or form a multidentate ligand.

In some embodiments, the compound may be an acceptor, and the OLED may further comprise a sensitizer selected from the group consisting of a delayed fluorescence emitter, a phosphorescent emitter, and combination thereof.

In some embodiments, the compound may be a fluorescent emitter, a delayed fluorescence emitter, or a component of an exciplex that is a fluorescent emitter or a delayed fluorescence emitter.

In yet another aspect, the OLED of the present disclosure may also comprise an emissive region containing a compound as disclosed in the above compounds section of the present disclosure.

In some embodiments, the emissive region can comprise the first host compound and the second host compound as described elsewhere herein.

In some embodiments, at least one of the anode, the cathode, or a new layer disposed over the organic emissive layer functions as an enhancement layer. The enhancement layer comprises a plasmonic material exhibiting surface plasmon resonance that non-radiatively couples to the emitter material and transfers excited state energy from the emitter material to non-radiative mode of surface plasmon polariton. The enhancement layer is provided no more than a threshold distance away from the organic emissive layer, wherein the emitter material has a total non-radiative decay rate constant and a total radiative decay rate constant due to the presence of the enhancement layer and the threshold distance is where the total non-radiative decay rate constant is equal to the total radiative decay rate constant. In some embodiments, the OLED further comprises an outcoupling layer. In some embodiments, the outcoupling layer is disposed over the enhancement layer on the opposite side of the organic emissive layer. In some embodiments, the outcoupling layer is disposed on opposite side of the emissive layer from the enhancement layer but still outcouples energy from the surface plasmon mode of the enhancement layer. The outcoupling layer scatters the energy from the surface plasmon polaritons. In some embodiments this energy is scattered as photons to free space. In other embodiments, the energy is scattered from the surface plasmon mode into other modes of the device such as but not limited to the organic waveguide mode, the substrate mode, or another waveguiding mode. If energy is scattered to the non-free space mode of the OLED other outcoupling schemes could be incorporated to extract that energy to free space. In some embodiments, one or more intervening layer can be disposed between the enhancement layer and the outcoupling layer. The examples for interventing layer(s) can be dielectric materials, including organic, inorganic, perovskites, oxides, and may include stacks and/or mixtures of these materials.

The enhancement layer modifies the effective properties of the medium in which the emitter material resides resulting in any or all of the following: a decreased rate of emission, a modification of emission line-shape, a change in emission intensity with angle, a change in the stability of the emitter material, a change in the efficiency of the OLED, and reduced efficiency roll-off of the OLED device. Placement of the enhancement layer on the cathode side, anode side, or on both sides results in OLED devices which take advantage of any of the above-mentioned effects. In addition to the specific functional layers mentioned herein and illustrated in the various OLED examples shown in the figures, the OLEDs according to the present disclosure may include any of the other functional layers often found in OLEDs.

The enhancement layer can be comprised of plasmonic materials, optically active metamaterials, or hyperbolic metamaterials. As used herein, a plasmonic material is a material in which the real part of the dielectric constant crosses zero in the visible or ultraviolet region of the electromagnetic spectrum. In some embodiments, the plasmonic material includes at least one metal. In such embodiments the metal may include at least one of Ag, Al, Au, Ir, Pt, Ni, Cu, W, Ta, Fe, Cr, Mg, Ga, Rh, Ti, Ru, Pd, In, Bi, Ca alloys or mixtures of these materials, and stacks of these materials. In general, a metamaterial is a medium composed of different materials where the medium as a whole acts differently than the sum of its material parts. In particular, we define optically active metamaterials as materials which have both negative permittivity and negative permeability. Hyperbolic metamaterials, on the other hand, are anisotropic media in which the permittivity or permeability are of different sign for different spatial directions. Optically active metamaterials and hyperbolic metamaterials are strictly distinguished from many other photonic structures such as Distributed Bragg Reflectors (“DBRs”) in that the medium should appear uniform in the direction of propagation on the length scale of the wavelength of light. Using terminology that one skilled in the art can understand: the dielectric constant of the metamaterials in the direction of propagation can be described with the effective medium approximation. Plasmonic materials and metamaterials provide methods for controlling the propagation of light that can enhance OLED performance in a number of ways.

In some embodiments, the enhancement layer is provided as a planar layer. In other embodiments, the enhancement layer has wavelength-sized features that are arranged periodically, quasi-periodically, or randomly, or sub-wavelength-sized features that are arranged periodically, quasi-periodically, or randomly. In some embodiments, the wavelength-sized features and the sub-wavelength-sized features have sharp edges.

In some embodiments, the outcoupling layer has wavelength-sized features that are arranged periodically, quasi-periodically, or randomly, or sub-wavelength-sized features that are arranged periodically, quasi-periodically, or randomly. In some embodiments, the outcoupling layer may be composed of a plurality of nanoparticles and in other embodiments the outcoupling layer is composed of a pluraility of nanoparticles disposed over a material. In these embodiments the outcoupling may be tunable by at least one of varying a size of the plurality of nanoparticles, varying a shape of the plurality of nanoparticles, changing a material of the plurality of nanoparticles, adjusting a thickness of the material, changing the refractive index of the material or an additional layer disposed on the plurality of nanoparticles, varying a thickness of the enhancement layer , and/or varying the material of the enhancement layer. The plurality of nanoparticles of the device may be formed from at least one of metal, dielectric material, semiconductor materials, an alloy of metal, a mixture of dielectric materials, a stack or layering of one or more materials, and/or a core of one type of material and that is coated with a shell of a different type of material. In some embodiments, the outcoupling layer is composed of at least metal nanoparticles wherein the metal is selected from the group consisting of Ag, Al, Au, Ir, Pt, Ni, Cu, W, Ta, Fe, Cr, Mg, Ga, Rh, Ti, Ru, Pd, In, Bi, Ca, alloys or mixtures of these materials, and stacks of these materials. The plurality of nanoparticles may have additional layer disposed over them. In some embodiments, the polarization of the emission can be tuned using the outcoupling layer. Varying the dimensionality and periodicity of the outcoupling layer can select a type of polarization that is preferentially outcoupled to air. In some embodiments the outcoupling layer also acts as an electrode of the device.

In yet another aspect, the present disclosure also provides a consumer product comprising an organic light-emitting device (OLED) having an anode, a cathode, and an organic layer disposed between the anode and the cathode, wherein the organic layer may comprise a compound as disclosed in the above compounds section of the present disclosure.

In some embodiments, the consumer product comprises an organic light-emitting device (OLED) having an anode, a cathode, and an organic layer disposed between the anode and the cathode, wherein the organic layer may comprise the first compound and the second compound as described herein.

In some embodiments, the consumer product can be one of a flat panel display, a computer monitor, a medical monitor, a television, a billboard, a light for interior or exterior illumination and/or signaling, a heads-up display, a fully or partially transparent display, a flexible display, a laser printer, a telephone, a cell phone, tablet, a phablet, a personal digital assistant (PDA), a wearable device, a laptop computer, a digital camera, a camcorder, a viewfinder, a micro-display that is less than 2 inches diagonal, a 3-D display, a virtual reality or augmented reality display, a vehicle, a video wall comprising multiple displays tiled together, a theater or stadium screen, a light therapy device, and a sign.

Generally, an OLED comprises at least one organic layer disposed between and electrically connected to an anode and a cathode. When a current is applied, the anode injects holes and the cathode injects electrons into the organic layer(s). The injected holes and electrons each migrate toward the oppositely charged electrode. When an electron and hole localize on the same molecule, an “exciton,” which is a localized electron-hole pair having an excited energy state, is formed. Light is emitted when the exciton relaxes via a photoemissive mechanism. In some cases, the exciton may be localized on an excimer or an exciplex. Non-radiative mechanisms, such as thermal relaxation, may also occur, but are generally considered undesirable.

Several OLED materials and configurations are described in U.S. Pat. Nos. 5,844,363, 6,303,238, and 5,707,745, which are incorporated herein by reference in their entirety.

The initial OLEDs used emissive molecules that emitted light from their singlet states (“fluorescence”) as disclosed, for example, in U.S. Pat. No. 4,769,292, which is incorporated by reference in its entirety. Fluorescent emission generally occurs in a time frame of less than 10 nanoseconds.

More recently, OLEDs having emissive materials that emit light from triplet states (“phosphorescence”) have been demonstrated. Baldo et al., “Highly Efficient Phosphorescent Emission from Organic Electroluminescent Devices,” Nature, vol. 395, 151-154, 1998; (“Baldo-I”) and Baldo et al., “Very high-efficiency green organic light-emitting devices based on electrophosphorescence,” Appl. Phys. Lett., vol. 75, No. 3, 4-6 (1999) (“Baldo-II”), are incorporated by reference in their entireties. Phosphorescence is described in more detail in U.S. Pat. No. 7,279,704 at cols. 5-6, which are incorporated by reference.

### Combination with Other Materials

The materials described herein as useful for a particular layer in an organic light emitting device may be used in combination with a wide variety of other materials present in the device. For example, emissive dopants disclosed herein may be used in conjunction with a wide variety of hosts, transport layers, blocking layers, injection layers, electrodes and other layers that may be present. The materials described or referred to below are non-limiting examples of materials that may be useful in combination with the compounds disclosed herein, and one of skill in the art can readily consult the literature to identify other materials that may be useful in combination.

Various materials may be used for the various emissive and non-emissive layers and arrangements disclosed herein. Examples of suitable materials are disclosed in U.S. Patent Application Publication No. 2017/0229663, which is incorporated by reference in its entirety.

### Conductivity Dopants

A charge transport layer can be doped with conductivity dopants to substantially alter its density of charge carriers, which will in turn alter its conductivity. The conductivity is increased by generating charge carriers in the matrix material, and depending on the type of dopant, a change in the Fermi level of the semiconductor may also be achieved. Hole-transporting layer can be doped by p-type conductivity dopants and n-type conductivity dopants are used in the electron-transporting layer.

Non-limiting examples of the conductivity dopants that may be used in an OLED in combination with materials disclosed herein are exemplified below together with references that disclose those materials: EP01617493, EP01968131, EP2020694, EP2684932, US20050139810, US20070160905, US20090167167, US2010288362, WO06081780, WO2009003455, WO2009008277, WO2009011327, WO2014009310, US2007252140, US2015060804, US20150123047, and US2012146012.

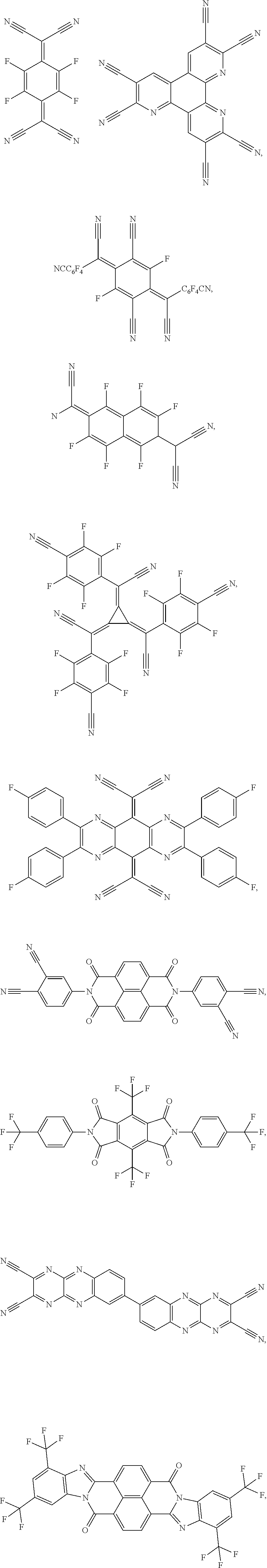

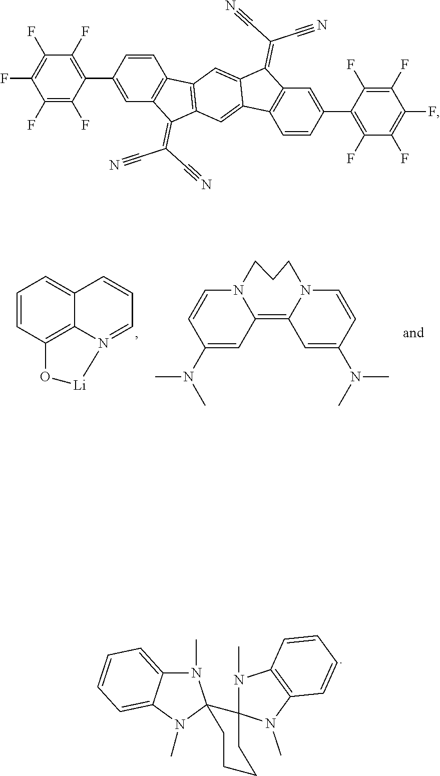

### HIL/HTL

A hole injecting/transporting material to be used in the present disclosure is not particularly limited, and any compound may be used as long as the compound is typically used as a hole injecting/transporting material. Examples of the material include, but are not limited to: a phthalocyanine or porphyrin derivative, an aromatic amine derivative, an indolocarbazole derivative, a polymer containing fluorohydrocarbon, a polymer with conductivity dopants, a conducting polymer, such as PEDOT/PSS, a self-assembly monomer derived from compounds such as phosphonic acid and silane derivatives, a metal oxide derivative, such as MoOₓ, a p-type semiconducting organic compound, such as 1,4,5,8,9,12-Hexaazatriphenylenehexacarbonitrile, a metal complex, and a cross-linkable compounds.

Examples of aromatic amine derivatives used in HIL or HTL include, but not limit to the following general structures:

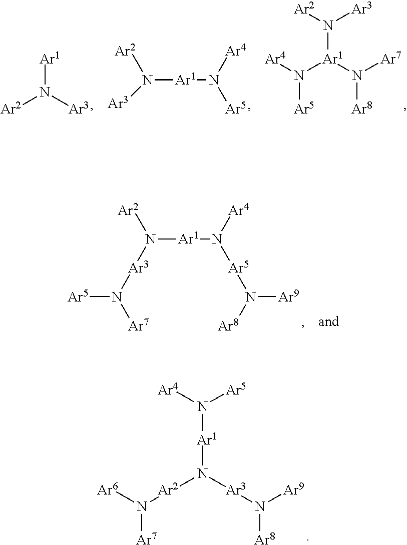

Each of Ar¹ to Ar⁹ is selected from the group consisting of aromatic hydrocarbon cyclic compounds such as benzene, biphenyl, triphenyl, triphenylene, naphthalene, anthracene, phenalene, phenanthrene, fluorene, pyrene, chrysene, perylene, and azulene, the group consisting of aromatic heterocyclic compounds such as dibenzothiophene, dibenzofuran, dibenzoselenophene, furan, thiophene, benzofuran, benzothiophene, benzoselenophene, carbazole, indolocarbazole, pyridylindole, pyrrolodipyridine, pyrazole, imidazole, triazole, oxazole, thiazole, oxadiazole, oxatriazole, dioxazole, thiadiazole, pyridine, pyridazine, pyrimidine, pyrazine, triazine, oxazine, oxathiazine, oxadiazine, indole, benzimidazole, indazole, indoxazine, benzoxazole, benzisoxazole, benzothiazole, quinoline, isoquinoline, cinnoline, quinazoline, quinoxaline, naphthyridine, phthalazine, pteridine, xanthene, acridine, phenazine, phenothiazine, phenoxazine, benzofuropyridine, furodipyridine, benzothienopyridine, thienodipyridine, benzoselenophenopyridine, and selenophenodipyridine, and the group consisting of 2 to 10 cyclic structural units which are groups of the same type or different types selected from the aromatic hydrocarbon cyclic group and the aromatic heterocyclic group and are bonded to each other directly or via at least one of oxygen atom, nitrogen atom, sulfur atom, silicon atom, phosphorus atom, boron atom, chain structural unit and the aliphatic cyclic group. Each Ar may be unsubstituted or may be substituted by a substituent selected from the group consisting of deuterium, halogen, alkyl, cycloalkyl, heteroalkyl, heterocycloalkyl, arylalkyl, alkoxy, aryloxy, amino, silyl, alkenyl, cycloalkenyl, heteroalkenyl, alkynyl, aryl, heteroaryl, acyl, carboxylic acids, ether, ester, nitrile, isonitrile, sulfanyl, sulfinyl, sulfonyl, phosphino, and combinations thereof.

In one aspect, Ar¹ to Ar⁹ is independently selected from the group consisting of:

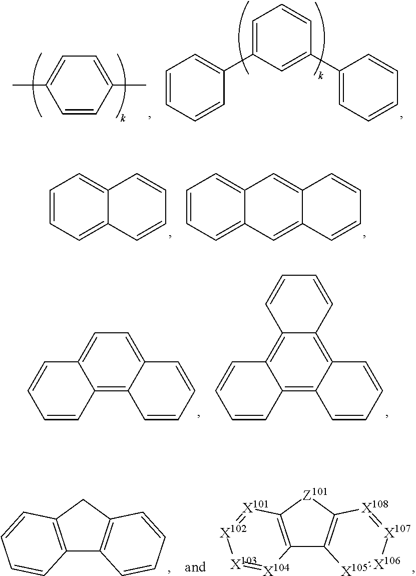

wherein k is an integer from 1 to 20, X¹⁰¹ to X¹⁰⁸ is C (including CH) or N, Z¹⁰¹ is NAr¹, O, or S, Ar¹ has the same group defined above.

Examples of metal complexes used in HIL or HTL include, but are not limited to the following general formula:

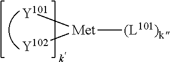

wherein Met is a metal, which can have an atomic weight greater than 40, (Y¹⁰¹-Y¹⁰²) is a bidentate ligand, Y¹⁰¹ and Y¹⁰² are independently selected from C, N, O, P, and S, L¹⁰¹ is an ancillary ligand, k′ is an integer value from 1 to the maximum number of ligands that may be attached to the metal, and k′+k″ is the maximum number of ligands that may be attached to the metal.

In one aspect, (Y¹⁰¹-Y¹⁰²) is a 2-phenylpyridine derivative. In another aspect, (Y¹⁰¹-Y¹⁰²) is a carbene ligand. In another aspect, Met is selected from Ir, Pt, Os, and Zn. In a further aspect, the metal complex has a smallest oxidation potential in solution vs. Fc⁺/Fc couple less than about 0.6 V.

Non-limiting examples of the HIL and HTL materials that may be used in an OLED in combination with materials disclosed herein are exemplified below together with references that disclose those materials: CN102702075, DE102012005215, EP01624500, EP01698613, EP01806334, EP01930964, EP01972613, EP01997799, EP02011790, EP02055700, EP02055701, EP1725079, EP2085382, EP2660300, EP650955, JP07-073529, JP2005112765, JP2007091719, JP2008021687, JP2014-009196, KR20110088898, KR20130077473, TW201139402, US06517957, US20020158242, US20030162053, US20050123751, US20060182993, US20060240279, US20070145888, US20070181874, US20070278938, US20080014464, US20080091025, US20080106190, US20080124572, US20080145707, US20080220265, US20080233434, US20080303417, US2008107919, US20090115320, US20090167161, US2009066235, US2011007385, US20110163302, US2011240968, US2011278551, US2012205642, US2013241401, US20140117329, US2014183517, U.S. Pat. Nos. 5,061,569, 5,639,914, WO05075451, WO07125714, WO08023550, WO08023759, WO2009145016, WO2010061824, WO2011075644, WO2012177006, WO2013018530, WO2013039073, WO2013087142, WO2013118812, WO2013120577, WO2013157367, WO2013175747, WO2014002873, WO2014015935, WO2014015937, WO2014030872, WO2014030921, WO2014034791, WO2014104514, WO2014157018.

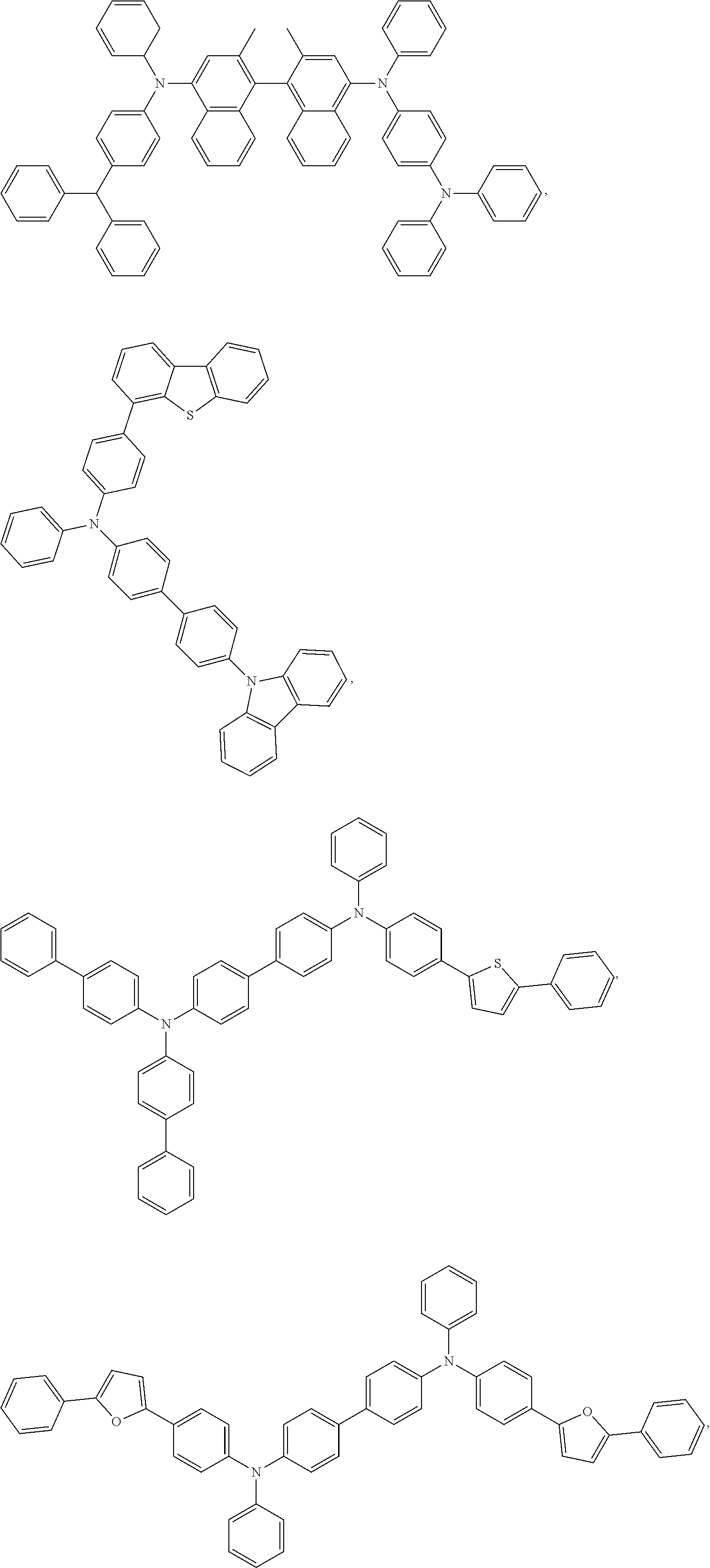 [SMILES: Cc1cc(N(c2ccccc2)c2ccc(N(c3ccccc3)c3ccccc3)cc2)c2ccccc2c1-c1c(C)cc(N(c2ccc(C(c3ccccc3)c3ccccc3)cc2)C2C=CC=CC2)c2ccccc12 ; c1ccc(N(c2ccc(-c3ccc(-n4c5ccccc5c5ccccc54)cc3)cc2)c2ccc(-c3cccc4c3sc3ccccc34)cc2)cc1 ; c1ccc(-c2ccc(N(c3ccc(-c4ccccc4)cc3)c3ccc(-c4ccc(N(c5ccccc5)c5ccc(-c6ccc(-c7ccccc7)s6)cc5)cc4)cc3)cc2)cc1 ; c1ccc(-c2ccc(-c3ccc(N(c4ccccc4)c4ccc(-c5ccc(N(c6ccccc6)c6ccc(-c7ccc(-c8ccccc8)o7)cc6)cc5)cc4)cc3)o2)cc1]

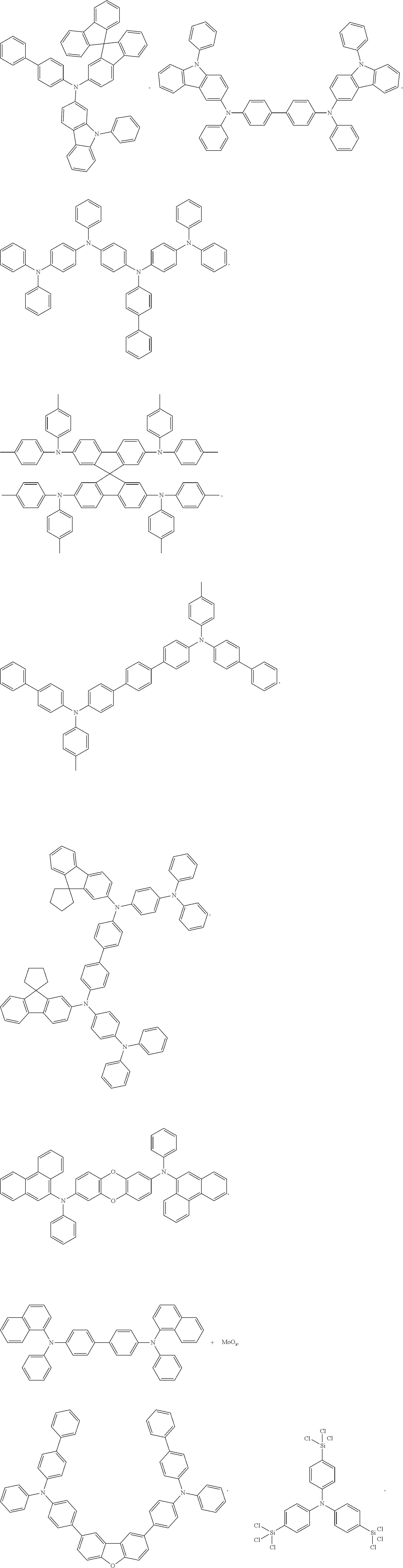

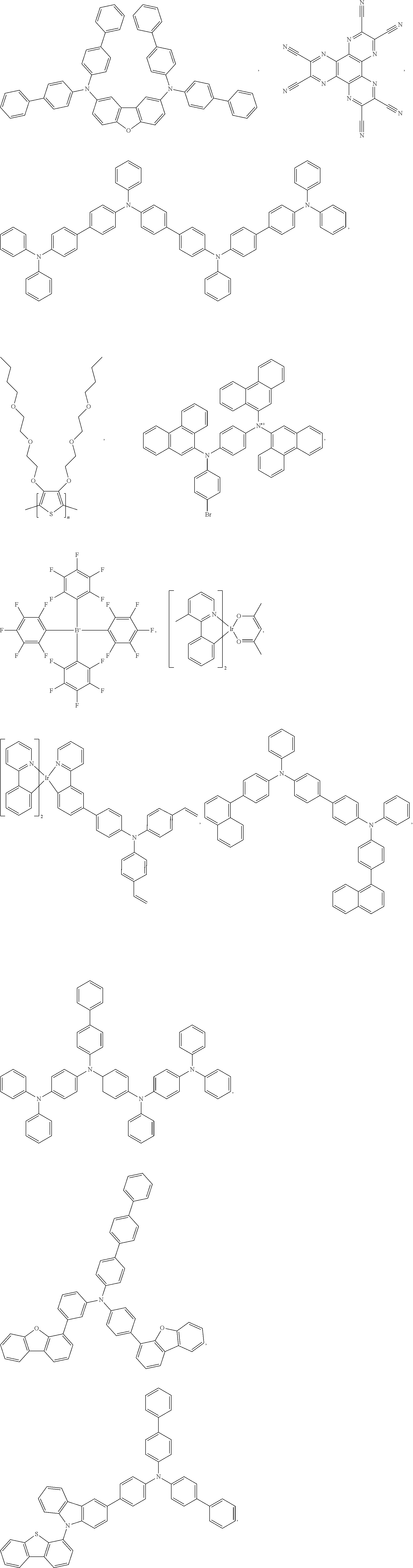

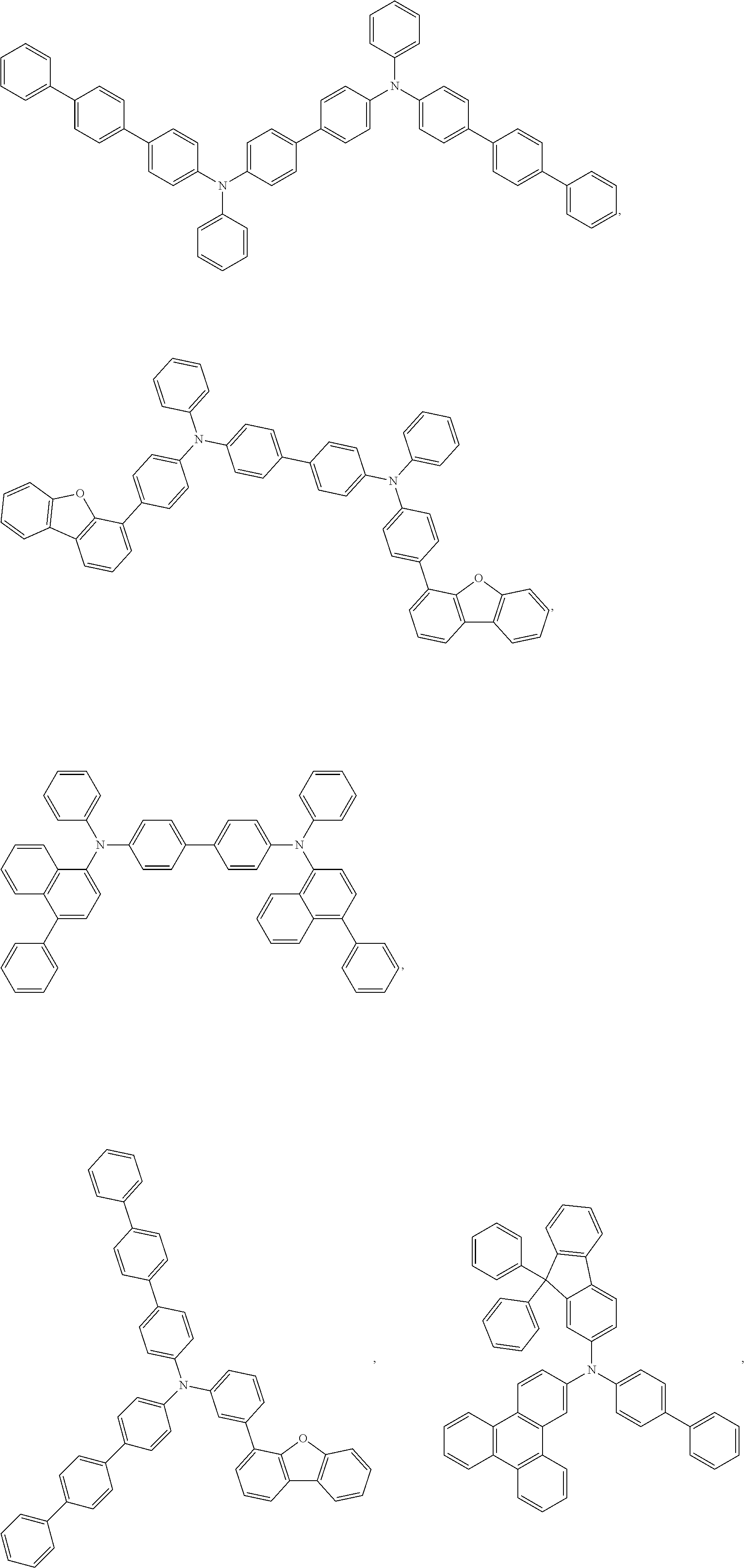

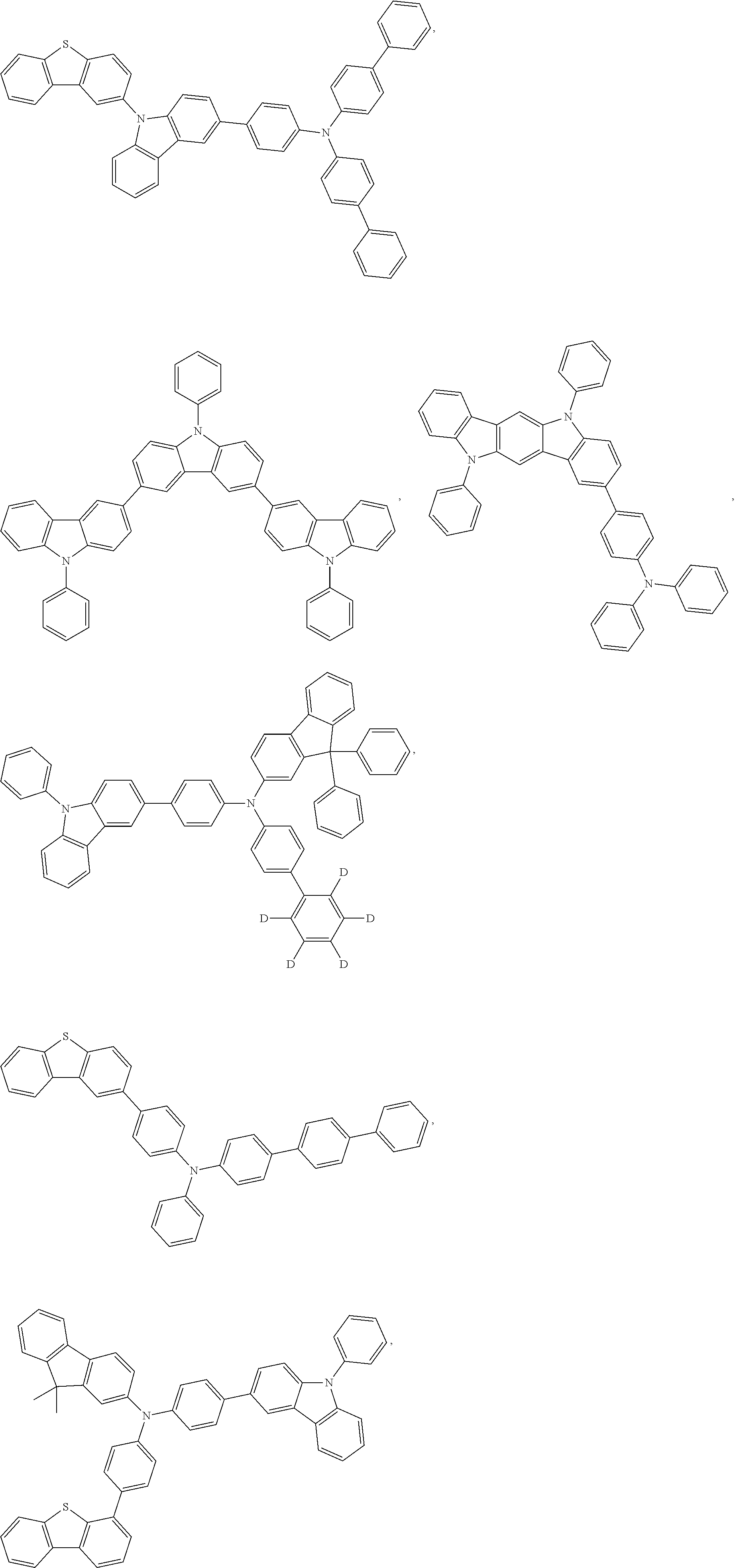

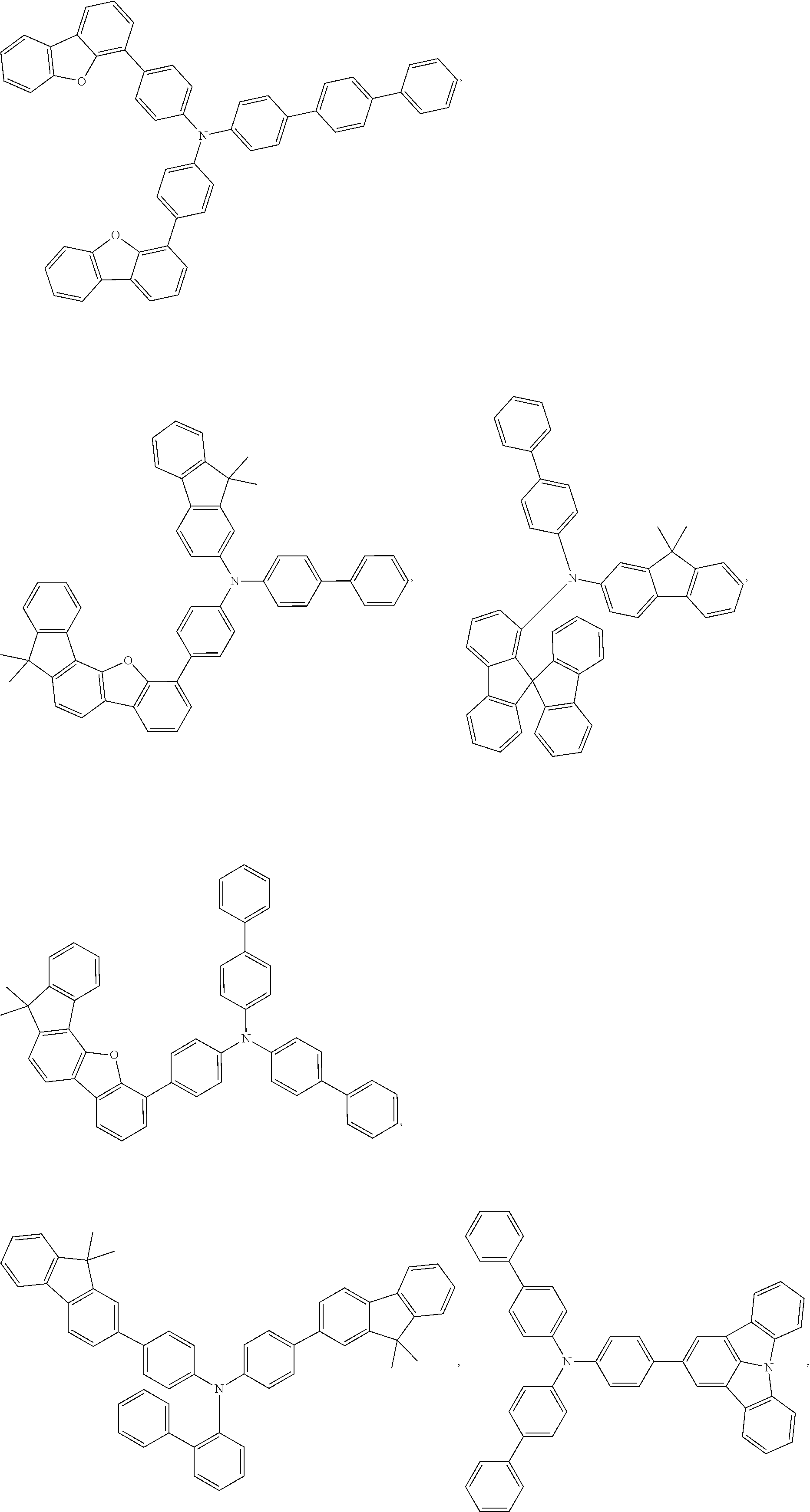

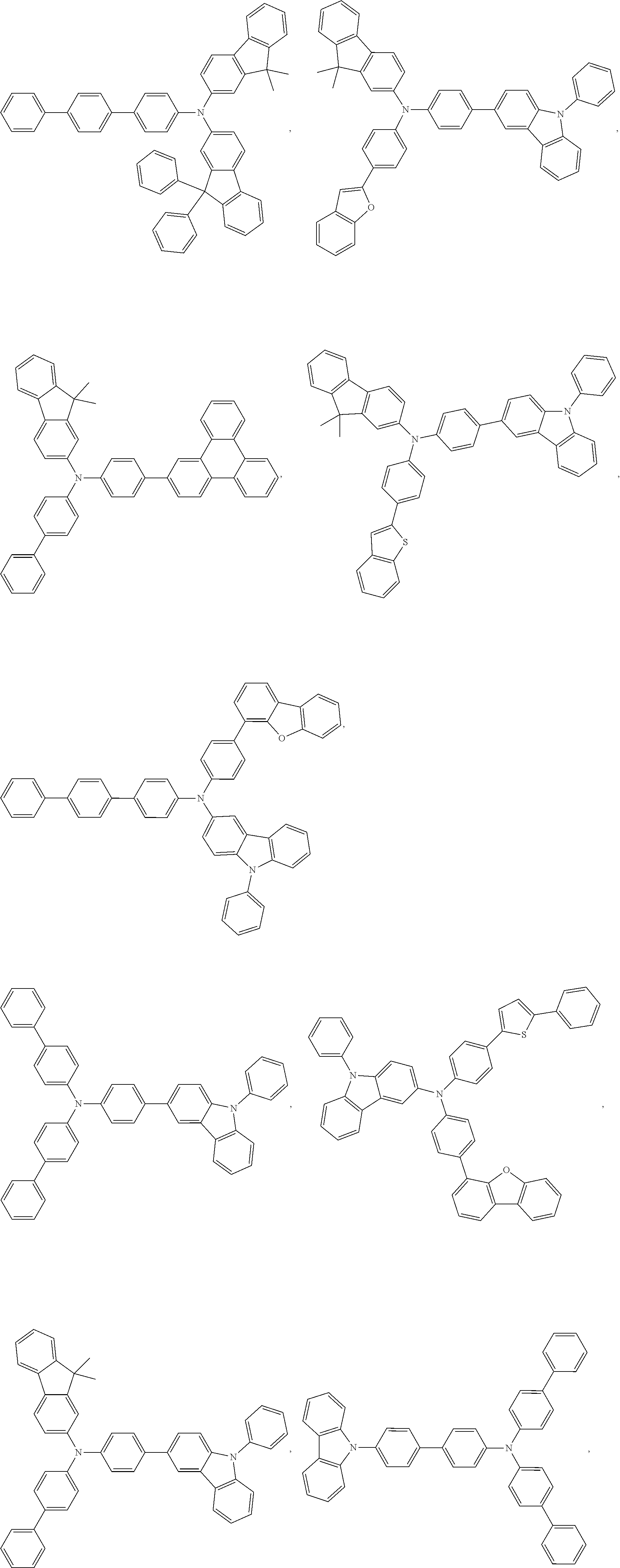

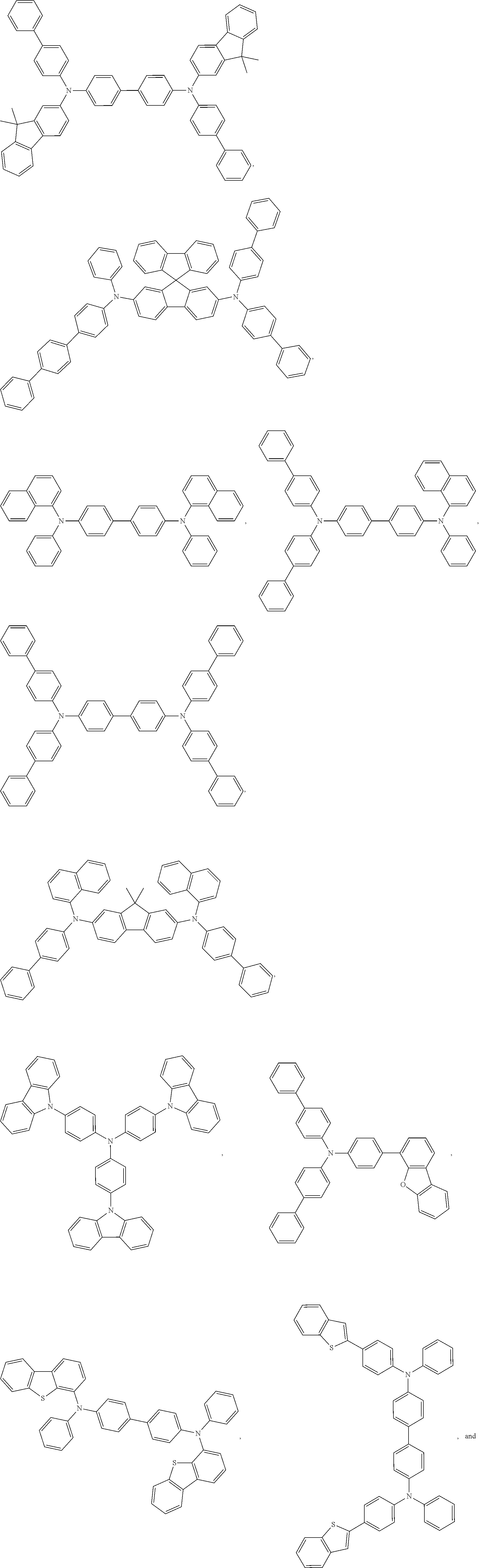

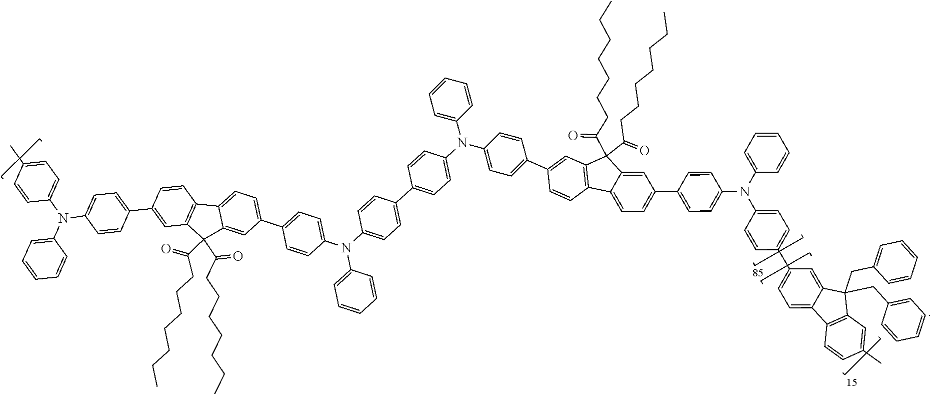

### EBL

An electron blocking layer (EBL) may be used to reduce the number of electrons and/or excitons that leave the emissive layer. The presence of such a blocking layer in a device may result in substantially higher efficiencies, and/or longer lifetime, as compared to a similar device lacking a blocking layer. Also, a blocking layer may be used to confine emission to a desired region of an OLED. In some embodiments, the EBL material has a higher LUMO (closer to the vacuum level) and/or higher triplet energy than the emitter closest to the EBL interface. In some embodiments, the EBL material has a higher LUMO (closer to the vacuum level) and or higher triplet energy than one or more of the hosts closest to the EBL interface. In one aspect, the compound used in EBL contains the same molecule or the same functional groups used as one of the hosts described below.

### Hosts

The light emitting layer of the organic EL device of the present disclosure preferably contains at least a metal complex as light emitting material, and may contain a host material using the metal complex as a dopant material. Examples of the host material are not particularly limited, and any metal complexes or organic compounds may be used as long as the triplet energy of the host is larger than that of the dopant. Any host material may be used with any dopant so long as the triplet criteria is satisfied.

Examples of metal complexes used as host are preferred to have the following general formula:

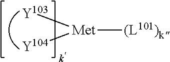

wherein Met is a metal, (Y¹⁰³-Y¹⁰⁴) is a bidentate ligand, Y¹⁰³ and Y¹⁰⁴ are independently selected from C, N, O, P, and S, L¹⁰¹ is an another ligand, k′ is an integer value from 1 to the maximum number of ligands that may be attached to the metal, and k′+k″ is the maximum number of ligands that may be attached to the metal.

In one aspect, the metal complexes are:

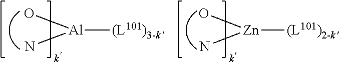

wherein (O—N) is a bidentate ligand, having metal coordinated to atoms O and N.

In another aspect, Met is selected from Ir and Pt. In a further aspect, (Y¹⁰³-Y¹⁰⁴) is a carbene ligand.

In one aspect, the host compound contains at least one of the following groups selected from the group consisting of aromatic hydrocarbon cyclic compounds such as benzene, biphenyl, triphenyl, triphenylene, tetraphenylene, naphthalene, anthracene, phenalene, phenanthrene, fluorene, pyrene, chrysene, perylene, and azulene, the group consisting of aromatic heterocyclic compounds such as dibenzothiophene, dibenzofuran, dibenzoselenophene, furan, thiophene, benzofuran, benzothiophene, benzoselenophene, carbazole, indolocarbazole, pyridylindole, pyrrolodipyridine, pyrazole, imidazole, triazole, oxazole, thiazole, oxadiazole, oxatriazole, dioxazole, thiadiazole, pyridine, pyridazine, pyrimidine, pyrazine, triazine, oxazine, oxathiazine, oxadiazine, indole, benzimidazole, indazole, indoxazine, benzoxazole, benzisoxazole, benzothiazole, quinoline, isoquinoline, cinnoline, quinazoline, quinoxaline, naphthyridine, phthalazine, pteridine, xanthene, acridine, phenazine, phenothiazine, phenoxazine, benzofuropyridine, furodipyridine, benzothienopyridine, thienodipyridine, benzoselenophenopyridine, and selenophenodipyridine, and the group consisting of 2 to 10 cyclic structural units which are groups of the same type or different types selected from the aromatic hydrocarbon cyclic group and the aromatic heterocyclic group and are bonded to each other directly or via at least one of oxygen atom, nitrogen atom, sulfur atom, silicon atom, phosphorus atom, boron atom, chain structural unit and the aliphatic cyclic group. Each option within each group may be unsubstituted or may be substituted by a substituent selected from the group consisting of deuterium, halogen, alkyl, cycloalkyl, heteroalkyl, heterocycloalkyl, arylalkyl, alkoxy, aryloxy, amino, silyl, alkenyl, cycloalkenyl, heteroalkenyl, alkynyl, aryl, heteroaryl, acyl, carboxylic acids, ether, ester, nitrile, isonitrile, sulfanyl, sulfinyl, sulfonyl, phosphino, and combinations thereof.

In one aspect, the host compound contains at least one of the following groups in the molecule:

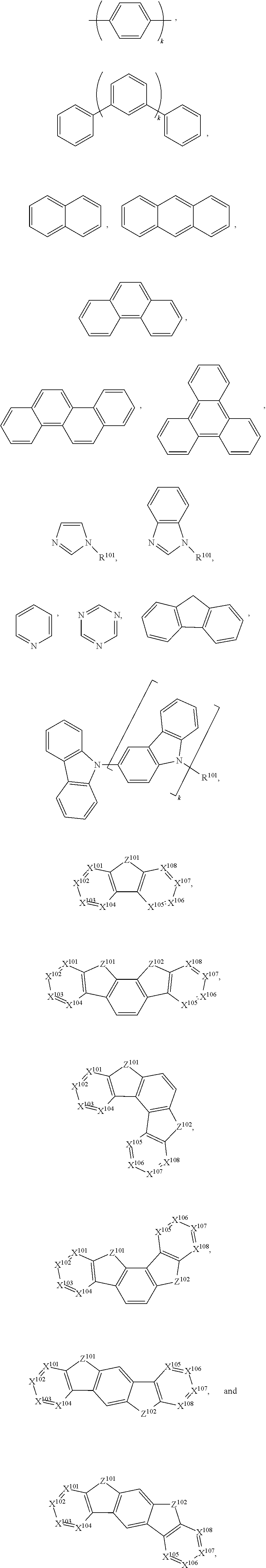

wherein R¹⁰¹ is selected from the group consisting of hydrogen, deuterium, halogen, alkyl, cycloalkyl, heteroalkyl, heterocycloalkyl, arylalkyl, alkoxy, aryloxy, amino, silyl, alkenyl, cycloalkenyl, heteroalkenyl, alkynyl, aryl, heteroaryl, acyl, carboxylic acids, ether, ester, nitrile, isonitrile, sulfanyl, sulfinyl, sulfonyl, phosphino, and combinations thereof, and when it is aryl or heteroaryl, it has the similar definition as Ar's mentioned above. k is an integer from 0 to 20 or 1 to 20. X¹⁰¹ to X¹⁰⁸ are independently selected from C (including CH) or N. Z¹⁰¹ and Z¹⁰² are independently selected from NR¹⁰¹, O, or S.

Non-limiting examples of the host materials, such as first host material compounds or HT host, that may be used in an OLED in combination with materials disclosed herein are exemplified below together with references that disclose those materials: EP2034538, EP2034538A, EP2757608, JP2007254297, KR20100079458, KR20120088644, KR20120129733, KR20130115564, TW201329200, US20030175553, US20050238919, US20060280965, US20090017330, US20090030202, US20090167162, US20090302743, US20090309488, US20100012931, US20100084966, US20100187984, US2010187984, US2012075273, US2012126221, US2013009543, US2013105787, US2013175519, US2014001446, US20140183503, US20140225088, US2014034914, U.S. Pat. No. 7,154,114, WO2001039234, WO2004093207, WO2005014551, WO2005089025, WO2006072002, WO2006114966, WO2007063754, WO2008056746, WO2009003898, WO2009021126, WO2009063833, WO2009066778, WO2009066779, WO2009086028, WO2010056066, WO2010107244, WO2011081423, WO2011081431, WO2011086863, WO2012128298, WO2012133644, WO2012133649, WO2013024872, WO2013035275, WO2013081315, WO2013191404, WO2014142472, US20170263869, US20160163995, U.S. Pat. No. 9,466,803,

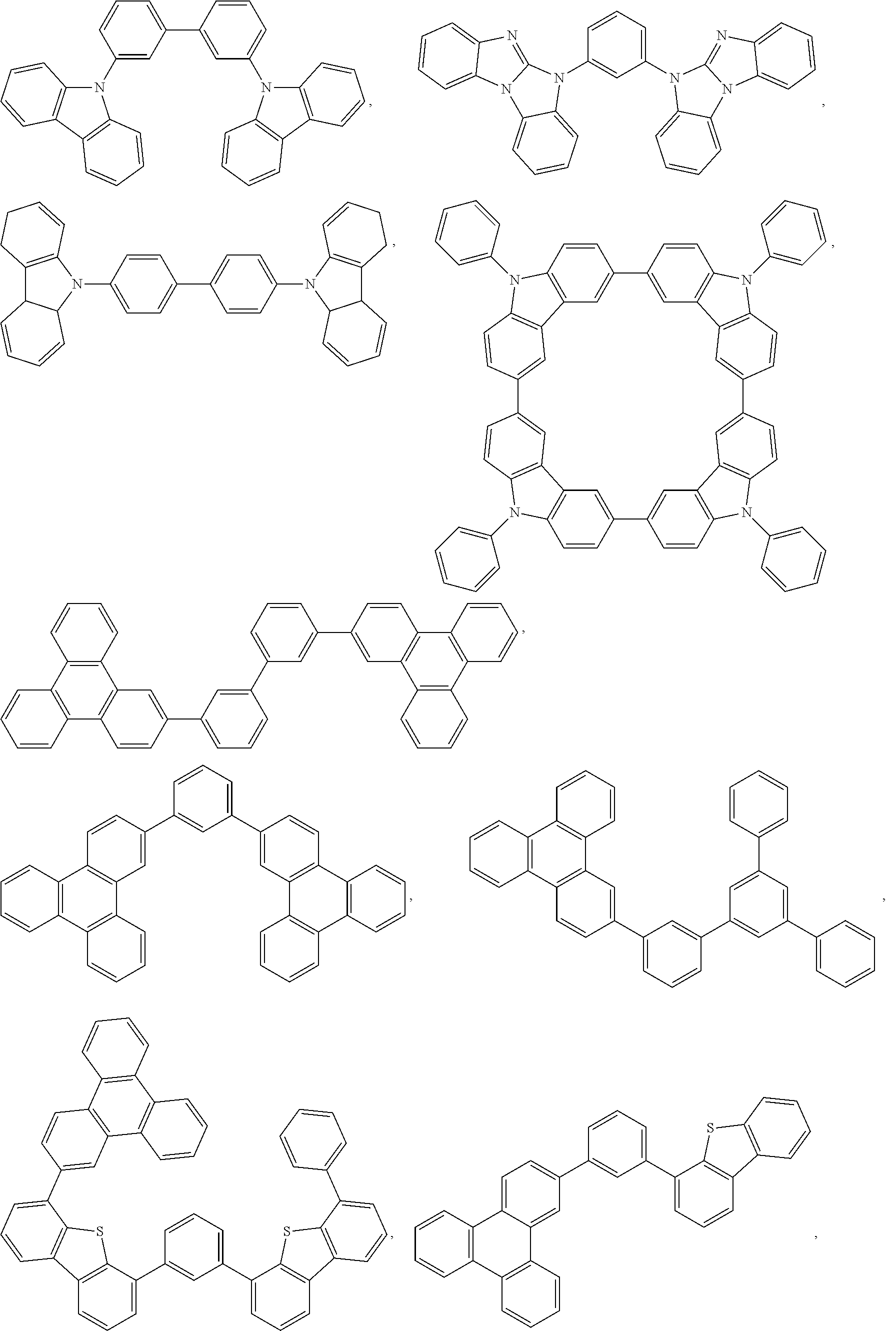

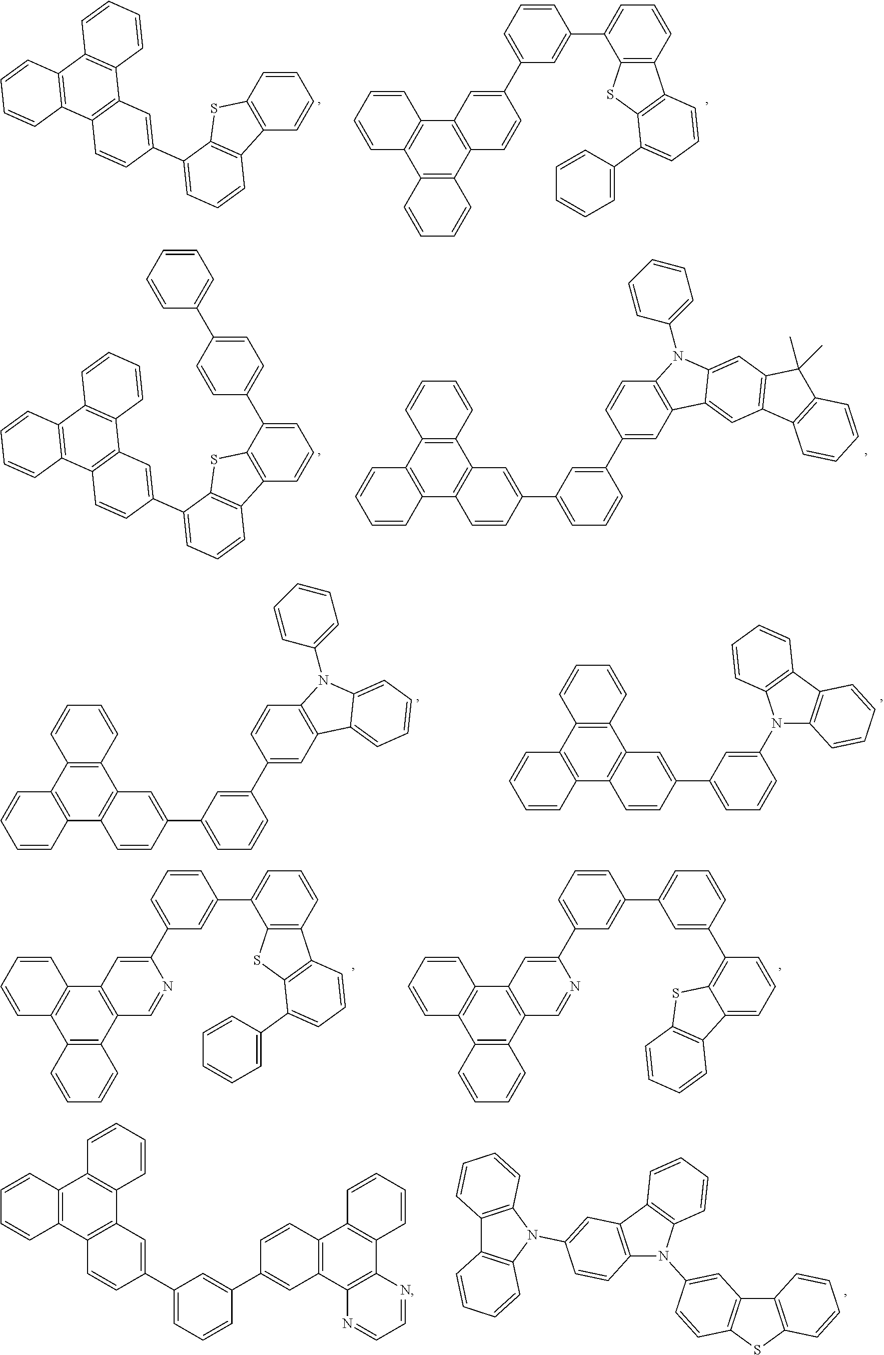

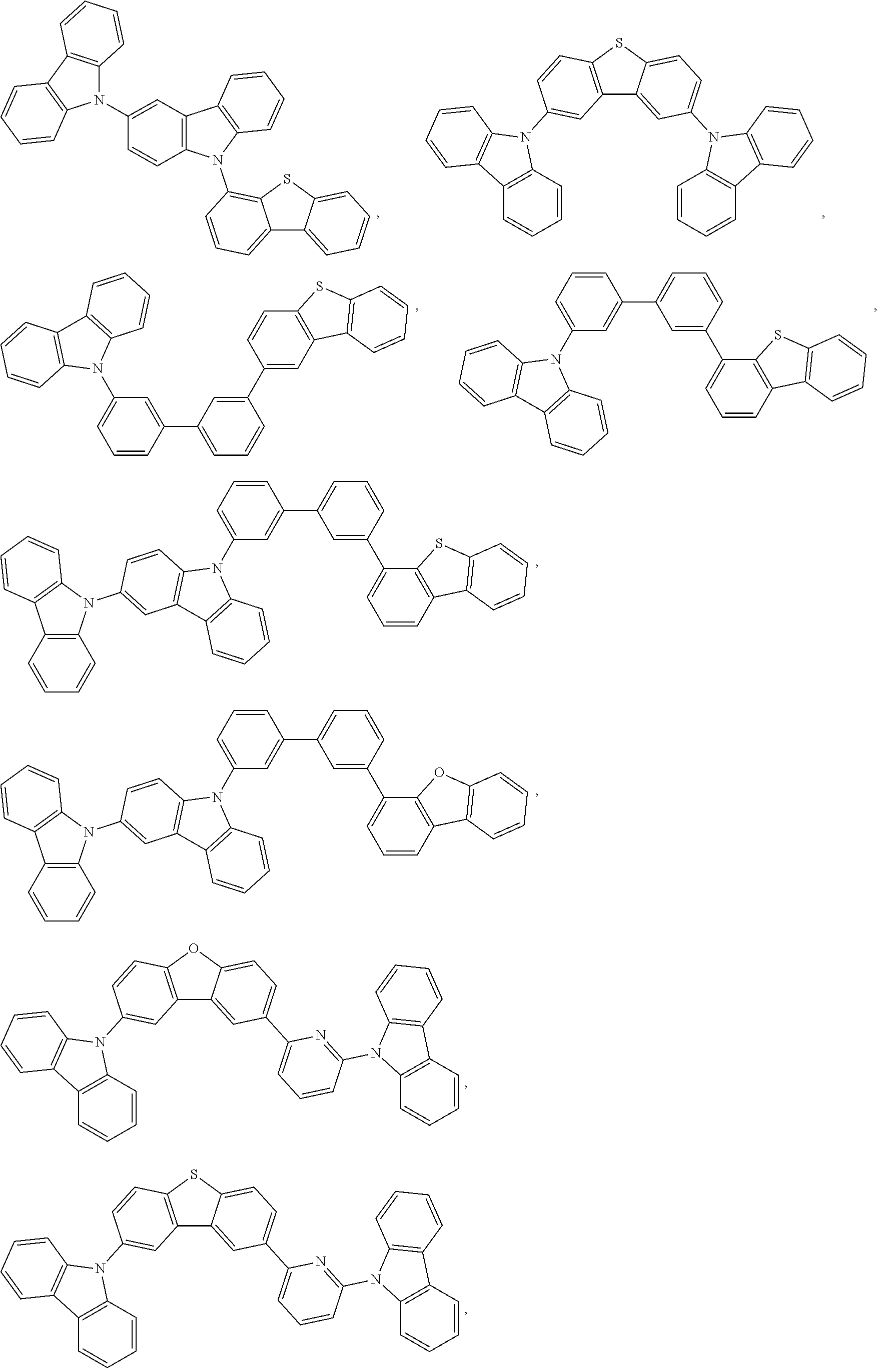

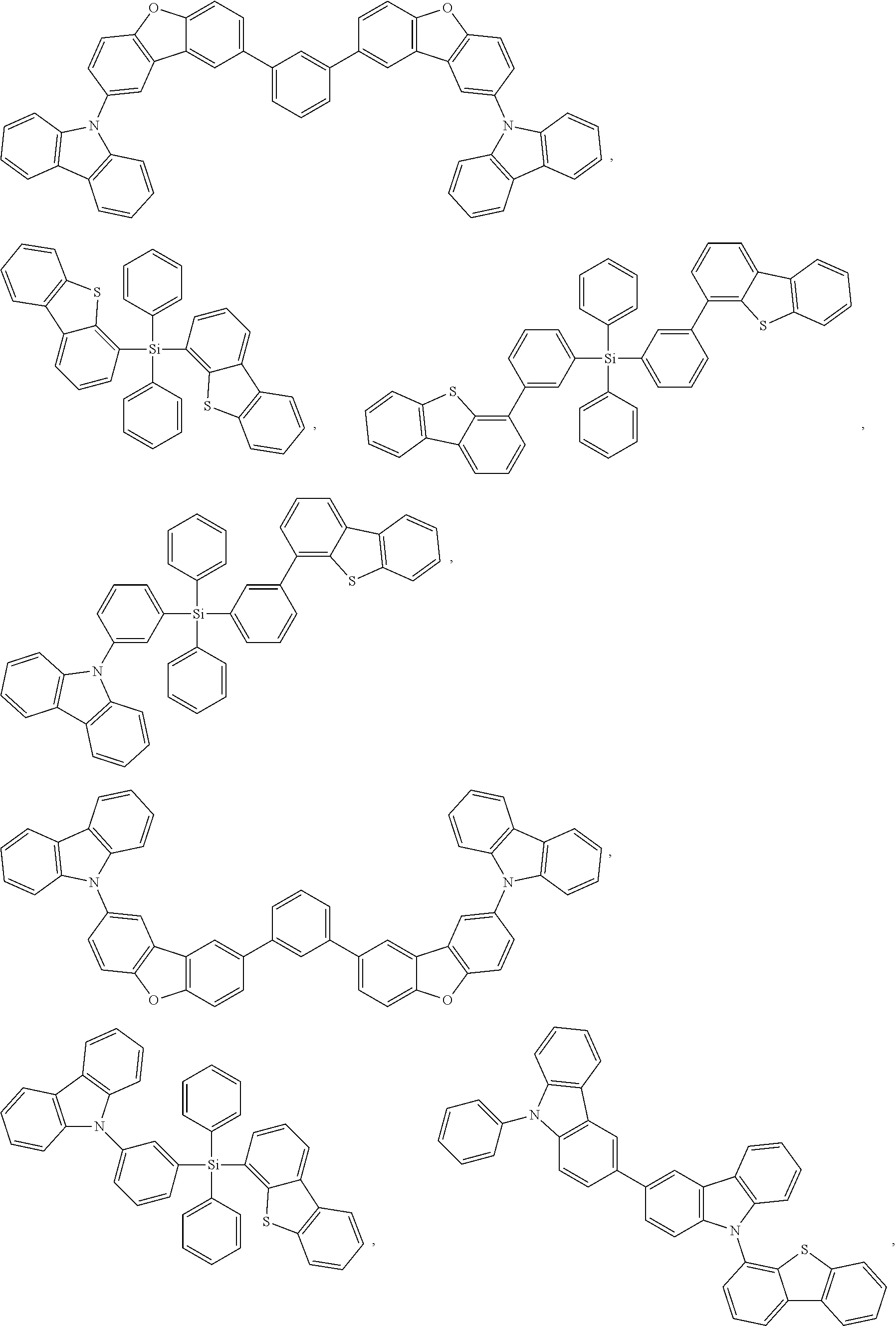

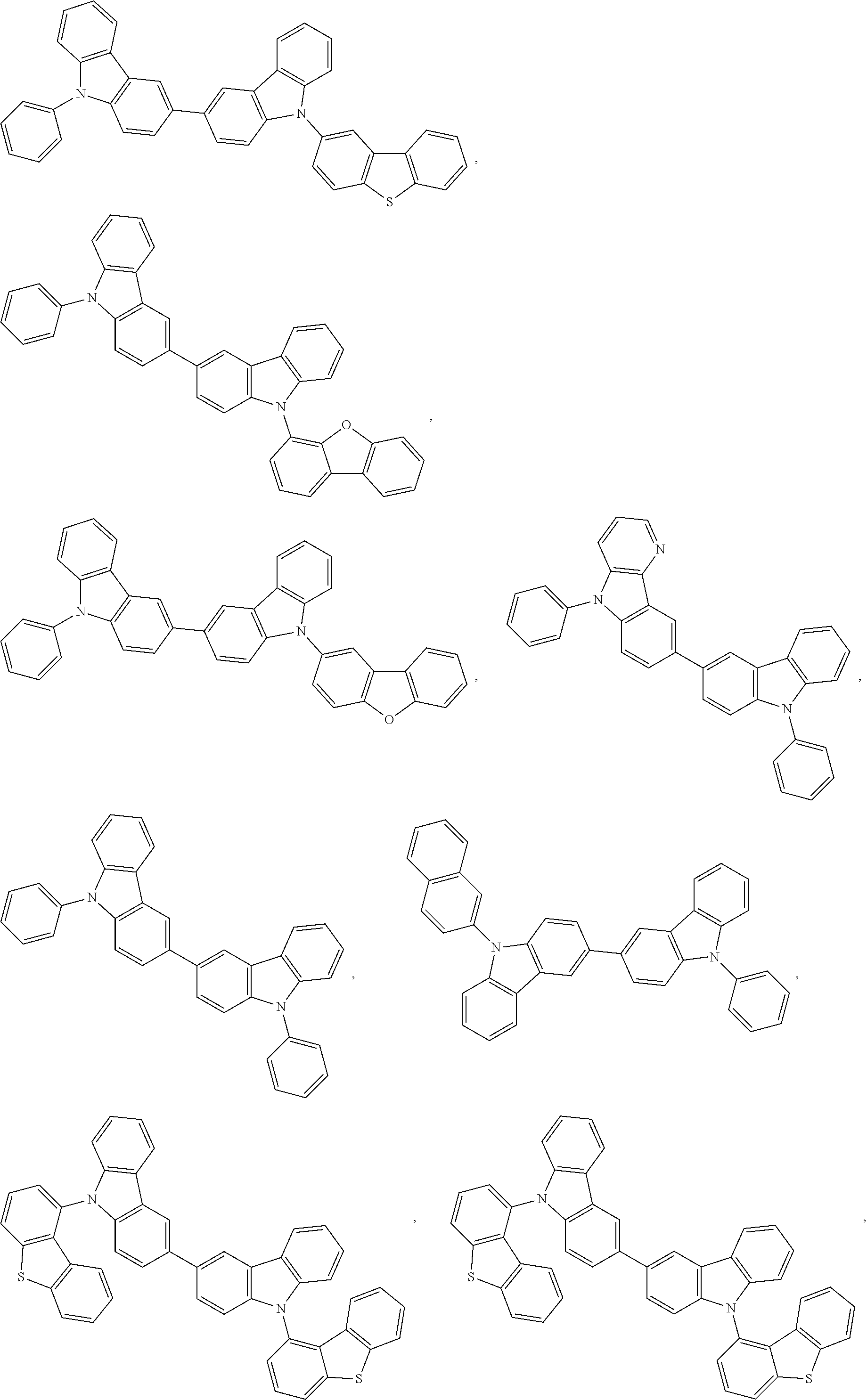

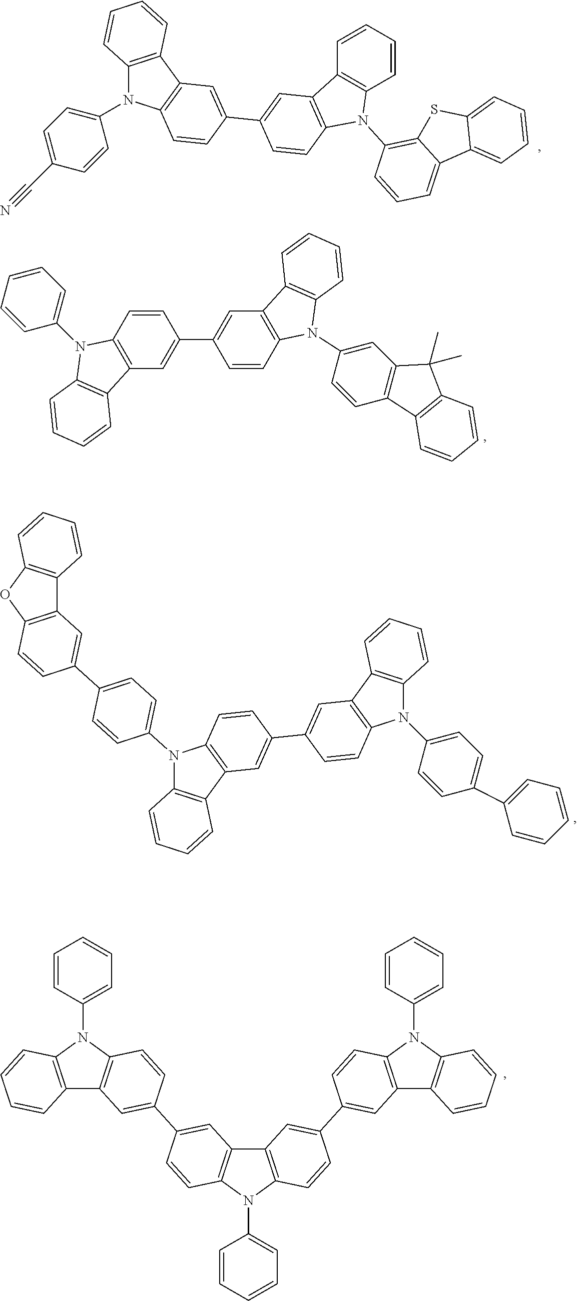 [SMILES: N#Cc1ccc(-n2c3ccccc3c3cc(-c4ccc5c(c4)c4ccccc4n5-c4cccc5c4sc4ccccc45)ccc32)cc1 ; CC1(C)c2ccccc2-c2ccc(-n3c4ccccc4c4cc(-c5ccc6c(c5)c5ccccc5n6-c5ccccc5)ccc43)cc21 ; c1ccc(-c2ccc(-n3c4ccccc4c4cc(-c5ccc6c(c5)c5ccccc5n6-c5ccc(-c6ccc7oc8ccccc8c7c6)cc5)ccc43)cc2)cc1 ; c1ccc(-n2c3ccccc3c3cc(-c4ccc5c(c4)c4cc(-c6ccc7c(c6)c6ccccc6n7-c6ccccc6)ccc4n5-c4ccccc4)ccc32)cc1]

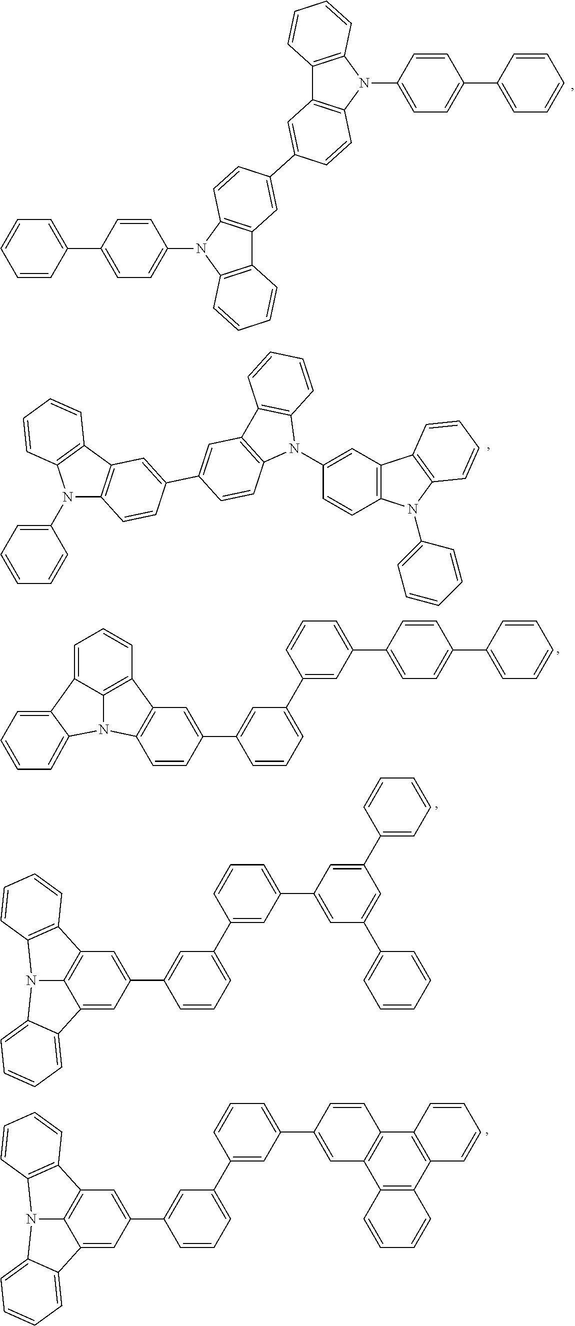

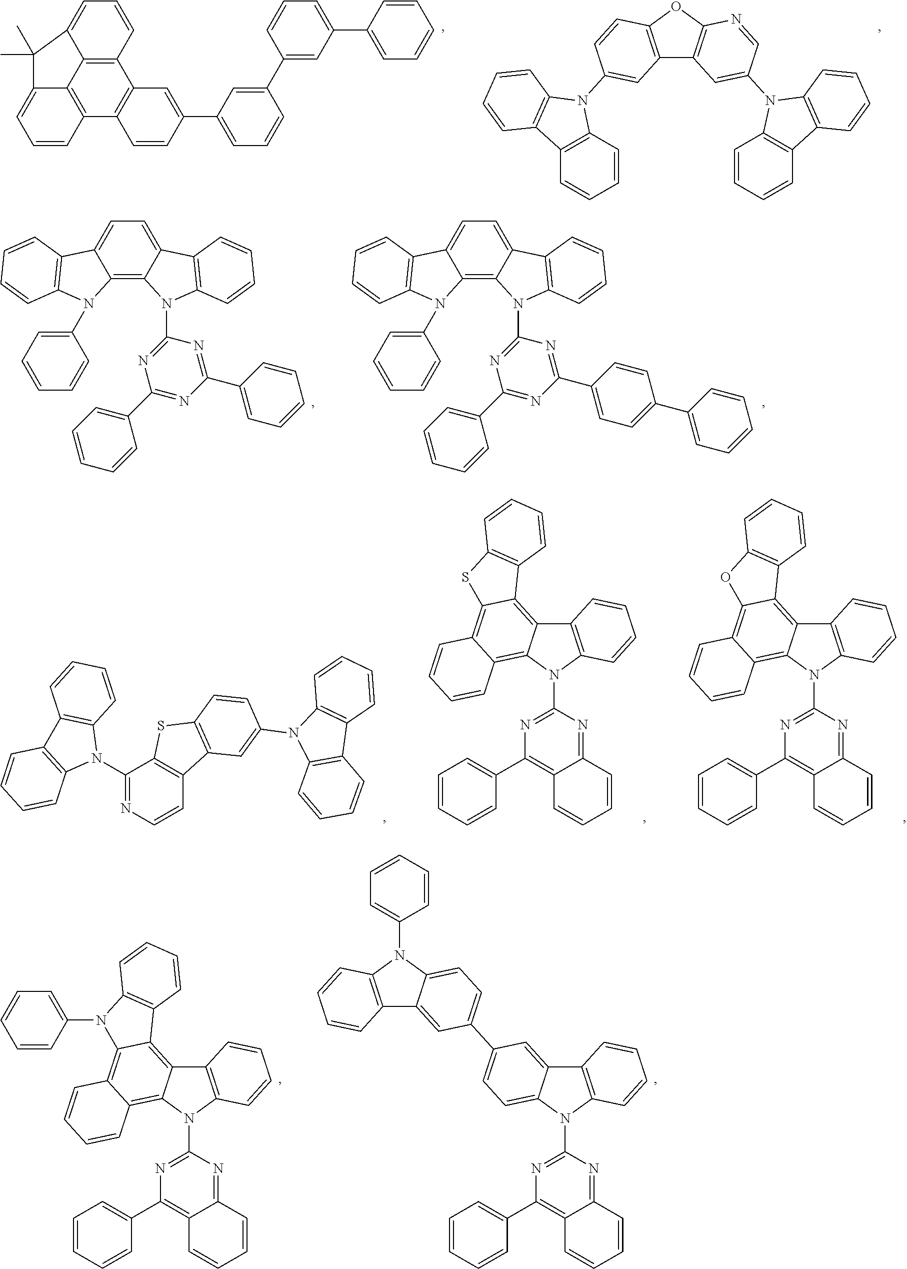

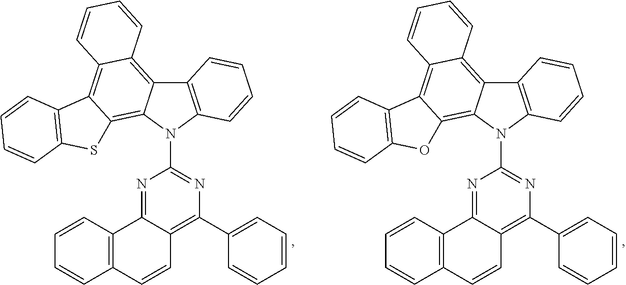 [SMILES: c1ccc(-c2nc(-n3c4ccccc4c4c5ccccc5c5c6ccccc6sc5c43)nc3c2ccc2ccccc23)cc1 ; c1ccc(-c2nc(-n3c4ccccc4c4c5ccccc5c5c6ccccc6oc5c43)nc3c2ccc2ccccc23)cc1]

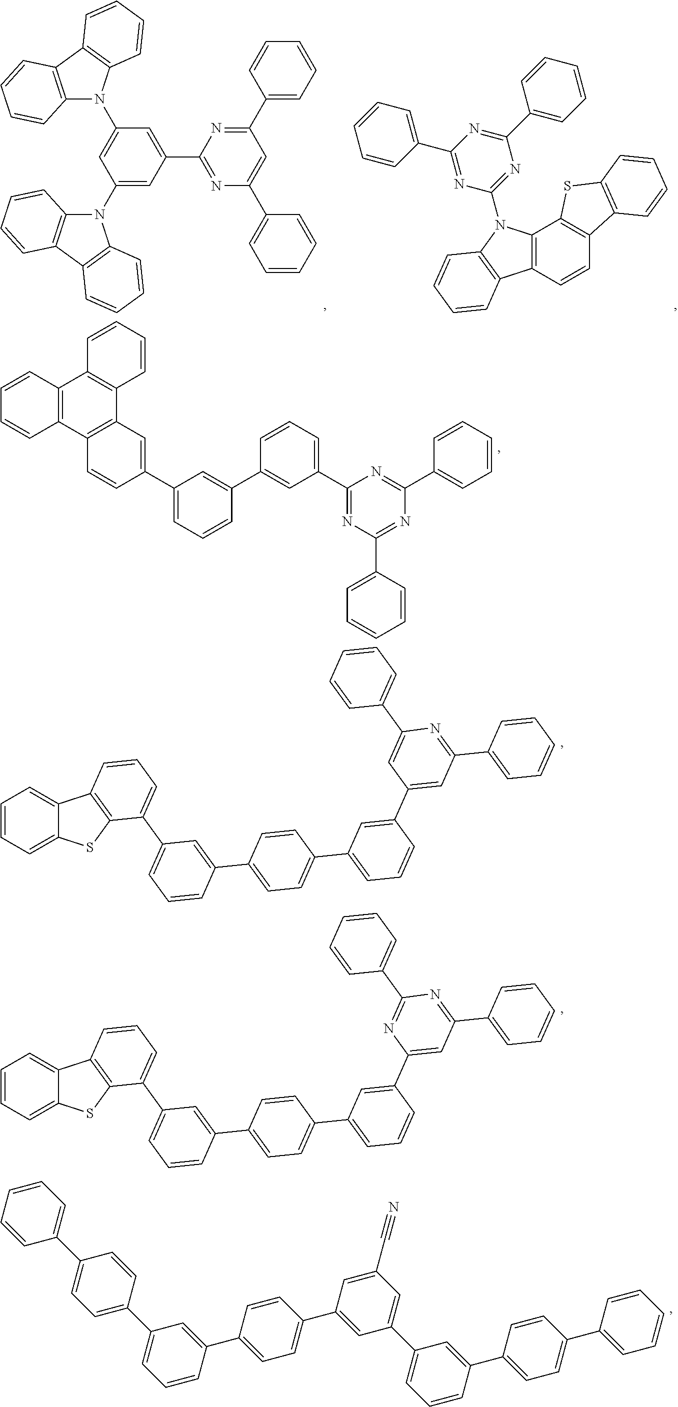

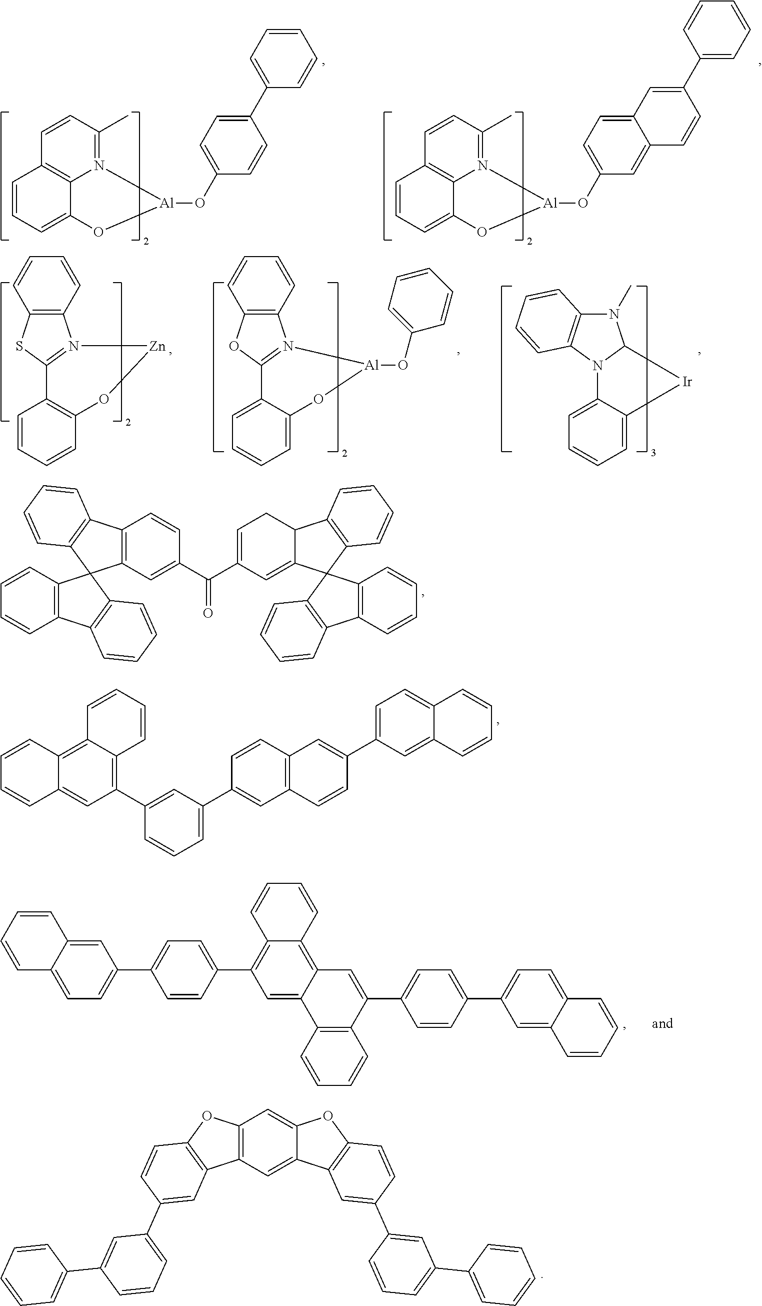

### Additional Emitters

One or more additional emitter dopants may be used in conjunction with the compound of the present disclosure. Examples of the additional emitter dopants are not particularly limited, and any compounds may be used as long as the compounds are typically used as emitter materials. Examples of suitable emitter materials include, but are not limited to, compounds which can produce emissions via phosphorescence, fluorescence, thermally activated delayed fluorescence, i.e., TADF (also referred to as E-type delayed fluorescence), triplet-triplet annihilation, or combinations of these processes.

Non-limiting examples of the emitter materials that may be used in an OLED in combination with materials disclosed herein are exemplified below together with references that disclose those materials: CN103694277, CN1696137, EB01238981, EP01239526, EP01961743, EP1239526, EP1244155, EP1642951, EP1647554, EP1841834, EP1841834B, EP2062907, EP2730583, JP2012074444, JP2013110263, JP4478555, KR1020090133652, KR20120032054, KR20130043460, TW201332980, U.S. Pat. Nos. 6,699,599, 6,916,554, US20010019782, US20020034656, US20030068526, US20030072964, US20030138657, US20050123788, US20050244673, US2005123791, US2005260449, US20060008670, US20060065890, US20060127696, US20060134459, US20060134462, US20060202194, US20060251923, US20070034863, US20070087321, US20070103060, US20070111026, US20070190359, US20070231600, US2007034863, US2007104979, US2007104980, US2007138437, US2007224450, US2007278936, US20080020237, US20080233410, US20080261076, US20080297033, US200805851, US2008161567, US2008210930, US20090039776, US20090108737, US20090115322, US20090179555, US2009085476, US2009104472, US20100090591, US20100148663, US20100244004, US20100295032, US2010102716, US2010105902, US2010244004, US2010270916, US20110057559, US20110108822, US20110204333, US2011215710, US2011227049, US2011285275, US2012292601, US20130146848, US2013033172, US2013165653, US2013181190, US2013334521, US20140246656, US2014103305, U.S. Pat. Nos. 6,303,238, 6,413,656, 6,653,654, 6,670,645, 6,687,266, 6,835,469, 6,921,915, 7,279,704, 7,332,232, 7,378,162, 7,534,505, 7,675,228, 7,728,137, 7,740,957, 7,759,489, 7,951,947, 8,067,099, 8,592,586, 8,871,361, WO06081973, WO06121811, WO07018067, WO07108362, WO07115970, WO07115981, WO08035571, WO2002015645, WO2003040257, WO2005019373, WO2006056418, WO2008054584, WO2008078800, WO2008096609, WO2008101842, WO2009000673, WO2009050281, WO2009100991, WO2010028151, WO2010054731, WO2010086089, WO2010118029, WO2011044988, WO2011051404, WO2011107491, WO2012020327, WO2012163471, WO2013094620, WO2013107487, WO2013174471, WO2014007565, WO2014008982, WO2014023377, WO2014024131, WO2014031977, WO2014038456, WO2014112450.

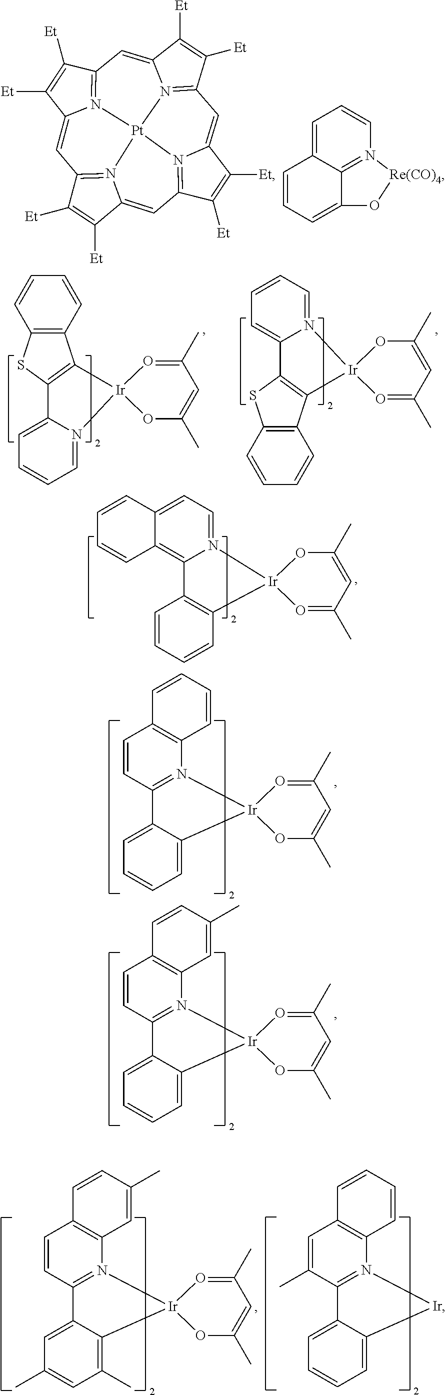

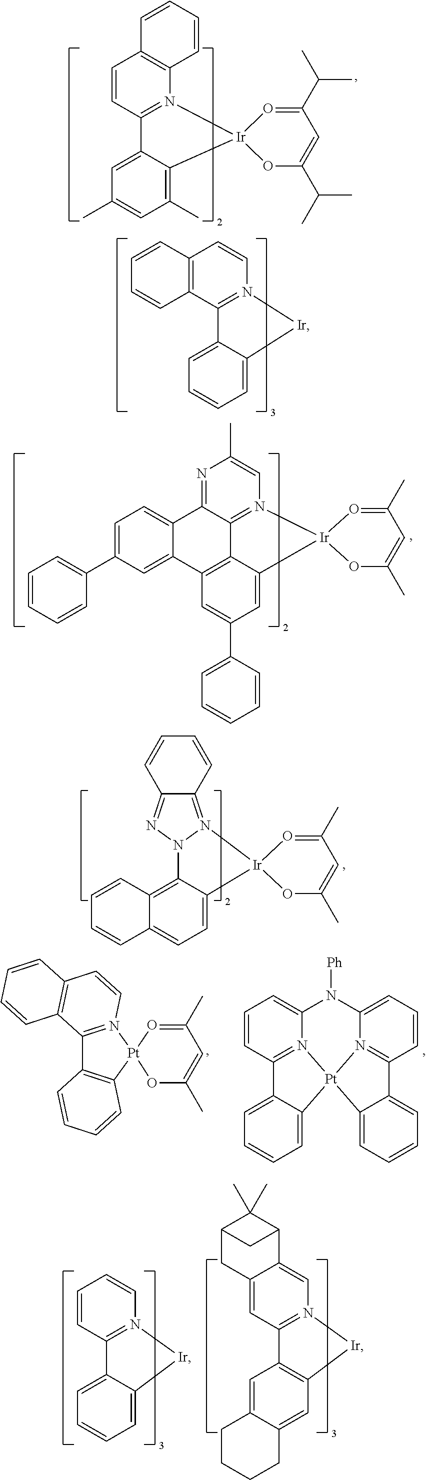

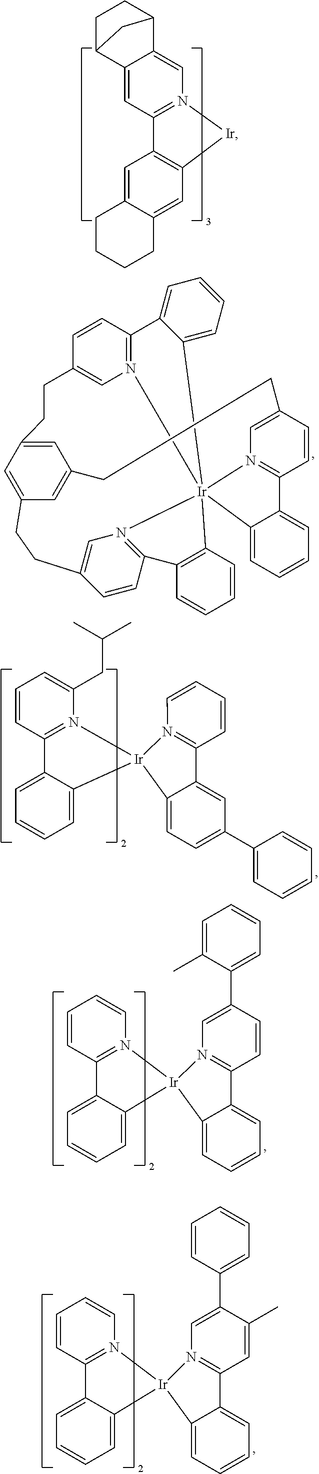

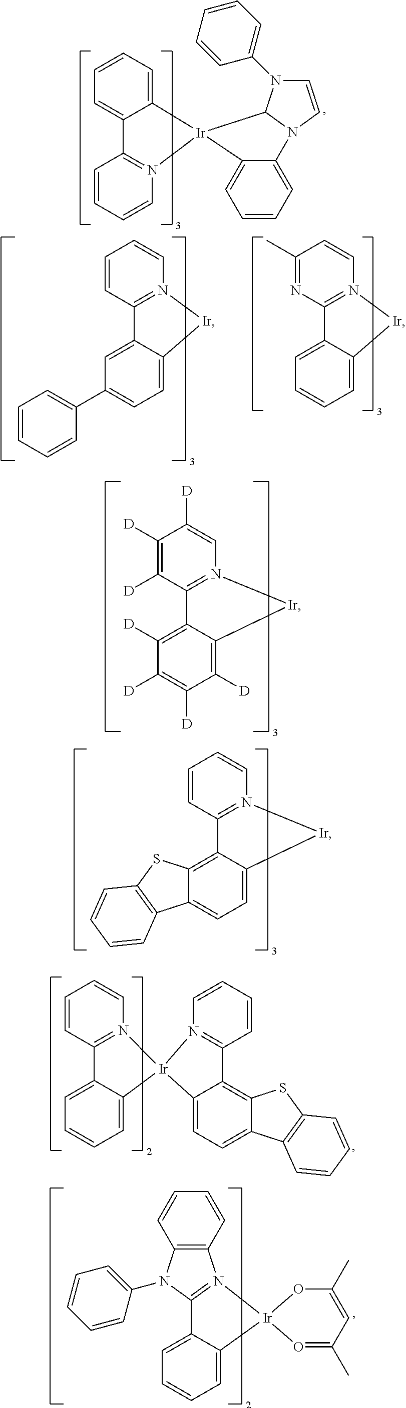

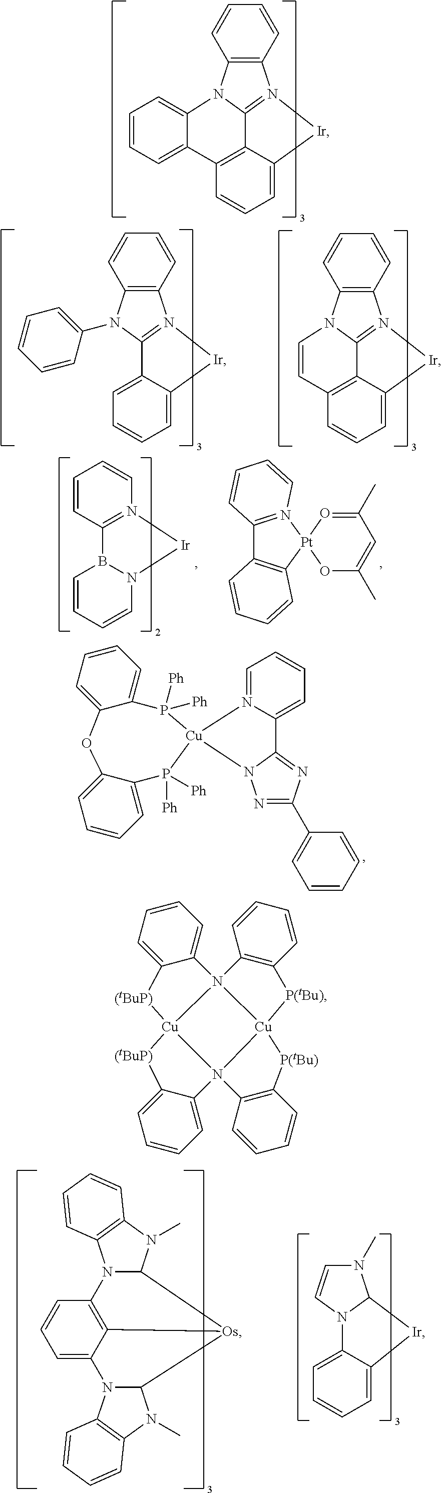

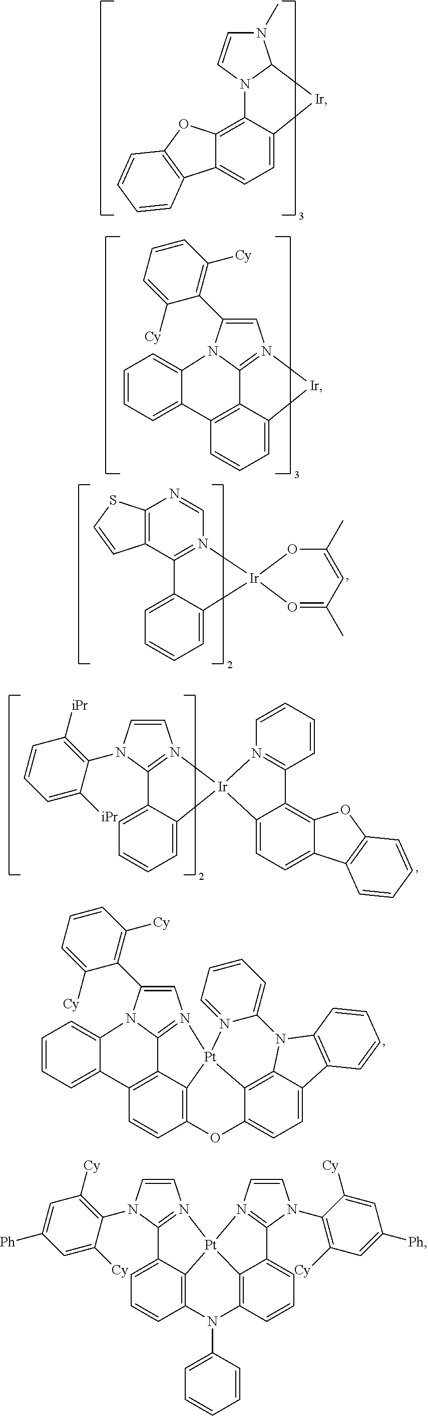

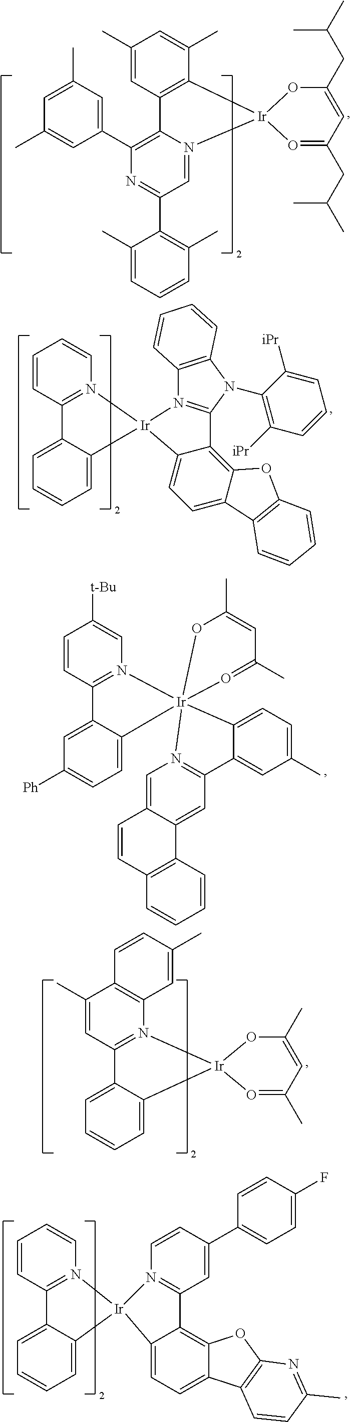

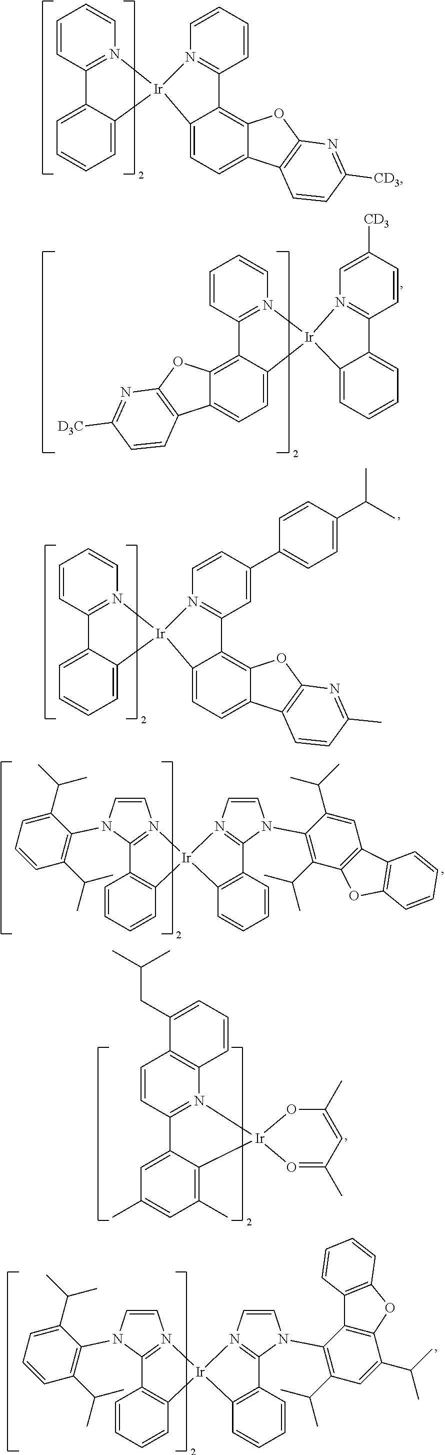

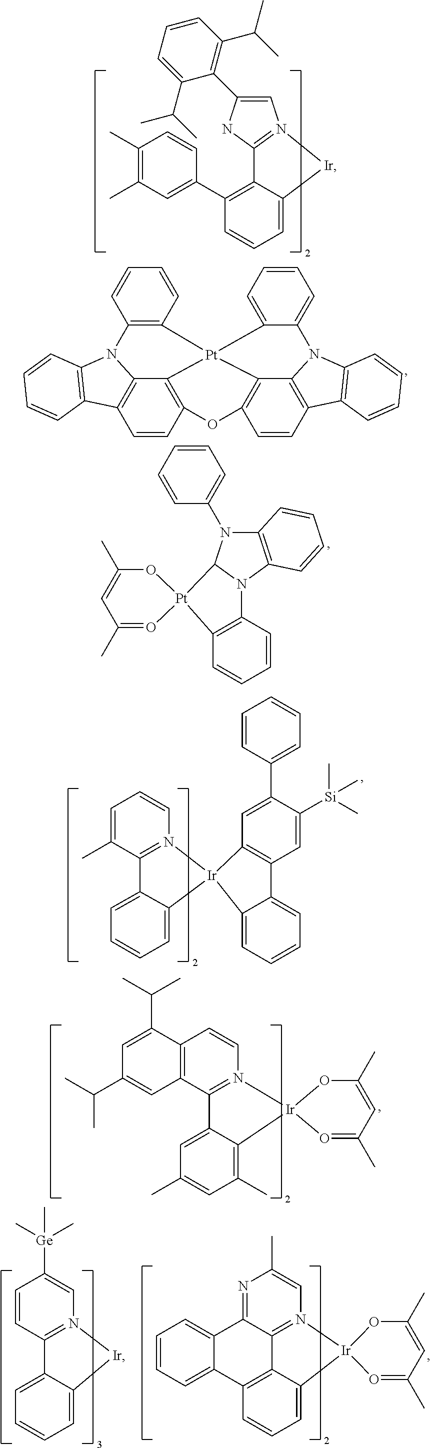

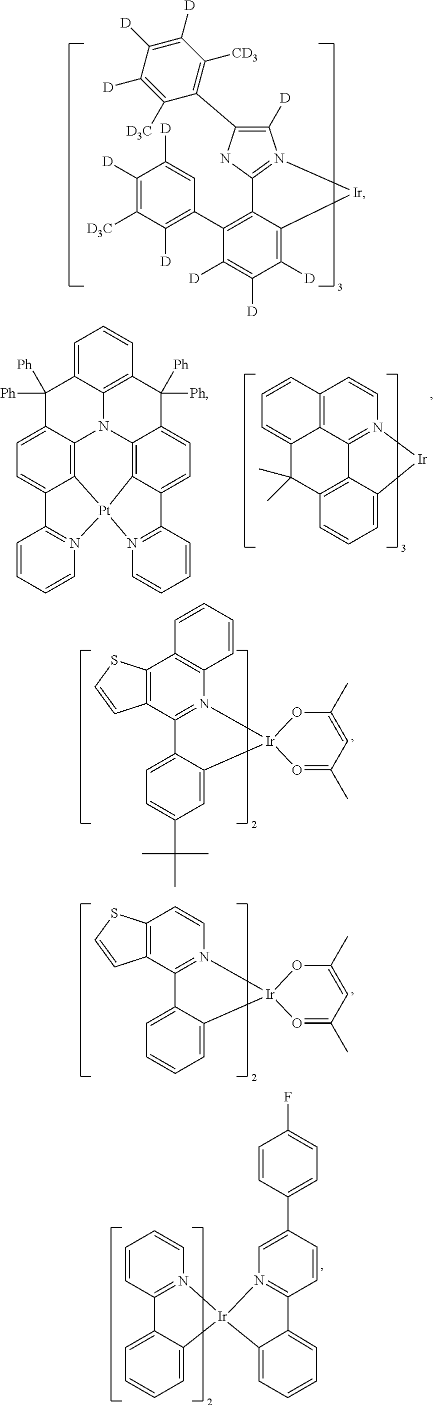

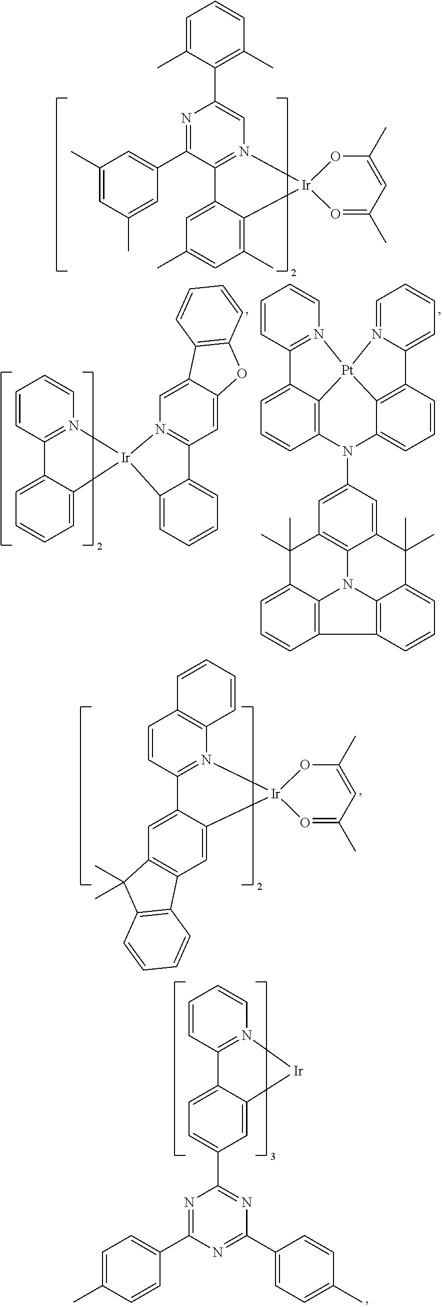

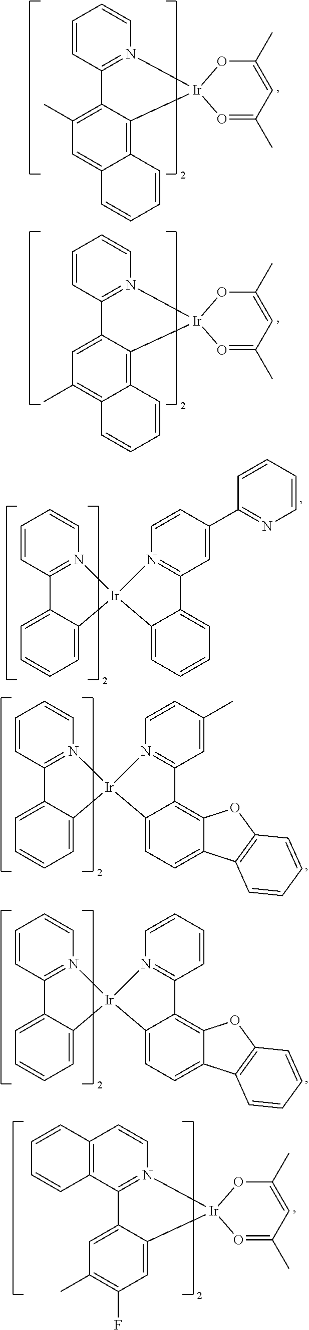

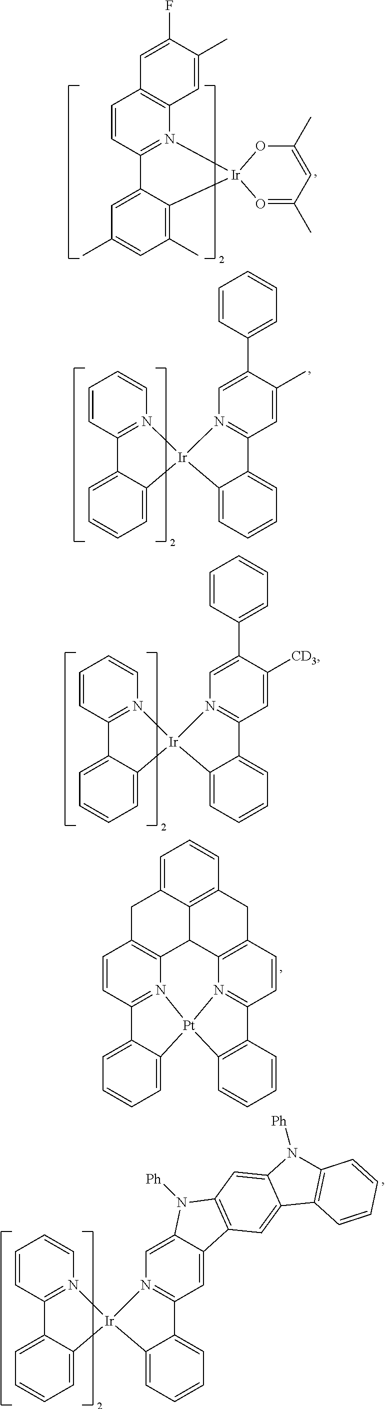

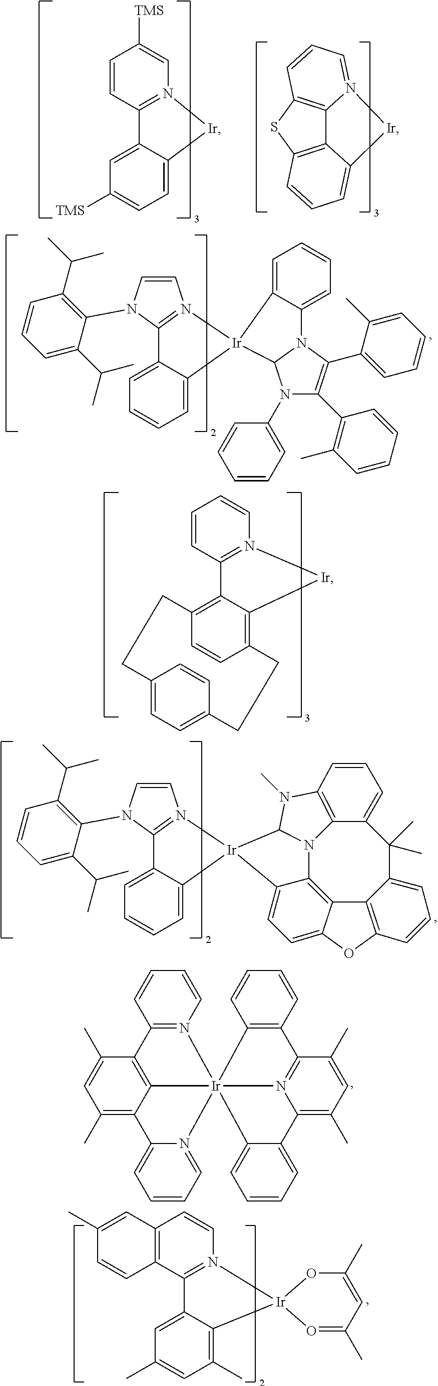

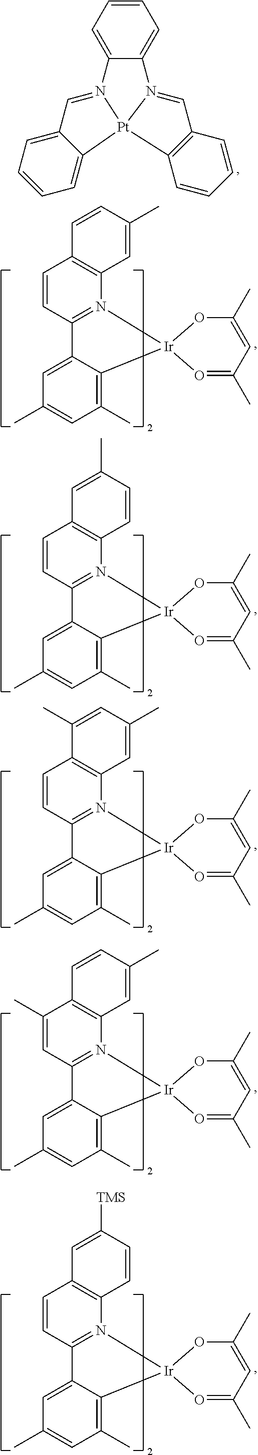

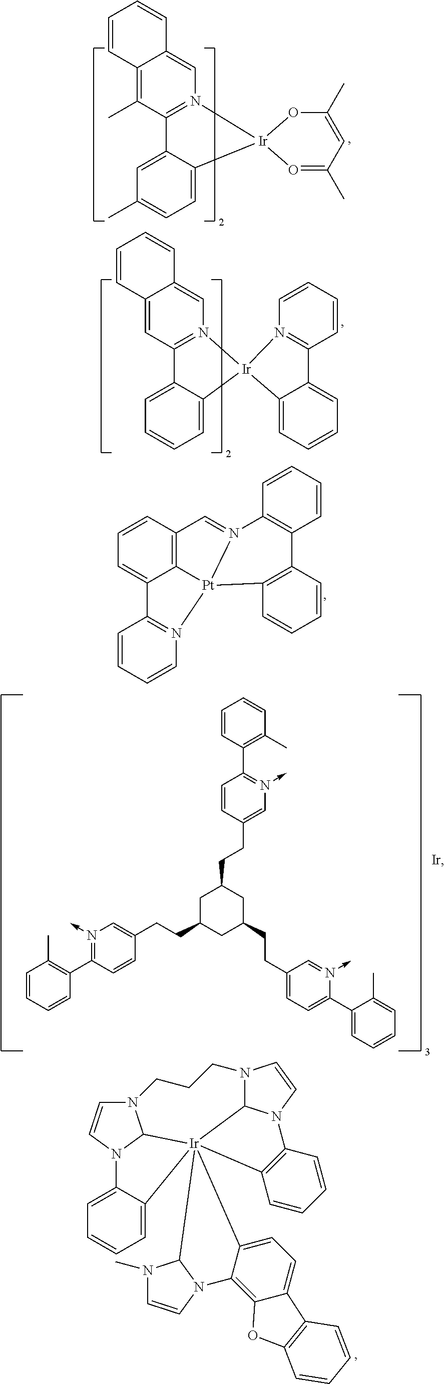

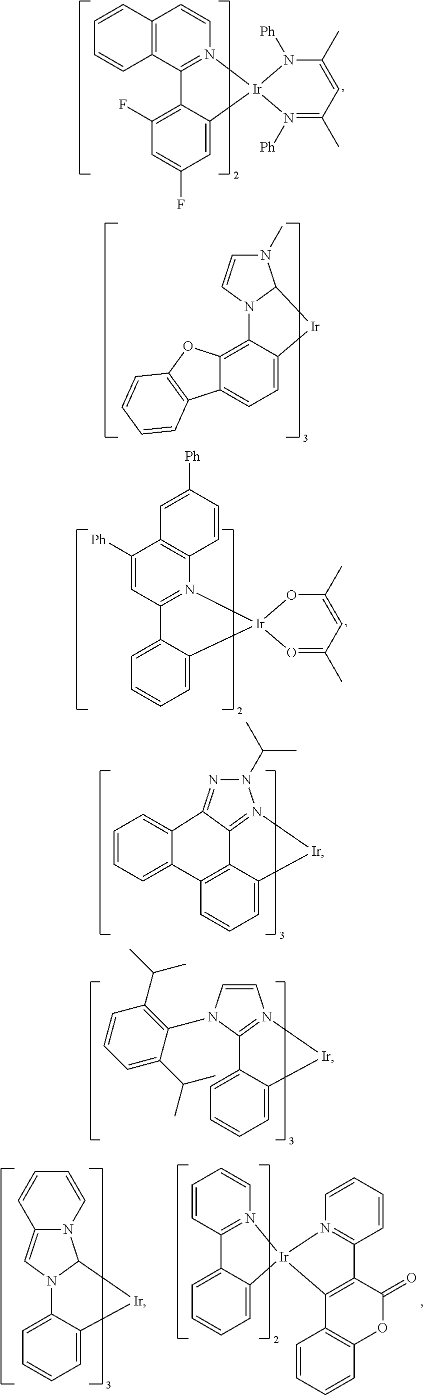

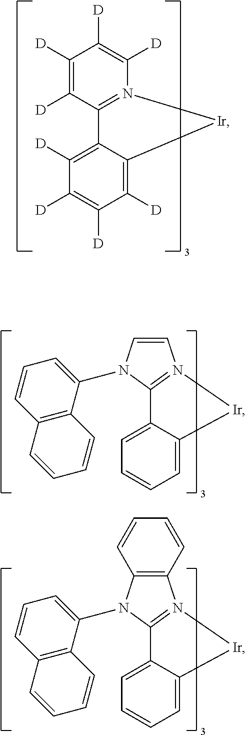

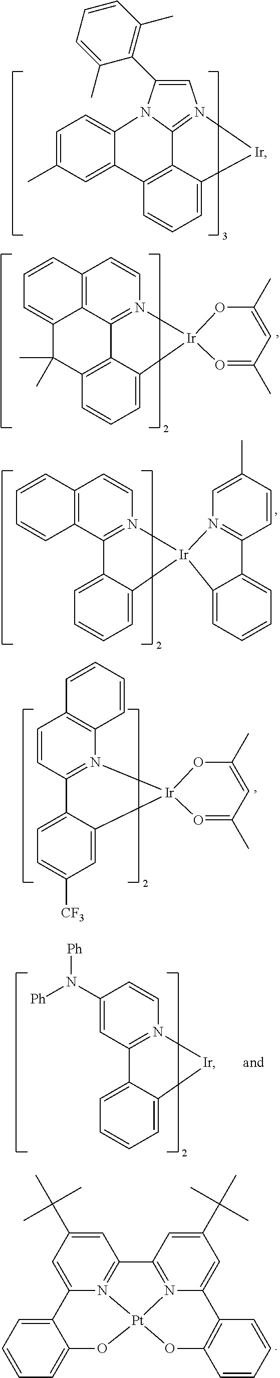

### HBL

A hole blocking layer (HBL) may be used to reduce the number of holes and/or excitons that leave the emissive layer. The presence of such a blocking layer in a device may result in substantially higher efficiencies and/or longer lifetime as compared to a similar device lacking a blocking layer. Also, a blocking layer may be used to confine emission to a desired region of an OLED. In some embodiments, the HBL material has a lower HOMO (further from the vacuum level) and or higher triplet energy than the emitter closest to the HBL interface. In some embodiments, the HBL material has a lower HOMO (further from the vacuum level) and or higher triplet energy than one or more of the hosts closest to the HBL interface.

In one aspect, compound used in HBL contains the same molecule or the same functional groups used as host described above.

In another aspect, compound used in HBL contains at least one of the following groups in the molecule:

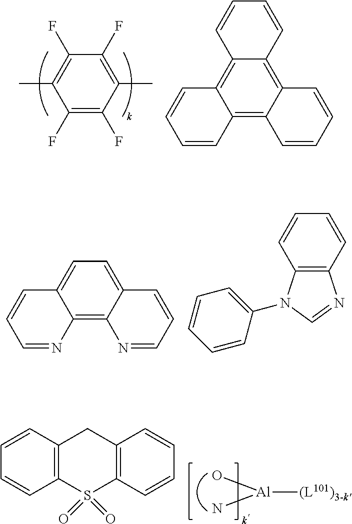

wherein k is an integer from 1 to 20, L¹⁰¹ is another ligand, k′ is an integer from 1 to 3.

### ETL

An electron transport layer (ETL) may include a material capable of transporting electrons. The electron transport layer may be intrinsic (undoped), or doped. Doping may be used to enhance conductivity. Examples of the ETL material are not particularly limited, and any metal complexes or organic compounds may be used as long as they are typically used to transport electrons.

In one aspect, compound used in ETL contains at least one of the following groups in the molecule:

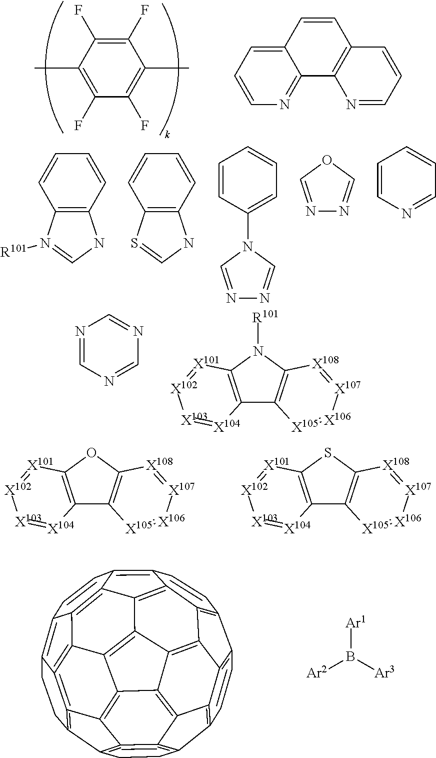

wherein R¹⁰¹ is selected from the group consisting of hydrogen, deuterium, halogen, alkyl, cycloalkyl, heteroalkyl, heterocycloalkyl, arylalkyl, alkoxy, aryloxy, amino, silyl, alkenyl, cycloalkenyl, heteroalkenyl, alkynyl, aryl, heteroaryl, acyl, carboxylic acids, ether, ester, nitrile, isonitrile, sulfanyl, sulfinyl, sulfonyl, phosphino, and combinations thereof, when it is aryl or heteroaryl, it has the similar definition as Ar's mentioned above. Ar¹ to Ar³ has the similar definition as Ar's mentioned above. k is an integer from 1 to 20. X¹⁰¹ to X¹⁰⁸ is selected from C (including CH) or N.

In another aspect, the metal complexes used in ETL contains, but not limit to the following general formula:

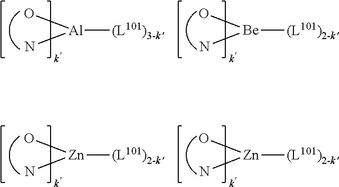

wherein (O—N) or (N—N) is a bidentate ligand, having metal coordinated to atoms O, N or N, N, L¹⁰¹ is another ligand, k′ is an integer value from 1 to the maximum number of ligands that may be attached to the metal.

Non-limiting examples of the ETL materials that may be used in an OLED in combination with materials disclosed herein are exemplified below together with references that disclose those materials: CN103508940, EP01602648, EP01734038, EP01956007, JP2004-022334, JP2005149918, JP2005-268199, KR0117693, KR20130108183, US20040036077, US20070104977, US2007018155, US20090101870, US20090115316, US20090140637, US20090179554, US2009218940, US2010108990, US2011156017, US2011210320, US2012193612, US2012214993, US2014014925, US2014014927, US20140284580, U.S. Pat. Nos. 6,656,612, 8,415,031, WO2003060956, WO2007111263, WO2009148269, WO2010067894, WO2010072300, WO2011074770, WO2011105373, WO2013079217, WO2013145667, WO2013180376, WO2014104499, WO2014104535,

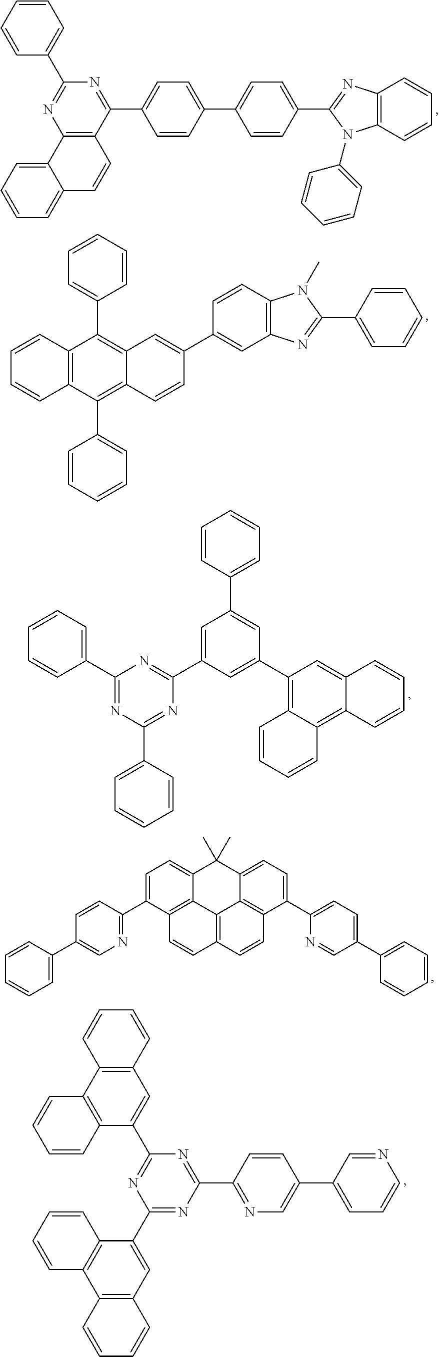

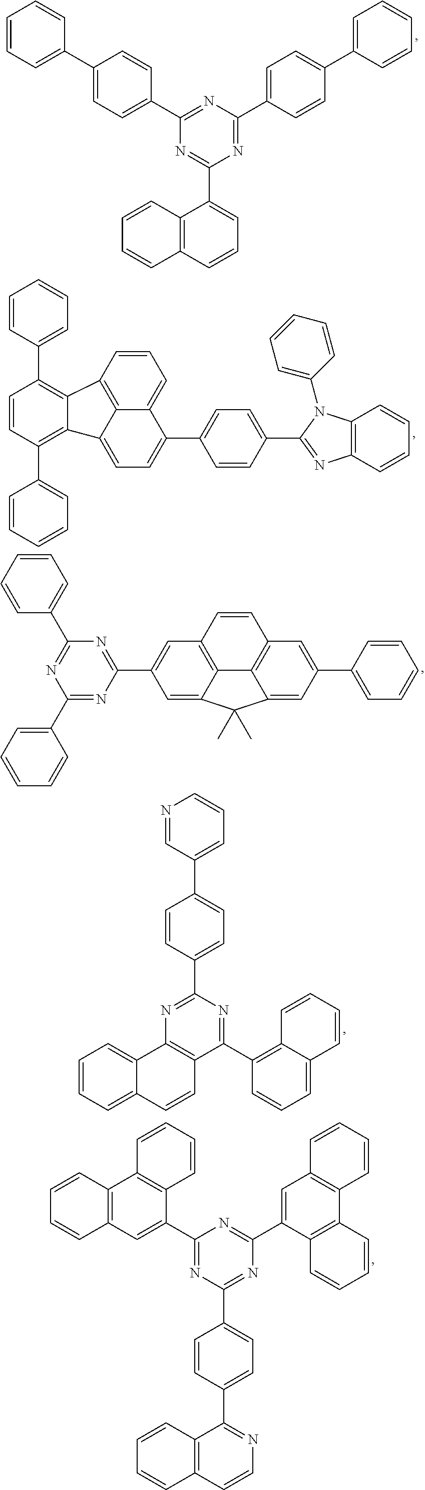

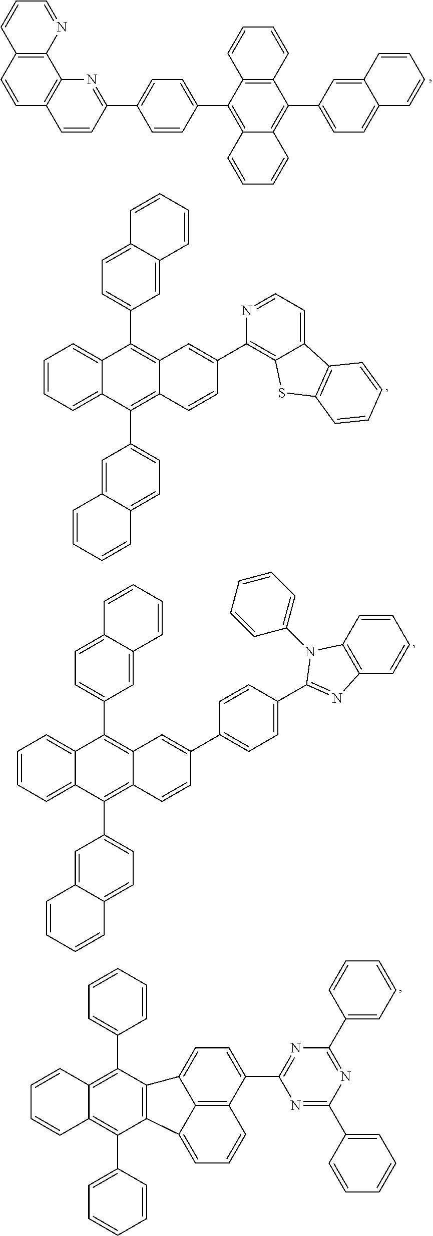

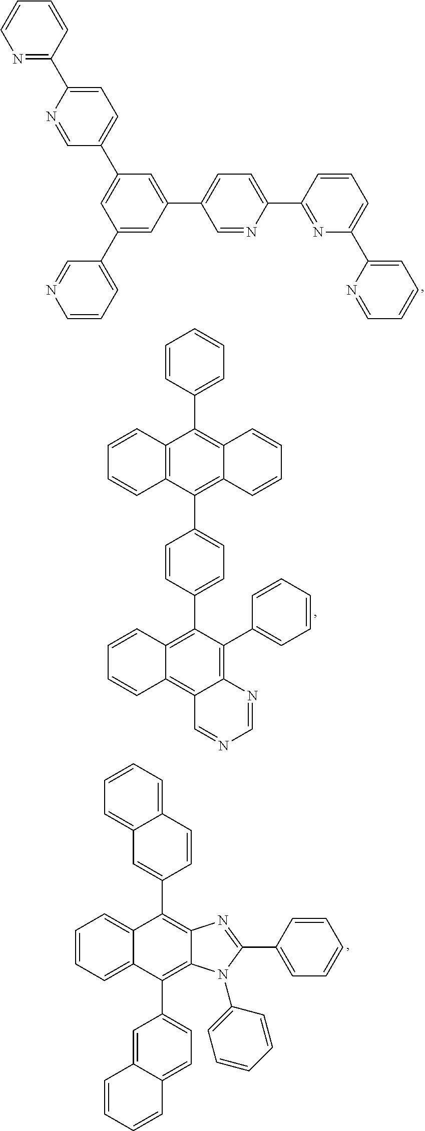 [SMILES: c1ccc(-c2ccc(-c3cc(-c4cccnc4)cc(-c4ccc(-c5cccc(-c6ccccn6)n5)nc4)c3)cn2)nc1 ; c1ccc(-c2c3ccccc3c(-c3ccc(-c4c(-c5ccccc5)c5ncncc5c5ccccc45)cc3)c3ccccc23)cc1 ; c1ccc(-c2nc3c(-c4ccc5ccccc5c4)c4ccccc4c(-c4ccc5ccccc5c4)c3n2-c2ccccc2)cc1]

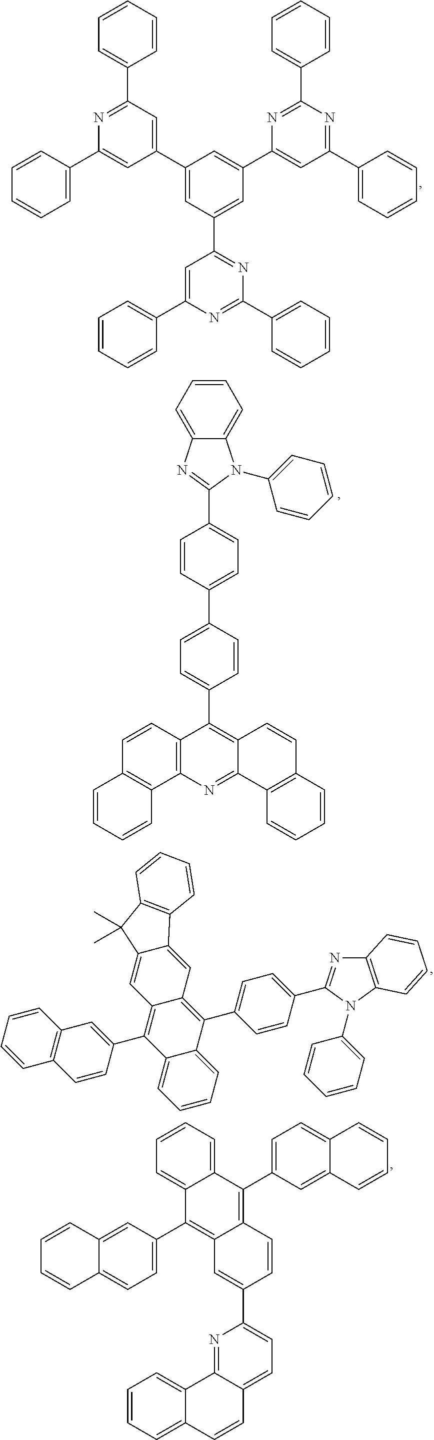

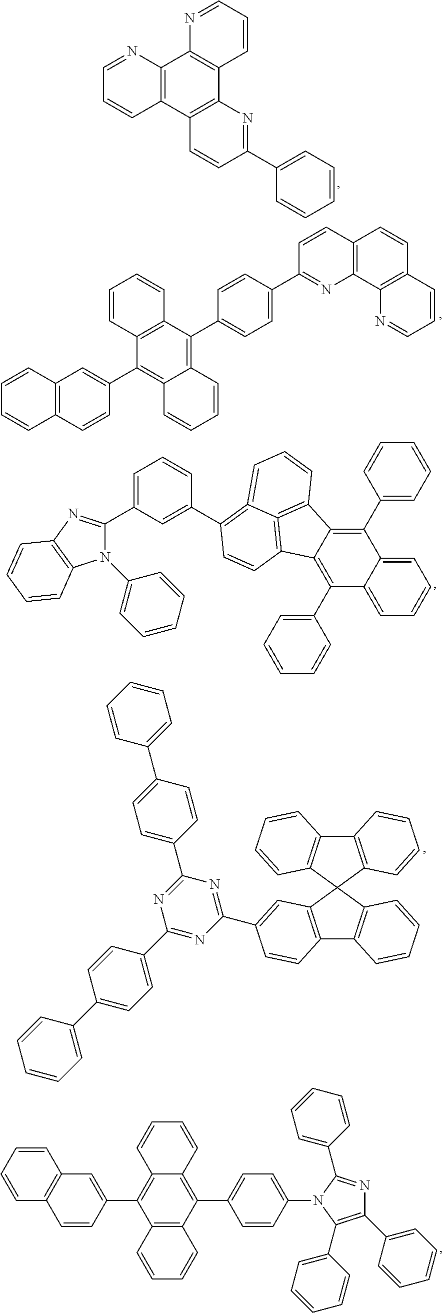

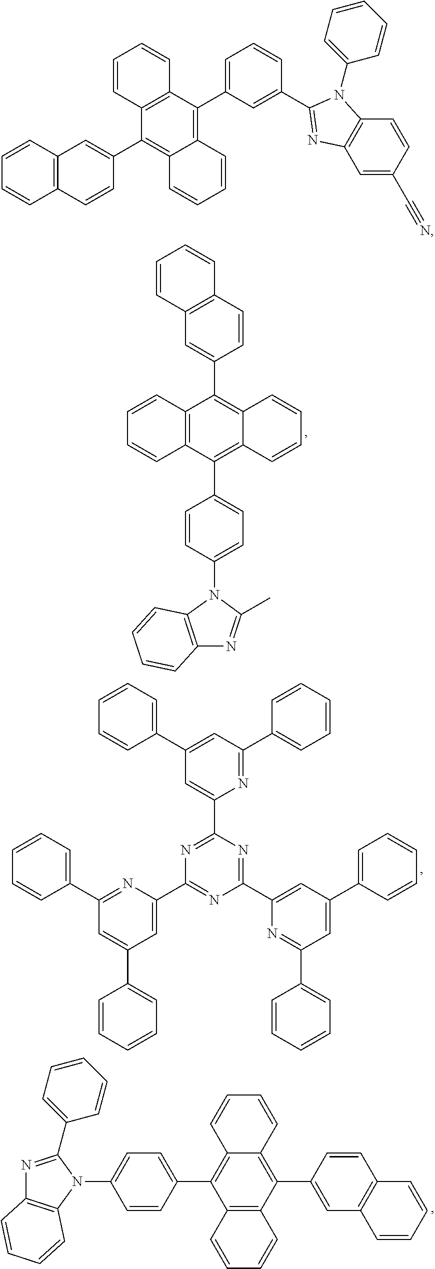

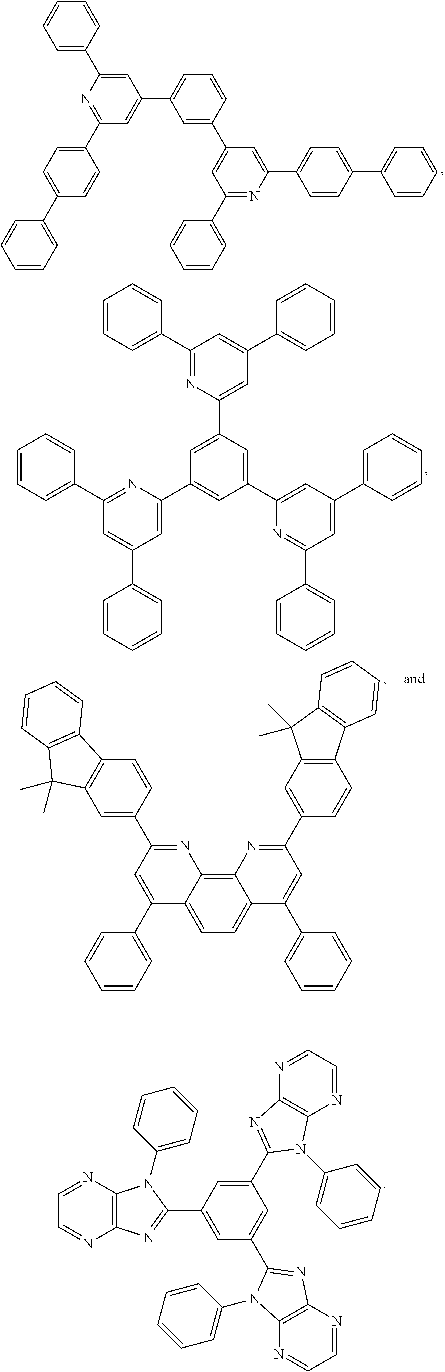

### Charge Generation Layer (CGL)

The CGL plays an essential role in the performance, which is composed of an n-doped layer and a p-doped layer for injection of electrons and holes, respectively. Electrons and holes are supplied from the CGL and electrodes. The consumed electrons and holes in the CGL are refilled by the electrons and holes injected from the cathode and anode, respectively, then, the bipolar currents reach a steady state gradually. Typical CGL materials include n and p conductivity dopants used in the transport layers.

In any above-mentioned compounds used in each layer of the OLED device, the hydrogen atoms can be partially or fully deuterated. The minimum amount of hydrogen of the compound being deuterated is selected from the group consisting of 30%, 40%, 50%, 60%, 70%, 80%, 90%, 95%, 99%, and 100%. Thus, any specifically listed substituent, such as, without limitation, methyl, phenyl, pyridyl, etc. may be undeuterated, partially deuterated, and fully deuterated versions thereof. Similarly, classes of substituents such as, without limitation, alkyl, aryl, cycloalkyl, heteroaryl, etc. also may be undeuterated, partially deuterated, and fully deuterated versions thereof.

It is understood that the various embodiments described herein are by way of example only and are not intended to limit the scope of the invention. For example, many of the materials and structures described herein may be substituted with other materials and structures without deviating from the spirit of the invention. The present invention as claimed may therefore include variations from the particular examples and preferred embodiments described herein, as will be apparent to one of skill in the art. It is understood that various theories as to why the invention works are not intended to be limiting.

As previously disclosed, OLEDs and other similar devices may be fabricated using a variety of techniques and devices. For example, in OVJP and similar techniques, one or more jets of material is directed at a substrate to form the various layers of the OLED.

### EXPERIMENTAL EXAMPLES

### Analysis Methods

The drift-diffusion model is as follows. The electron current (and similarly, hole current), the electrical field and the electron mobility are expressed as:

$${J}_{n} ( x , t ) = q {μ}_{n} ( x , t ) n ( x , t ) E ( x , t ) - kT {μ}_{n} ( x , t ) \frac{\partial }{\partial x} n ( x , t )$$

$$\frac{d E ( x , t )}{d x} = \frac{q}{ε} [ p ( x , t ) - n ( x , t ) ] = - \frac{{d}^{2} V ( x , t )}{d {x}^{2}}$$

$${μ}_{n} ( x , t ) = {μ}_{0 n} ( x ) {e ( \frac{E ( x , t )}{{E}_{0}} )}^{\frac{1}{2}} \times \{ \begin{matrix}e \frac{{ϕ}_{n} - Δ ϕ ( t )}{k T} , & {ϕ}_{n} > Δ ϕ \\ 1 , & {ϕ}_{n} < Δ ϕ\end{matrix}$$

At the barrier interface, the Poole-Frankel type field dependence and a Miller-Abrahams transfer model for the thermionic emission over electron barriers are considered. The mobility in the EML, μ₀ₙ(x<d_{EML}) and μ₀ₚ(x<d_{EML}) are modulated by the concentration of each transport medium following μᵢ=αᵢ exp(βᵢcᵢ), i=n, p. The exciton profile is calculated from:

$$\frac{d n ( x , t )}{d t} = - γ n ( x , t ) p ( x , t ) - \frac{{dJ}_{n} ( x , t )}{d x}$$

$$\frac{d N ( x , t )}{d t} = γ n ( x , t ) p ( x , t ) - \frac{1}{τ} N ( x , t ) - \frac{d}{d x} [ {D}_{N} ( x ) \frac{d N ( x , t )}{d x} ]$$

Here Langevin recombination, exciton diffusion and spontaneous decay are considered.

### Fabrication and Characterization

First, phosphorescent and TADF OLED devices, hole-only and electron-only devices were deposited using vapor thermal evaporation (VTE) in high vacuum (<1e-7 Torr).

Second, external quantum efficiency (EQE) and J-V curve were measured by a parameter analyzer with precision down to fA. Exciton PL lifetime was measured via transient photoluminescence using a chirped pulse amplifier (CPA) laser, an optical parametric amplifier (OPA) and a streak camera/single photon counter. Device transient EL was measured by a pulse generator, an Si avalanche photodiode and an oscilloscope, or a streak camera.

Third, device lifetime and voltage rise were measured using Si photodiodes under continuous, steady current supply.

Fourth, exciton profile was measured by the sensing layer method, using a parameter analyzer and a spectrometer.

FIGD. 4A-4D show that compared to the control device (only the single host HT host 1 is co-deposited with the dopant), the mixed-host device lifetime is 100 times higher through LT70 to LT40 (initial luminance is 500 cd/m² for the control).

### Improved Host Matrix Morphology, Device Efficiency and Device lifetime via Mixed Host Emission Layer

Mixing a high glass transition temperature (T_{g}) host material into a conventional single host-guest emissive layer suppresses the phase separation of the host matrix while increasing the efficiency and operational lifetime of deep blue phosphorescent organic light emitting diodes (PHOLEDs). The high T_{g} host enables homogenous mixing of the molecules comprising the emissive layer while suppressing aggregation that is a significant channel to loss of excitons via concentration quenching and annihilation. By reducing the non-radiative decay of excitons at aggregates, the PHOLED external quantum efficiency is increased by 41±6% relative to an analogous, single-host device. In contrast to single host PHOLEDs where electrons are transported by the host and holes by the dopants, both charge carriers are conducted by the mixed host, thereby further reducing the probability of exciton annihilation. This leads to doubling of the deep blue PHOLED operational lifetime to 52±3 h to reach 70% of the initial luminance of 500 cd/m². This methodology demonstrate the correspondence of host matrix morphology in the emission layer and every aspect of PHOLED performance.

The photoluminescent quantum yield (PLQY) of a dopant is a function of its optical properties (M. Furno, et al., Phys. Rev. B 2012, 85, 115205, E. M. Purcell, et al., Phys. Rev. 1946, 69, 37, M. A. Fusella, et al., Nature 2020, 585, 379) and morphological (S. Reineke, et al., Appl. Phys. Lett. 2009, 94, 163305) environment. That is, the PLQY is critically affected by dopant aggregation that can lead to increased concentration quenching or triplet-triplet and triplet-polaron annihilation (TTA and TPA, respectively) (N. C. Giebink, S. R. Forrest, Phys. Rev. B 2008, 77, 235215, N. C. Giebink, et al., J. Appl. Phys. 2008, 103, 044509, N. C. Giebink et al., J. Appl. Phys. 2009, 105, 124514, Y. Divayana, X. W. Sun, Phys. Rev. Lett. 2007, 99, 143003, D. R. Lutz, et al., Chem. Phys. 1981, 58, 325). Increasing the average intermolecular distance of dopant molecules by reducing the dopant aggregation is well known to increase the PLQY, thereby improving the organic light emitting device (OLED) efficiency, especially at high exciton densities where annihilation dominates. However, solely reducing the dopant concentration can also degrade the charge balance in emission layers where the dopant transports charge of one polarity. Homogeneous mixing of molecules within the emissive layer increases the average intermolecular distance of dopant molecules while maintaining the doping concentration, and thus is critical for improving the device performance.

PHOLEDs are synthesized as described herein with a mixed emissive layer comprising mCBP and a high T_{g} molecule SiTrzCz2 (T_{g}=118° C.). This leads to homogeneous mixing without aggregation of the emissive layer components, including the deep blue dopant, fac-tris(5-(tert-butyl)-1,3-diphenyl2,3-dihydro-1H-imidazo[4,5-b]pyrazine) iridium] (Ir(cb)₃). The optimized 1:1 volume ratio of mCBP in SiTrzCz2 leads to a 41±6% relative increase in the peak EQE compared to an emission layer comprising only mCBP. The PHOLEDs feature deep blue chromaticity coordinates of (0.14, 0.15). The operational lifetime of the mixed host device is doubled compared to the single host device, showing LT₇₀=52±3 h vs. 24±4 h, respectively. Here, LT₇₀ is the operation time to reach 70% of initial luminance of L₀=500 cd/m². Through this techinque, the morphology of emissive layer influences all aspects of the device including the charge balance, PLQY, EQE and most importantly, the operational lifetime.

PHOLED devices, including hole-only and electron-only devices are deposited using vacuum thermal evaporation. The J-V and EQE-J characteristics were measured using a parameter analyzer and a calibrated photodiode following standard procedures. The emission spectra were collected via an optical fiber and a calibrated spectrometer. For lifetime tests, PHOLEDs were operated at constant current) and the luminance and voltage data were automatically collected. All devices were encapsulated using bare glasses and UV-cured epoxy in the glovebox which maintained pure N2 atmosphere (<0.1 ppm O2 and H2O). Samples for GIWAXS measurements were prepared on Si wafers and thermally annealed in N2. The X-ray energy was 10 keV and the scattering patterns were recorded on a 2D image plate. Differential scanning calorimetry (DSC) data obtained using a differential scanning calorimeter from 40 to 300° C. at a heating rate of 10° C./min under a nitrogen atmosphere.

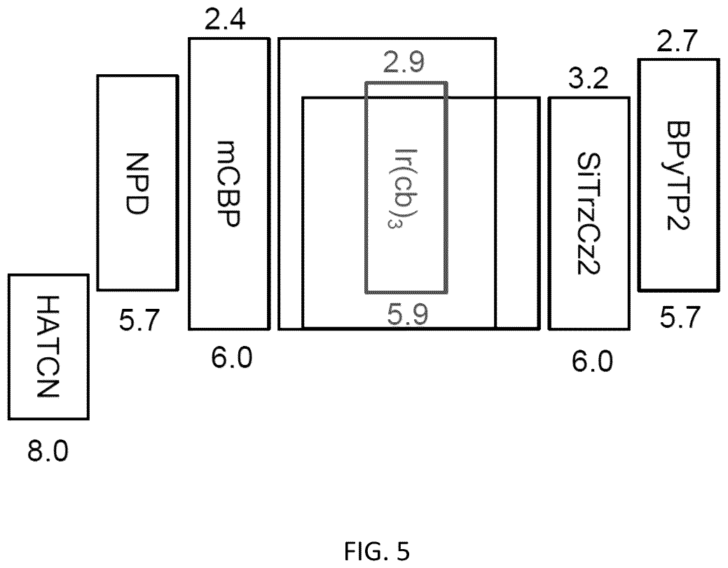

This technique includes a device structure and the characterization methodology. FIG. 5 shows the structure of the PHOLED used to study the electroluminescent properties of the mixed host emission layer (EML). The characterization of emission layer morphology includes differential scanning calorimetry (DSC) and the grazing incidence wide-angle X-ray scattering (GIWAXS). The characterization of the emission layer includes the PLQY measurements, transient photoluminescence (PL). The study of the charge carrier behaviors includes measuring the J-V characteristics of electron-only, hole-only, single-host and mixed-host devices varying doping concentrations. The standard device characterization includes J-V and EQE-J measurements using a parameter analyzer and a calibrated photodiode, the electroluminescence (EL) measurements using a calibrated spectrometer, and a lifetime test station for encapsulated devices operating at constant currents.

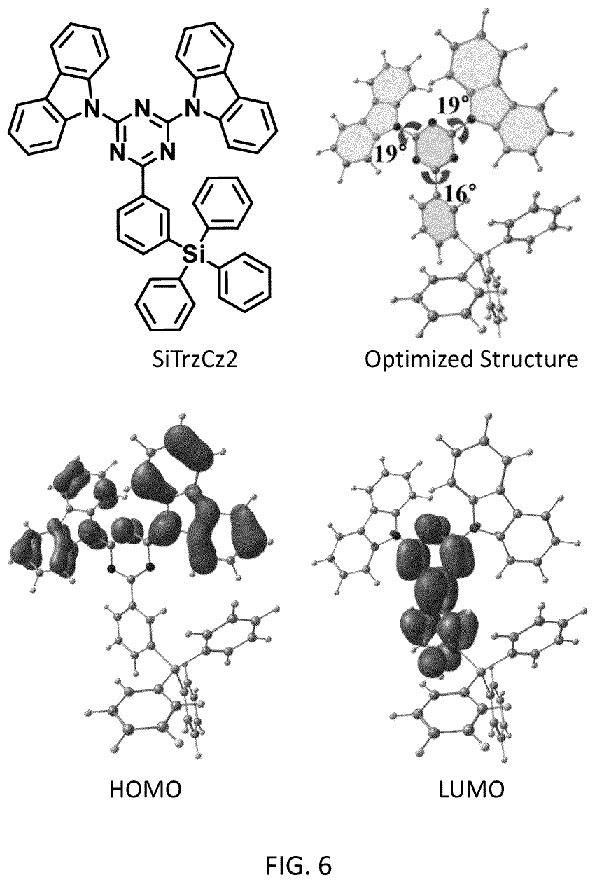

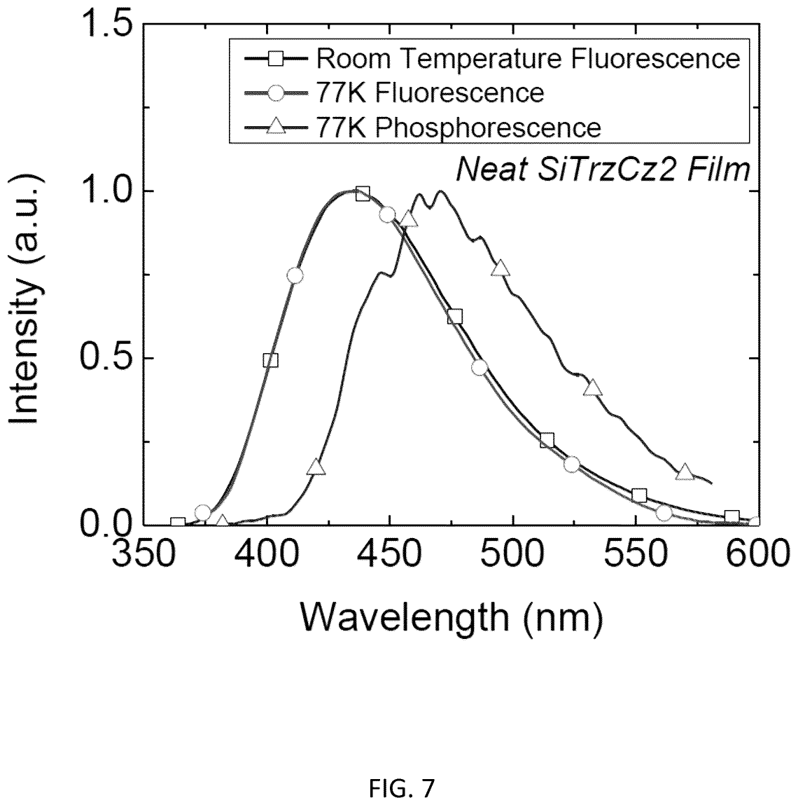

The molecular structural formula of SiTrzCz2 is shown in FIG. 6. The optimized structure shows 16° and 19° twist angles of the carbazole and phenyl groups from the center plane, respectively. The bulky geometry prevents tight molecular stacking of SiTrzCz2 when mixed with other compounds. Density functional theory (DFT) calculations show that the highest occupied molecular orbital (HOMO) resides primarily on the carbazole group, whereas the lowest unoccupied molecular orbital (LUMO) locates at the center of the molecule. The HOMO and LUMO do not form on the triphenylsilane moiety, which provides the steric bulk. The cyclic voltammetry scan gives HOMO and LUMO energies of −6.0 eV and −3.2eV, respectively, from which we infer an energy gap of 2.8 eV. This corresponds to a wavelength of 447 nm, which is consistent with the monomeric fluorescence peak in FIG. 7. The film phosphorescence peaks at 465 nm (2.7eV), making this a suitable host for deep blue phosphorescent host molecules.

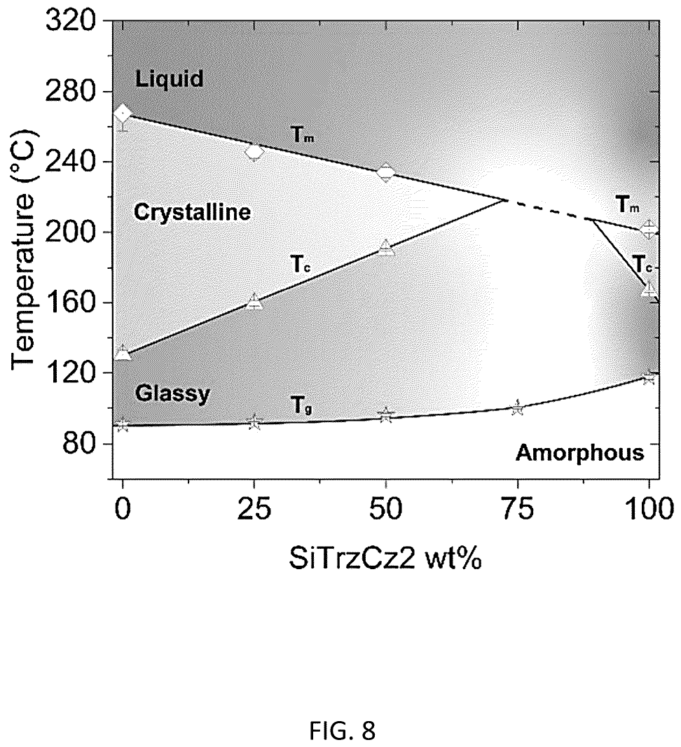

FIG. 8 shows the phase diagram of films comprising several weight ratios of mCBP and SiTrzCz2 as obtained from DSC data. The glass transition temperature, T_{g}, increases with SiTrzCz2 fraction, peaking for a neat SiTrzCz2 film. The crystallization temperature of the film, T_{c}, also increases with the degree of mixing, vanishing at 75% SiTrzCz2, showing that material mixing completely suppresses crystallization. Mixing materials also affects the melting temperature, Tₘ, showing a linear decrease with the SiTrzCz2 fraction. There is no clear temperature near 75 wt. % indicating crystallization or melting. It occurs since the two materials are strongly intermixed, not being able to be entirely separated. This is a direct indication that inclusion of either host prevents crystallization of the other.

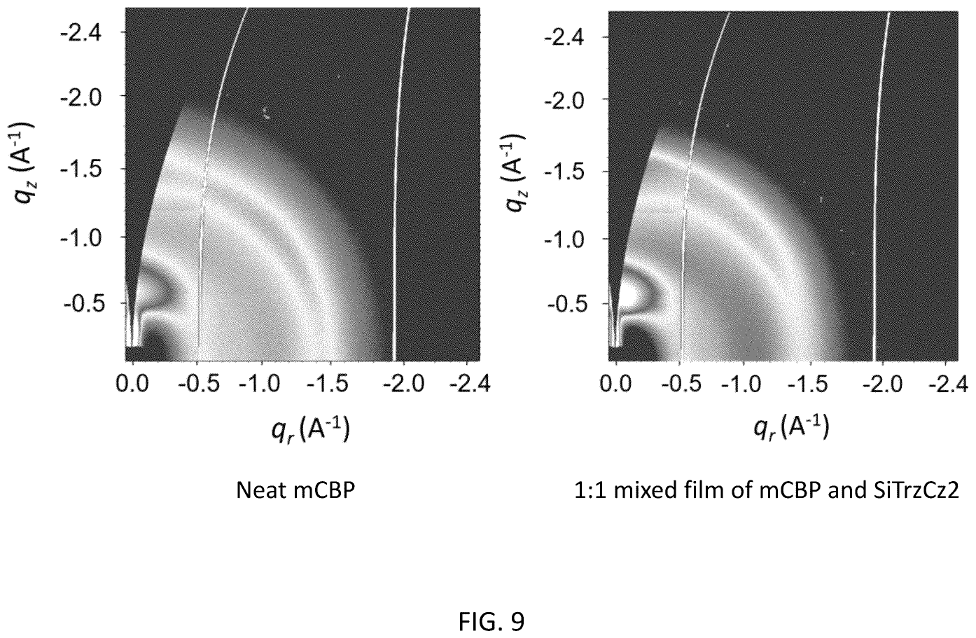

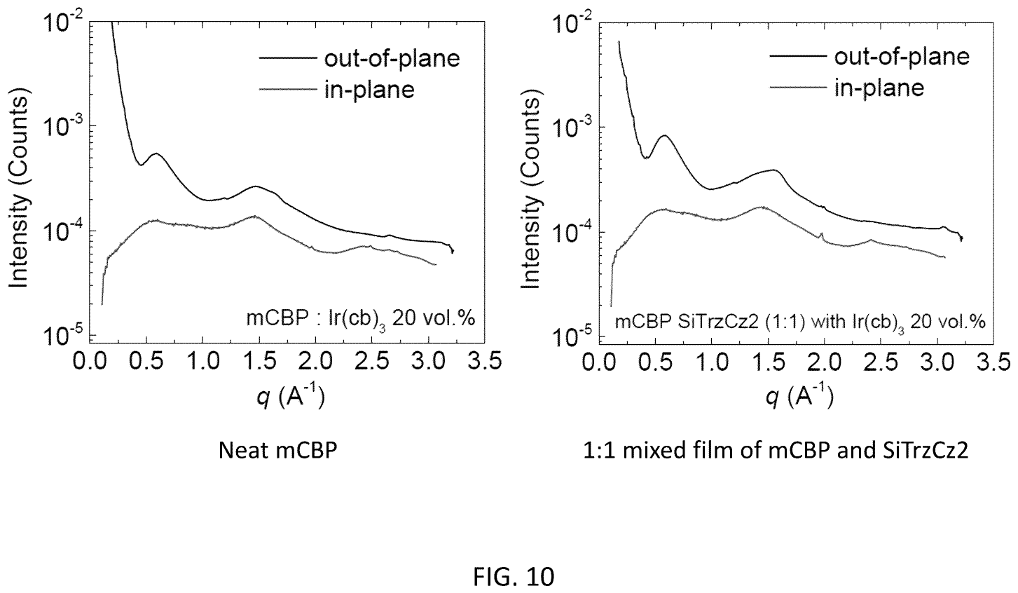

Grazing incidence wide-angle X-ray scattering (GIWAXS) patterns were captured of layers comprising SiTrzCz2 (FIG. 9, left), and a mixture of mCBP in SiTrzCz2 (1:1 volume ratio, FIG. 9, right) doped with Ir(cb)3 at 20 vol. %. Line-cuts of the diffraction patterns of neat mCBP and the mixed film are shown in FIG. 10, left and right respectively. We define the r- and z-axis as in- and out-of-plane, respectively. The (100) peaks are found at a scattering parameter of q_{z}=0.6 \acute{Å}⁻¹ , suggesting a lamellar stacking distance of 10.5 \acute{Å}. The (010) peak at q=1.5 \acute{Å}⁻¹ corresponds to a π-stacking distance of 4 \acute{Å}. The π-stacking habits and lamellar structures of an mCBP molecular crystal are shown in FIGS. 9, left and right respectively. The mixed film shows two π-stacking peaks, in which the feature at q=1.57 \acute{Å}⁻¹ possibly arises from stacking between the carbazole groups of mCBP and SiTrzCz2. This peak vanishes with annealing due to weak attraction between mCBP and SiTrzCz2 caused by the bulky structure of SiTrzCz2. The full-width-at-half-maximum (FWHM) of the lamellar peak of the neat mCBP and the mixed films are similar. However, the FWHM of the mCBP π-stacking peak changes when SiTrzCz2 is added, from 0.33±0.01 \acute{Å}⁻¹ to 0.53±0.01 \acute{Å}⁻¹ for a 1:1 ratio, showing that stacking of mCBP is suppressed in the mixed film.

FIG. 5 shows the structure of the PHOLED used to study the electroluminescent properties of the mixed host emission layer (EML). Neat layers of N, N′-di(1-naphthyl)-N, N′-diphenyl-(1,1′-biphenyl)-4,4′-diamine (NPD) and 5-(7-[2,2′-bipyridin]-5-yl-2-triphenylenyl)-2,2′-bipyridine (BPyTP2) are used as the hole and electron transporting layers, respectively, while neat mCBP and SiTrzCz2 are used as electron and exciton blocking layers, respectively. The emissive layer is comprised of a mixture of mCBP and SiTrzCz2 doped with Ir(cb)₃. The HOMO levels of the two hosts are comparable, whereas the LUMO of SiTrzCz2, determined from the reduction potential obtained via cyclic voltammetry, is 0.8 eV deeper than for mCBP.

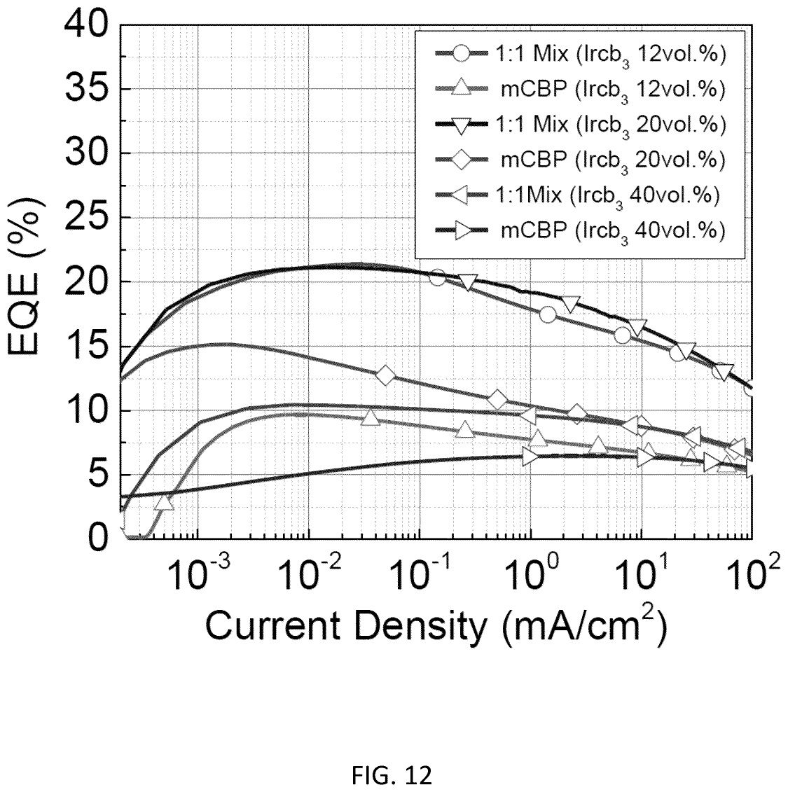

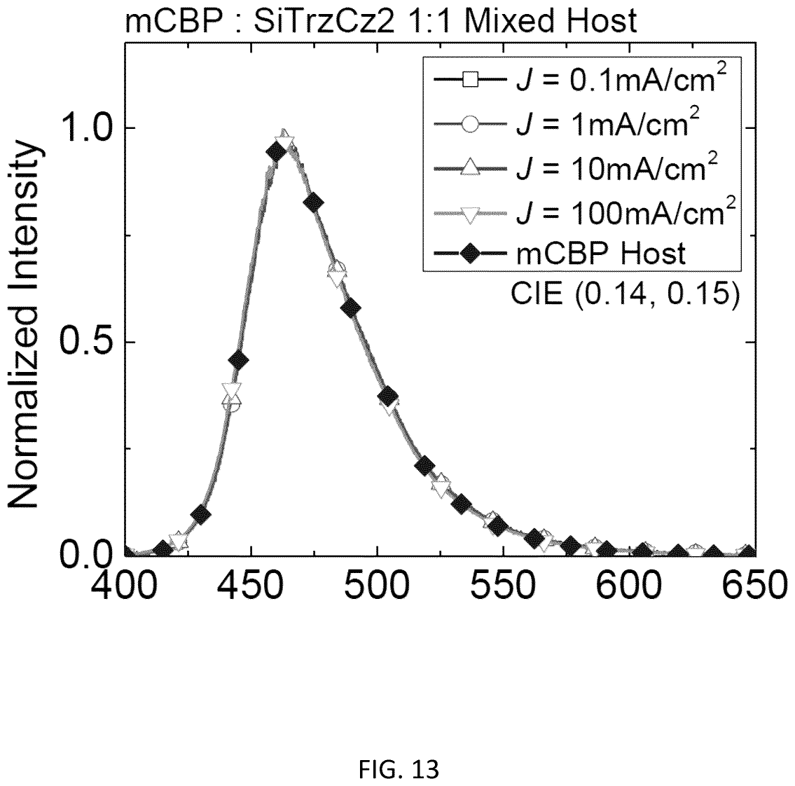

FIG. 12 shows the EQE vs. current density (J) of the PHOLEDs with a neat mCBP host, and a SiTrzCz2:mCBP mixed host (1:1 volume ratio) for several Ir(cb)₃ doping concentrations. Devices with the mixed host show a higher peak EQE compared to the neat mCBP host at all Ir(cb)₃ concentrations. The peak EQE=22±1% of the mixed host with 12 and 20 vol. % Ir(cb)₃ are comparable, whereas the neat mCBP host device shows a 56±4% decrease when the doping concentration is reduced to 12 vol. %. The electroluminescence spectra at several J are provided in FIG. 13 with a peak at 465 nm, featuring deep blue CIE coordinates of (0.14, 0.15) independent of J.

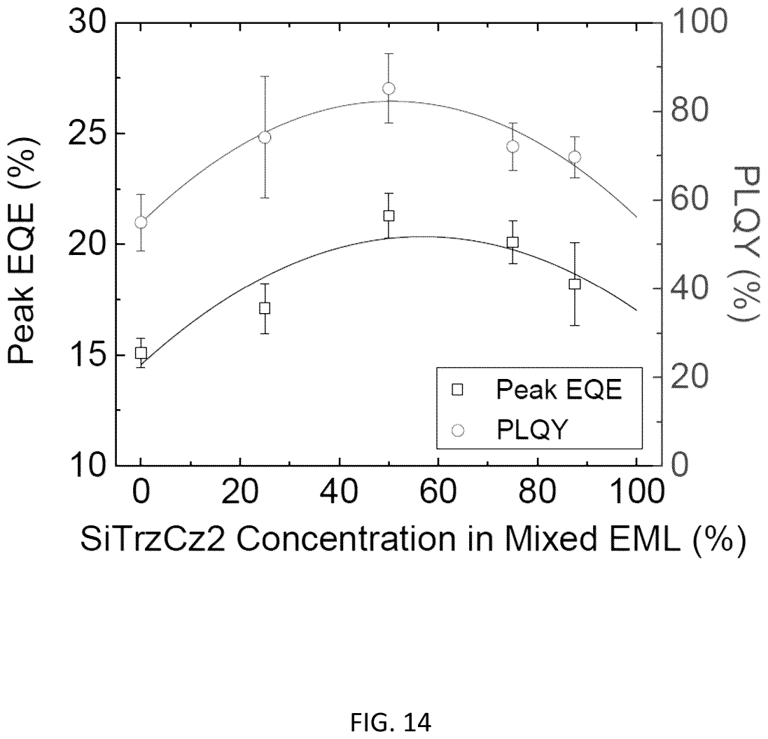

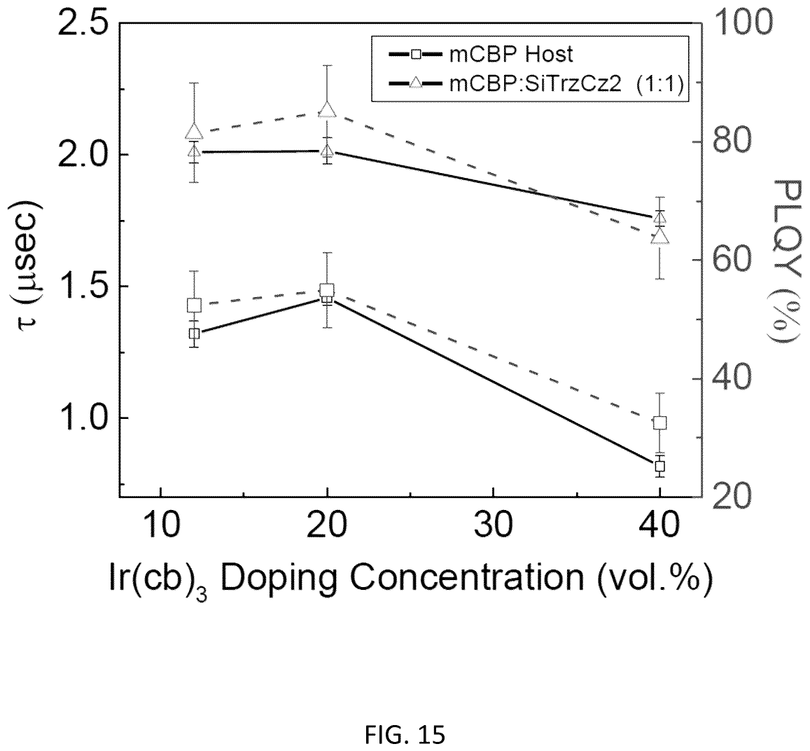

FIG. 14 shows the peak EQE of the PHOLEDs and the PLQY of the emissive layers with 0-90 vol. % mixing ratio of SiTrzCz2 to mCBP with 20 vol. % Ir(cb)₃, showing maxima at a 1:1 ratio. FIG. 15 gives the exciton radiative lifetime vs. Ir(cb)₃ doping concentration in neat mCBP and 1:1 mCBP:SiTrzCz2. The lifetime shows an approximately 40% increase by adding SiTrzCz2. The radiative lifetime at 12 and 20 vol. % concentration of Ir(cb)₃ shows similar results, followed by a decrease at 40 vol. %. The PLQY also shows similar values between 12 and 20 vol. %, again decreasing at higher doping concentrations.

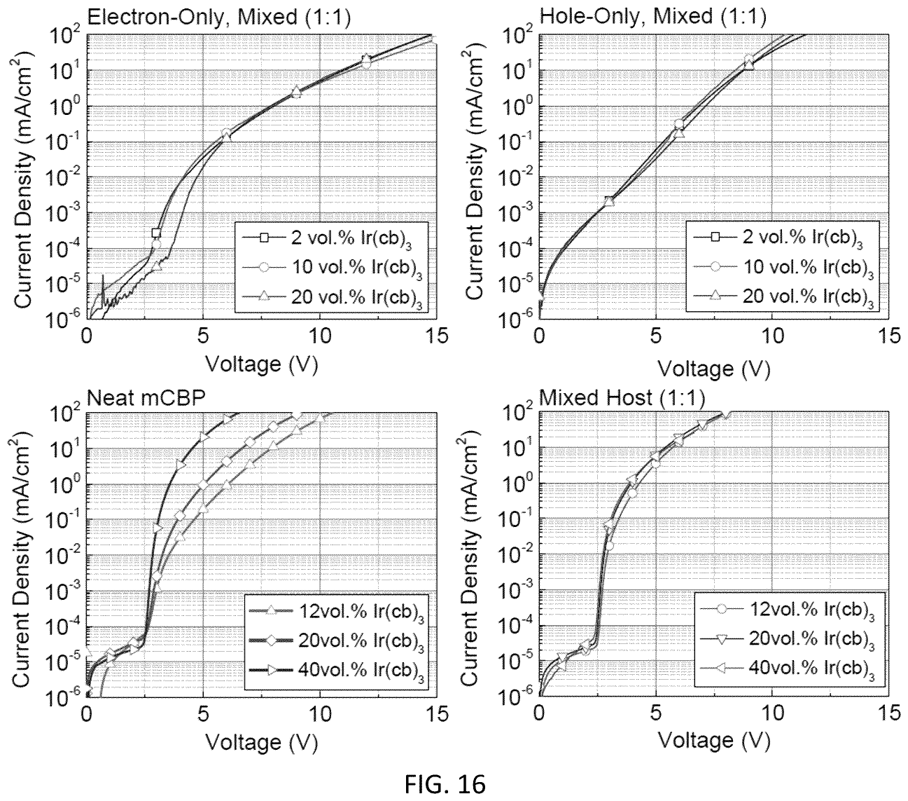

FIG. 16 shows the J-voltage (V) characteristics of electron- and hole-only devices at several Ir(cb)₃ concentrations in the mixed host EML. The current densities for both devices are independent of dopant concentration, demonstrating that charge is conducted by the hosts rather than the dopant. Since the LUMO of SiTrzCz2 is 0.8 eV deeper than mCBP, SiTrzCz2 must carry electrons in the EML, whereas mCBP conducts holes (J. Ràfols-Ribé, et al., Sci. Adv. 2018, 4). The electrons are blocked by the neat mCBP layer, improving the charge balance. In the emissive layer comprising neat mCBP, the dependence of the current vs. Ir(cb)₃ concentration indicates that the electrons are transported through the dopant in the absence of SiTrzCz2.

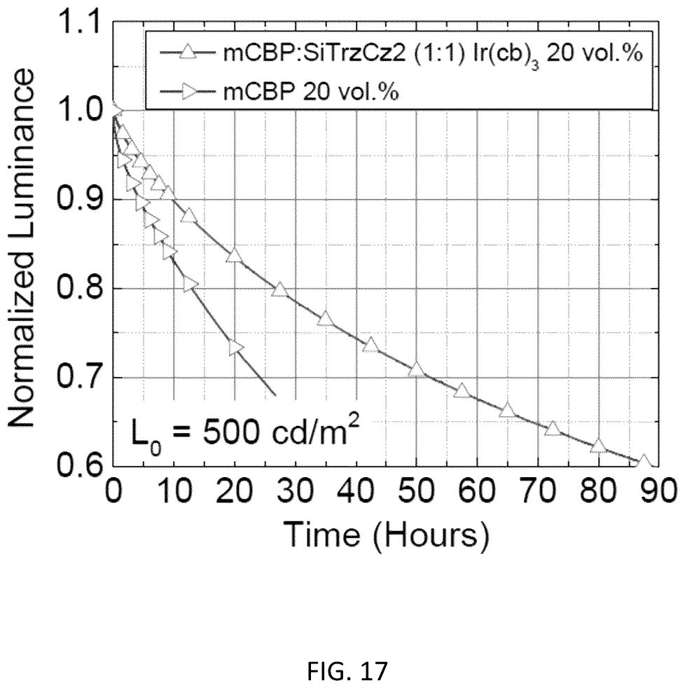

FIG. 17 shows the operational lifetime of encapsulated PHOLEDs with neat mCBP and 1:1 mCBP:SiTrzCz2 emissive layers at an initial luminance of L₀=500 cd/m². The neat mCBP host devices show LT₇₀=24±4 h, whereas devices comprising the mixed host demonstrate 52±3 h, a two-fold improvement.

The following publications are each incorporated herein by reference in their entirety:

U.S. Patent Num. 11342526, “Hybrid organic light emitting device”, patented May 24, 2022.
U.S. Patent Application Num. 20210020867, “Organic light emitting device”, published Jan. 21, 2021.

The disclosures of each and every patent, patent application, and publication cited herein are hereby incorporated herein by reference in their entirety. While this invention has been disclosed with reference to specific embodiments, it is apparent that other embodiments and variations of this invention may be devised by others skilled in the art without departing from the true spirit and scope of the invention.

What is claimed is:

1. An organic light emitting device (OLED), comprising:
a substrate;
a first electrode positioned over the substrate;
a hole injection layer (HIL) positioned over the first electrode;
an emission layer (EML) positioned over the HIL, comprising oppositely graded cohost materials doped with an emitter material;
an electron transport layer (ETL) positioned over the EML; and
a second electrode positioned over the ETL.

2. The device of claim 1, wherein the emitter material is graded.

3. The device of claim 1, wherein the emitter material comprises a TADF emitter or a blue TADF emitter.

4. The device of claim 1, wherein the one of the graded cohost materials comprises an electron transport (ET) host.

5. The device of claim 1, wherein the one of the graded cohost materials comprises a hole transport (HT) host.

6. The device of claim 1, wherein the one of the graded host material is linearly graded from 18% to 8% from the HBL interface to the EBL interface.

7. The device of claim 1, wherein the emitter material is linearly graded from 18% to 8% from the EBL interface to the HBL interface.

8. The device of claim 1, further comprising an electron blocking layer (EBL) positioned between the HIL and the EML.

9. The device of claim 1, further comprising a hole blocking layer (HBL) positioned between the EML and the ETL.

10. The device of claim 1, wherein the first electrode has a thickness of 50 nm to 100 nm.

11. The device of claim 1, wherein the first electrode comprises ITO.

12. The device of claim 1, wherein the HIL has thickness of 0.5 nm to 10 nm.

13. The device of claim 1, wherein the ETL has a thickness of 10 nm to 50 nm.

14. The device of claim 5, wherein the HT host is a first host compound comprising at least one chemical moiety selected from the group consisting of triphenylene, carbazole, indolocarbazole, dibenzothiphene, dibenzofuran, dibenzoselenophene, 5λ2-benzo[d]benzo[4,5]imidazo[3,2-a]imidazole, 5,9-dioxa-13b-boranaphtho[3,2,1-de]anthracene, triazine, boryl, silyl, aza-triphenylene, aza-carbazole, aza-indolocarbazole, aza-dibenzothiophene, aza-dibenzofuran, aza-dibenzoselenophene, aza-5 λ 2-benzo[d]benzo[4,5]imidazo[3,2-a]imidazole, and aza-(5,9-dioxa-13b-boranaphtho[3,2,1-de]anthracene).

15. The device of claim 3, wherein the blue TADF emitter is a compound of Formula A: 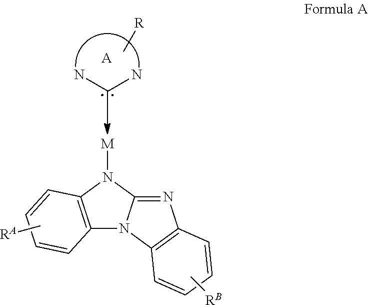
wherein, in Formula A,
M is a metal selected from the group consisting of Ag(I), Au(I), and Cu(I);
ring A is a carbene ligand;
R, R^{A}, and R^{B} represent mono to the maximum allowable substitution; and
each R, R^{A}, and R^{B} is independently hydrogen or a substituent selected from the group consisting of deuterium, halogen, alkyl, cycloalkyl, heteroalkyl, heterocycloalkyl, arylalkyl, alkoxy, aryloxy, amino, silyl, alkenyl, cycloalkenyl, heteroalkenyl, alkynyl, aryl, heteroaryl, nitrile, isonitrile, sulfanyl, boryl, acyl, carboxylic acid, ether, ester, sulfinyl, sulfonyl, cyano, phosphino, and combinations thereof; wherein any two adjacent R, R^{A}, and R^{B} are optionally joined or fused together to form a ring which is optionally substituted.

16. The device of claim 3, wherein the blue TADF emitter is represented by one of the following structures: 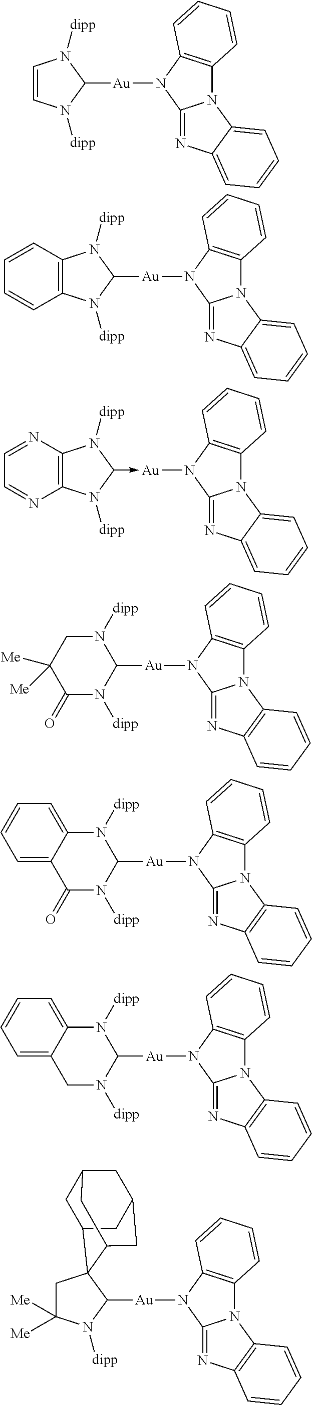 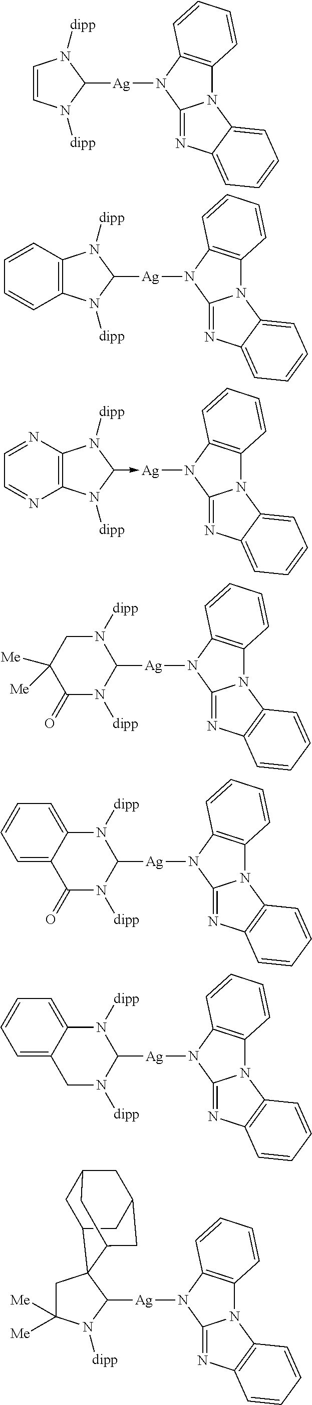 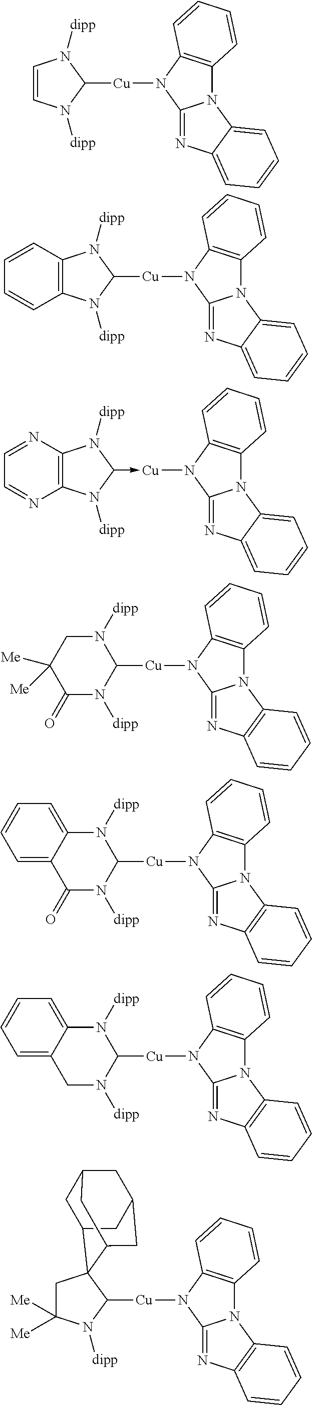 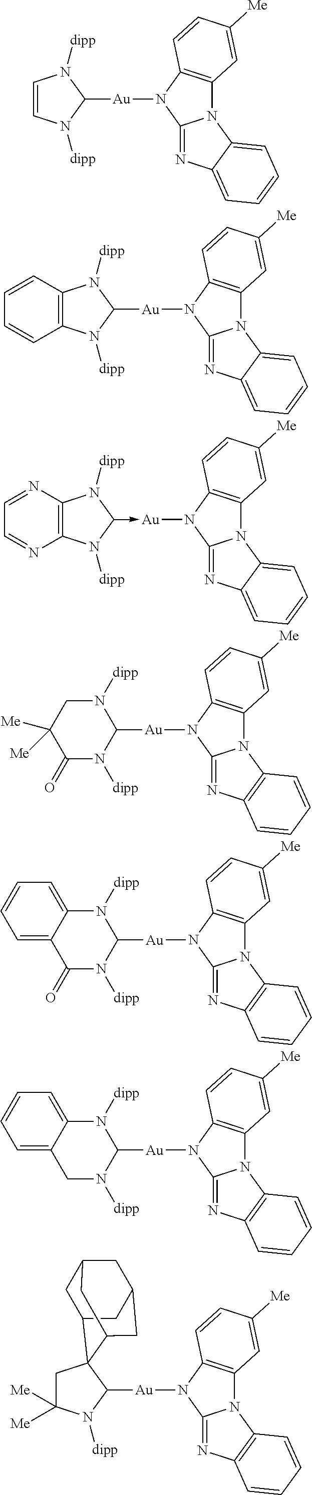 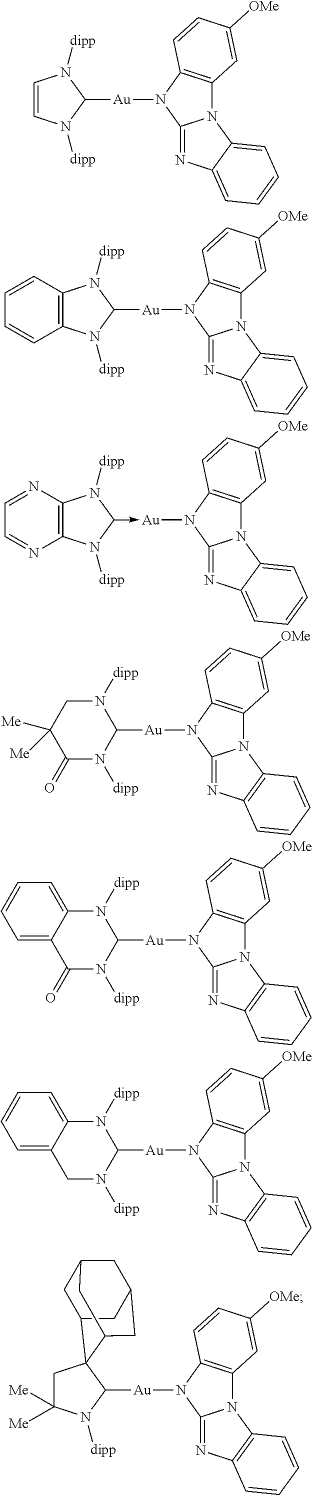
wherein dipp is 2,6-disopropylphenyl.

17. The device of claim 4, wherein the ET host is a second host compound having the structure of Formula I: 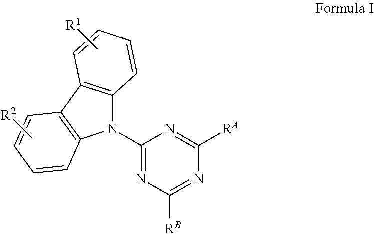
wherein, in Formula I,
R^{A} and R^{B} are each independently selected from the group consisting of: 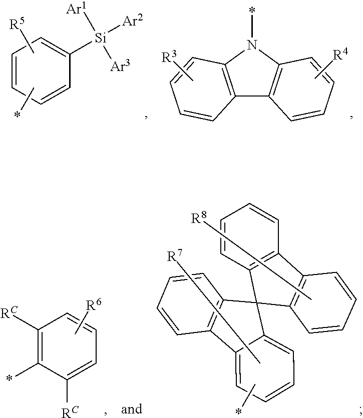
wherein * indicates the bond to Formula I;
wherein each of R⁵ to R⁸ represent mono to the maximum number of substitution, or no substitution;
Ar¹, Ar², and Ar³ are each an aryl or heteroaryl group, wherein the Ar¹, Ar², and Ar³ are each optionally further substituted with one or more substituents R^{D};
each R^{C}, R^{D}, and R¹ to R⁸ is independently a hydrogen or is selected from the group consisting of deuterium, halogen, alkyl, cycloalkyl, heteroalkyl, heterocycloalkyl, arylalkyl, alkoxy, aryloxy, amino, silyl, germyl, boryl, alkenyl, cycloalkenyl, heteroalkenyl, alkynyl, aryl, heteroaryl, acyl, carboxylic acid, ether, ester, nitrile, isonitrile, sulfanyl, selenyl, sulfinyl, sulfonyl, phosphino, and combinations thereof; and
R¹ to R⁸ represent mono to the maximum number of substitution, or no substitution;
each R¹ to R⁸ is independently a hydrogen or is selected from the group consisting of deuterium, halogen, alkyl, cycloalkyl, heteroalkyl, heterocycloalkyl, arylalkyl, alkoxy, aryloxy, amino, silyl, germyl, boryl, alkenyl, cycloalkenyl, heteroalkenyl, alkynyl, aryl, heteroaryl, acyl, carboxylic acid, ether, ester, nitrile, isonitrile, sulfanyl, selenyl, sulfinyl, sulfonyl, phosphino, and combinations thereof; and
wherein any two adjacent substituents may join to form a ring.

18. The device of claim 1, wherein the LUMO of the EML is in the range of 0.1 to 2 eV, and the HOMO of the EML is in the range of 5 to 7 eV.

19. A product comprising the device of claim 1, the product selected from the group consisting of a flat panel display, a curved display, a computer monitor, a computer, a medical monitor, a television, a billboard, a light for interior or exterior illumination and/or signaling, a heads-up display, a fully or partially transparent display, a flexible display, a rollable display, a foldable display, a stretchable display, a laser printer, a telephone, a mobile phone, a tablet, a phablet, a personal digital assistant (PDA), a wearable device, a laptop computer, a digital camera, a camcorder, a viewfinder, a micro-display, a 3-D display, a virtual reality or augmented reality display or device, a vehicle, a video wall comprising multiple displays tiled together, a theater or stadium screen, a light therapy device, a camera, an imaging device, and a sign.

20. A method of manufacturing an organic light emitting device (OLED), comprising:
depositing a first electrode over a substrate;
depositing a hole injection layer (HIL) positioned over the first electrode;
depositing an emission layer (EML) positioned over the HIL, wherein the EML comprises a graded cohost or co-doped emission layer;
depositing an electron transport layer (ETL) positioned over the EML; and
depositing a second electrode positioned over the ETL.
